(19) United States
(12) Patent Application Publication
(10) Pub. No.: US 2025/0069335 A1
(43) Pub. Date: Feb. 27, 2025

(54) DISPLAY SYSTEM

(71) Applicant: Semiconductor Energy Laboratory Co., Ltd., Atsugi-shi, Kanagawa-ken (JP)

(72) Inventors: Daigo ITO, Isehara (JP); Yuki HATA, Atsugi (JP)

(21) Appl. No.: 18/711,330

(22) PCT Filed: Nov. 17, 2022
(86) PCT No.: PCT/IB2022/061050

§ 371 Date: May 17, 2024

(30) Foreign Application Priority Data
Nov. 30, 2021 (JP) 2021-194491

(51) Int. Cl. G06T 19/00; G02B 27/01

(52) U.S. Cl. CPC G06T 19/006; G02B 27/0172; G02B 2027/0178

(57) ABSTRACT

A display apparatus with a novel structure or a display system with a novel structure is provided. The display system includes a first display apparatus capable of AR display and a second display apparatus. The first display apparatus includes a first display portion displaying a first image superimposed on a transmission image. The second display apparatus includes a second display portion. The first display apparatus has a function of obtaining positional information of the second display portion. A display position of the first image is determined on the basis of the positional information of the second display portion.

### TECHNICAL FIELD

One embodiment of the present invention relates to a display apparatus and a display system including the display apparatus.

Note that one embodiment of the present invention is not limited to the above technical field. Examples of the technical field of one embodiment of the present invention disclosed in this specification and the like include a semiconductor device, an imaging device, a display apparatus, a light-emitting apparatus, a power storage device, a storage device, a display system, an electronic device, a lighting device, an input device, an input/output device, a driving method thereof, and a manufacturing method thereof.

In this specification and the like, a semiconductor device refers to every device that can function by utilizing semiconductor characteristics. A display apparatus (a liquid crystal display apparatus, a light-emitting display apparatus, and the like), a projection device, a lighting device, an electro-optical device, a power storage device, a storage device, a semiconductor circuit, an imaging device, an electronic device, and the like can sometimes be regarded as a semiconductor device. Alternatively, they can sometimes be regarded as including a semiconductor device.

### BACKGROUND ART

As electronic devices with display apparatuses for augmented reality (AR) or virtual reality (VR), smartphones, tablets, wearable electronic devices, stationary electronic devices, and the like are becoming widespread. Examples of wearable electronic devices include a head-mounted display (HMD) and a glasses-type electronic device. Examples of stationary electronic devices include a head-up display (HUD).

As one of AR techniques, a technique using a two-dimensional barcode printed on paper or the like is known. A two-dimensional barcode is captured by a camera, a captured image is identified, and a three-dimensional image corresponding to the two-dimensional barcode is displayed at the position of the two-dimensional barcode, whereby a visual effect in which a real space and a virtual space are superimposed can be obtained. Patent Document 1 discloses a system using a game machine (an electronic device), a board, and a card as a game system utilizing AR techniques.

### REFERENCE

### Patent Document

[Patent Document 1] Japanese Published Patent Application No. 2012-178068

### SUMMARY OF THE INVENTION

### Problems to be Solved by the Invention

As in Patent Document 1 or the like, there is a display system in which AR display is superimposed on a two-dimensional barcode printed on a paper medium or the like. However, it is difficult to change the content printed on a paper medium and other printed materials, and a plurality of printed materials such as game boards and game cards need to be used. That is, enjoying a plurality of games needs a plurality of printed materials, which causes problems such as poor portability, an increase in storage space, and an increased risk of loss.

Thus, an object of one embodiment of the present invention is to achieve a system that uses a display apparatus such as a liquid crystal display or an organic EL display instead of a printed material superimposed on AR display. Note that the object to be solved by the present invention is described above taking a game system as an example; however, the object to be solved by the present invention is not limited to the game system.

That is, an object of one embodiment of the present invention is to achieve a display system in which AR display in a first electronic device (e.g., a goggle-type device) and normal display in a second electronic device (e.g., a smartphone and a tablet) are superimposed in conjunction with each other. An object is to superimpose AR display and normal display to achieve realistic display and a variety of expressions that cannot be conventionally performed.

Another object of one embodiment of the present invention is to provide a display apparatus with a novel structure or a display system with a novel structure. Another object of one embodiment of the present invention is to provide a method for operating a display apparatus with a novel structure or a method for operating a display system with a novel structure.

Note that the description of a plurality of objects does not preclude the existence of each object. One embodiment of the present invention does not have to achieve all of these objects. Objects other than those listed above will be apparent from the description of the specification, the drawings, the claims, and the like, and such objects could be objects of one embodiment of the present invention.

### Means for Solving the Problems

One embodiment of the present invention is a display system including a first display apparatus and a second display apparatus. The first display apparatus includes a first display portion displaying a first image superimposed on a transmission image. The second display apparatus includes a second display portion. The first display apparatus has a function of obtaining positional information of the second display portion. A display position of the first image is determined on the basis of the positional information of the second display portion.

In the display system described above, the first display portion has a light-transmitting property and the transmission image is an image passing through the first display portion.

In the display system described above, the first display apparatus includes an imaging means and the transmission image is an image captured by the imaging means.

In any one of the display systems described above, the first image is preferably displayed in the case where at least part of the second display portion is positioned in the range of the transmission image.

In any one of the display systems described above, the first image is preferably generated in accordance with the positional information.

In any one of the display systems described above, the first display apparatus is preferably a glasses-type apparatus.

In any one of the display systems described above, the first display apparatus is preferably a goggle-type display apparatus.

In any one of the display systems described above, the second display apparatus preferably includes a hinge portion, and the second display apparatus preferably has a function of being folded at the hinge portion.

In any one of the display systems described above, preferably, the first display apparatus includes a first layer, a second layer, and a third layer; the first layer includes a driver circuit and a CPU; the second layer includes a pixel circuit; the third layer includes a display device; the first layer includes a first transistor including a semiconductor layer including silicon in a channel formation region; the second layer includes a second transistor including a semiconductor layer including a metal oxide in a channel formation region; and the third layer includes an organic EL device.

In any one of the display systems described above, the metal oxide preferably includes indium, an element M (M is aluminum, gallium, yttrium, or tin), and zinc.

In any one of the display systems described above, the organic EL device is preferably a light-emitting device processed by a photolithography method.

### Effect of the Invention

In a display system of one embodiment of the present invention, AR display in a first electronic device (e.g., a goggle-type device) and normal display in a second electronic device (e.g., a smartphone and a tablet) can be superimposed in conjunction with each other. Superimposing AR display and normal display enables realistic display and a variety of expressions that cannot be conventionally performed.

Another embodiment of the present invention can provide a display apparatus with a novel structure or a display system with a novel structure. Another embodiment of the present invention can provide a method for operating a display apparatus with a novel structure or a method for operating a display system with a novel structure.

Note that the description of these effects does not preclude the existence of other effects. One embodiment of the present invention does not need to have all the effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a schematic diagram illustrating a structure example of a display system.

FIG. 2A to FIG. 2C are schematic diagrams each illustrating a structure example of a display system.

FIG. 3A and FIG. 3B are schematic diagrams each illustrating a structure example of a display system.

FIG. 4A and FIG. 4B are schematic diagrams each illustrating a structure example of a display system.

FIG. 5 is a schematic diagram illustrating a structure example of a display system.

FIG. 6A and FIG. 6B are schematic diagrams each illustrating a structure example of a display system.

FIG. 7A and FIG. 7B are schematic diagrams each illustrating a structure example of a display system.

FIG. 8 is a flowchart illustrating an operation of a display system.

FIG. 9 is a flowchart illustrating an operation of a display system.

FIG. 10A and FIG. 10B are diagrams illustrating a structure example of a display apparatus.

FIG. 11 is a diagram illustrating a structure example of a display apparatus.

FIG. 12A to FIG. 12C are perspective views of a display module.

FIG. 13A and FIG. 13B are diagrams illustrating a structure example of a display apparatus.

FIG. 14A to FIG. 14D are diagrams each illustrating a structure example of a display apparatus.

FIG. 15A to FIG. 15D are diagrams each illustrating a structure example of a display apparatus.

FIG. 16 is a timing chart showing a driving method of a display apparatus.

FIG. 17A and FIG. 17B are diagrams illustrating a structure example of a display apparatus.

FIG. 18A and FIG. 18B are diagrams each illustrating an operation example of a display apparatus.

FIG. 19A and FIG. 19B are diagrams illustrating a structure example of a display apparatus.

FIG. 20A to FIG. 20D are diagrams illustrating a structure example of a display apparatus.

FIG. 21A to FIG. 21C are diagrams illustrating a structure example of a display apparatus.

FIG. 22 is a block diagram illustrating a structure example of a display apparatus.

FIG. 23 is a block diagram illustrating a structure example of a display apparatus.

FIG. 24A and FIG. 24B are diagrams illustrating a structure example of a display apparatus.

FIG. 25 is a diagram illustrating a structure example of a display apparatus.

FIG. 26 is a diagram illustrating a structure example of a display apparatus.

FIG. 27A to FIG. 27C are diagrams illustrating a structure example of a display apparatus.

FIG. 28A to FIG. 28F are diagrams each illustrating a structure example of a pixel.

FIG. 29A and FIG. 29B are diagrams illustrating a structure example of a display apparatus.

FIG. 30 is a diagram illustrating a structure example of a display apparatus.

FIG. 31 is a diagram illustrating a structure example of a display apparatus.

FIG. 32 is a diagram illustrating a structure example of a display apparatus.

FIG. 33 is a diagram illustrating a structure example of a display apparatus.

FIG. 34 is a diagram illustrating a structure example of a display apparatus.

FIG. 35 is a diagram illustrating a structure example of a display apparatus.

FIG. 36 is a diagram illustrating a structure example of a display apparatus.

FIG. 37A to FIG. 37F are diagrams each illustrating a structure example of a light-emitting device.

FIG. 38A to FIG. 38C are diagrams each illustrating a structure example of a light-emitting device.

FIG. 39A and FIG. 39B are diagrams each illustrating an example of an electronic device.

FIG. 40A and FIG. 40B are diagrams each illustrating an example of an electronic device.

FIG. 41A is a diagram illustrating an example of an electronic device. FIG. 41B is a cross-sectional view illustrating an example of an electronic device.

FIG. 42A to FIG. 42D are diagrams each illustrating an example of an electronic device.

FIG. 43A to FIG. 43G are diagrams each illustrating an example of an electronic device.

FIG. 44A and FIG. 44B are diagrams illustrating an example of an electronic device.

### MODE FOR CARRYING OUT THE INVENTION

Embodiments of the present invention will be described in detail below with reference to the drawings. Note that the present invention is not limited to the following description, and it is readily understood by those skilled in the art that modes and details of the present invention can be modified in various ways. In addition, the present invention should not be construed as being limited to the description of the embodiments below.

The term “electrically connected” includes the case where components are connected through an “object having any electric function”. There is no particular limitation on the “object having any electric function” as long as electric signals can be transmitted and received between the components connected through the object.

The position, size, range, or the like of each component illustrated in drawings and the like is not accurately represented in some cases for easy understanding. Therefore, the disclosed invention is not necessarily limited to the position, size, range, and the like disclosed in the drawings and the like.

Ordinal numbers such as “first”, “second”, and “third” are used to avoid confusion among components.

Note that in the drawings illustrating the present invention, some structures (e.g., the ratio between the size and the thickness of an electrode) are exaggerated for easy understanding in some cases. Furthermore, some components are not illustrated in some cases to avoid complexity of the drawings.

### Embodiment 1

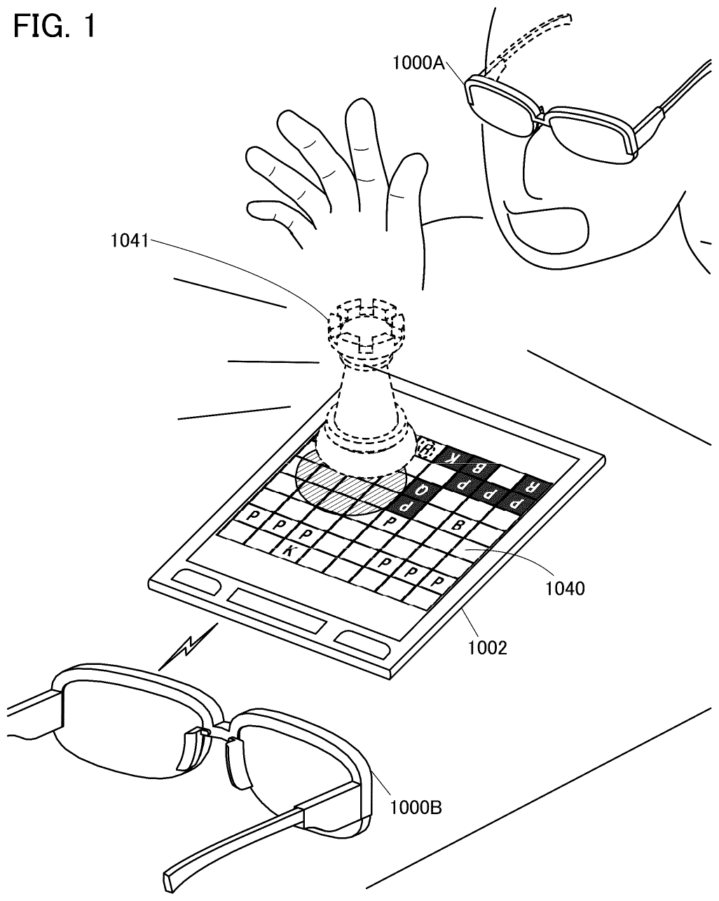

In this embodiment, a display apparatus and a display system of one embodiment of the present invention will be described with reference to FIG. 1 to FIG. 9.

### [Structure Examples of Display Apparatus and Display System]

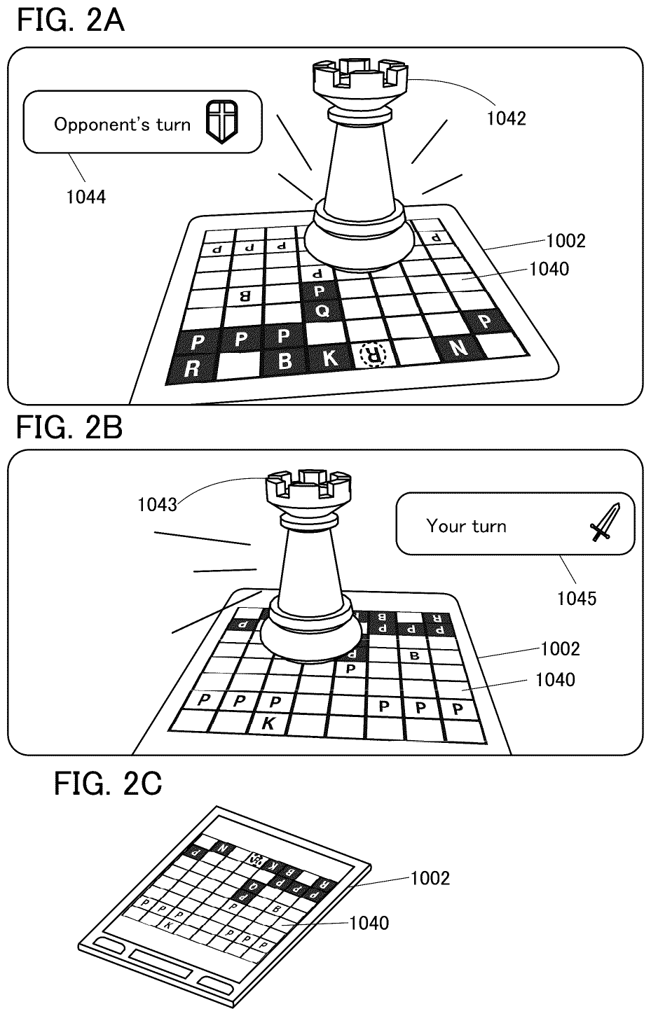

As illustrated in FIG. 1, a display system of one embodiment of the present invention includes a first display apparatus 1000A and a second display apparatus 1002, and each of the first display apparatus 1000A and the second display apparatus 1002 has a communication function. The display system of one embodiment of the present invention may further include a third display apparatus 1000B, and may include four or more display apparatuses. FIG. 1 and FIG. 2 illustrate examples of a display system including the first display apparatus 1000A, the second display apparatus 1002, and the third display apparatus 1000B. The communication function may be a communication function by wire connection but is preferably a communication function without wires (a wireless communication function) in order to improve the usability of the display system.

FIG. 1 is a diagram illustrating a state of playing a one-on-one game match using the display system of one embodiment of the present invention. In the diagram, one game player (a first game player) wears the first display apparatus 1000A (e.g., a glasses-type display apparatus), the other game player (a second game player) wears the third display apparatus 1000B (e.g., a glasses-type display apparatus), and the second display apparatus 1002 (e.g., a tablet-type display apparatus) is placed at a position seen from the first game player and the second game player.

Here, the first game player can see both a display image 1040 of the second display apparatus 1002 and a display image of the first display apparatus 1000A (an image of a three-dimensional virtual object 1041 seen from the position of the first display apparatus 1000A). The second game player can see both the display image 1040 of the second display apparatus 1002 and a display image of the third display apparatus 1000B (an image of the three-dimensional virtual object 1041 seen from the position of the third display apparatus 1000B). A third person (e.g., a spectator) other than the game players can see the display image 1040 of the second display apparatus 1002.

The display image of the first display apparatus 1000A and the display image of the third display apparatus 1000B include images of the same three-dimensional virtual object 1041 that are seen from different positions (views of point). Note that one embodiment of the present invention is not limited thereto, and the first display apparatus 1000A and the third display apparatus 1000B may display different images. It is preferable to freely set whether images of the same three-dimensional virtual object 1041 that are seen from different positions (views of point) are displayed as the display image of the first display apparatus 1000A and the display image of the third display apparatus 1000B.

For example, FIG. 2A illustrates an example of a view of the first game player wearing the first display apparatus 1000A. The first game player can see a display image 1042 (an image of the three-dimensional virtual object 1041 seen from the position of the first display apparatus 1000A) and a display image 1044, which are displayed by the first display apparatus 1000A, and the display image 1040 of the second display apparatus 1002, which is seen through the first display apparatus 1000A. The display image 1044 is an example of the image displayed for the first game player by the first display apparatus 1000A.

Note that in FIG. 2A, the display position of the display image 1042 preferably coincides with the display position of the display image 1040. In the game described in this example, the display image 1042 can be displayed at a position over the display image 1040, which coincides with the position of a piece moved by the first game player and the second game player. In this manner, the first display apparatus 1000A can display the display image 1042 superimposed on a transmission image (e.g., the display image 1040 of the second display apparatus 1002).

Note that in the case where a display portion of the first display apparatus 1000A has a light-transmitting property, the transmission image can be an image that passes through the display portion of the first display apparatus 1000A (referred to a see-through image in some cases). In the case where the first display apparatus 1000A includes an imaging unit (an imaging means such as a camera or an image sensor), the transmission image can be an image captured by the imaging means of the first display apparatus 1000A (referred to a video see-through image in some cases).

That is, the display system of one embodiment of the present invention preferably has a function of obtaining positional information of the first display apparatus 1000A and the second display apparatus 1002 and a function of determining the display position of the display image 1042 on the basis of the obtained positional information. Here, the display position of the display image 1042 can be determined so as to be a predetermined position relative to the display image 1040 seen through the display portion of the first display apparatus 1000A.

For example, the display position of the display image 1042 can be a position overlapping with the display image 1040 seen through the display portion of the first display apparatus 1000A. For another example, the display position of the display image 1042 can be a position apart from the display image 1040 seen through the display portion of the first display apparatus 1000A.

Note that in the operation of the first display apparatus 1000A, the display image 1042 may be displayed in the case where at least part of the display portion of the second display apparatus 1002 can be seen as a transmission image while the display image 1042 is not displayed in the case where the display portion of the second display apparatus 1002 cannot be seen.

FIG. 2B illustrates an example of a view of the second game player wearing the third display apparatus 1000B. The second game player can see a display image 1043 (an image of the three-dimensional virtual object 1041 seen from the position of the third display apparatus 1000B) and a display image 1045, which are displayed by the third display apparatus 1000B, and the display image 1040 of the second display apparatus 1002, which is seen through the third display apparatus 1000B. The display image 1045 is an example of the image displayed for the second game player by the third display apparatus 1000B.

Note that in FIG. 2B, the display position of the display image 1043 preferably coincides with the display position of the display image 1040. In the game described in this example, the display image 1043 can be displayed at a position over the display image 1040, which coincides with the position of a piece moved by the first game player and the second game player.

As illustrated in FIG. 2C, a third person (a spectator) other than the game players can see the display image 1040 of the second display apparatus 1002. That is, even without wearing the first display apparatus 1000A and the third display apparatus 1000B, the third person can obtain part of information of the display system of one embodiment of the present invention from the second display apparatus 1002.

A new visual experience will be possible with the display described in the above example (sometimes referred to as display with collaboration, collaborative display, synchronized display, cooperative display, or the like) combining first display in the first display apparatus such as a glasses-type display apparatus or a goggle-type display apparatus, which can perform AR display, and second display in a general display apparatus such as a tablet-type display apparatus.

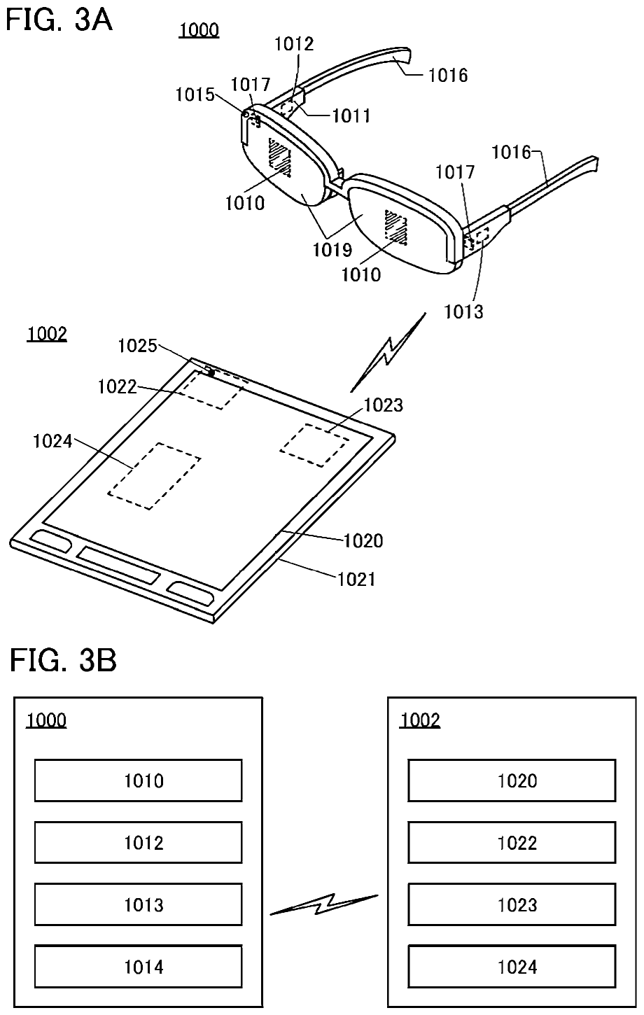

A first display apparatus 1000 and the second display apparatus 1002 included in the display system of one embodiment of the present invention are described with reference to FIG. 3A and FIG. 3B. As in the example described above, a display image of the first display apparatus 1000 is displayed so as to coincide with the position and the display image content of the second display apparatus 1002. That is, the first display apparatus 1000 has a function of obtaining positional information of the first display apparatus 1000 and the second display apparatus 1002. Display portions 1010 of the first display apparatus 1000 have a function of displaying images in accordance with the position of the display image of the second display apparatus 1002.

As illustrated in FIG. 3A and FIG. 3B, the first display apparatus 1000 includes the display portions 1010, a housing 1011, a sensor unit 1012, a communication unit 1013, a control unit 1014, wearing portions 1016, display panels 1017, and optical members 1019. The first display apparatus 1000 may further include a camera unit 1015. Although not illustrated, the first display apparatus 1000 and the second display apparatus 1002 may each include a memory unit.

In the first display apparatus 1000, images displayed by the display panels 1017 can be projected on the display portions 1010 of the optical members 1019. Since the optical members 1019 have a light-transmitting property, a user can see images displayed on display regions, which are superimposed on transmission images seen through the optical members 1019. Thus, the first display apparatus 1000 is an electronic device capable of AR display.

The second display apparatus 1002 includes a display portion 1020, a housing 1021, a sensor unit 1022, a communication unit 1023, and a control unit 1024. The second display apparatus 1002 may further include a camera unit 1025.

As the sensor unit 1012 and the sensor unit 1022, for example, a range sensor (hereinafter also referred to as a sensing portion) capable of measuring the distance from an object may be provided. As the sensor unit 1012, an image sensor or a range image sensor such as LIDAR (Light Detection and Ranging) can be used, for example.

The sensor unit 1012 and the sensor unit 1022 may include an acceleration sensor such as a gyroscope sensor. With the use of images obtained by the camera unit 1015 and the camera unit 1025 and images obtained by the range image sensors included in the sensor unit 1012 and the sensor unit 1022, a larger amount of information can be obtained to provide more accurate positional information.

As illustrated in FIG. 3B, wireless communication can be performed between the communication unit 1013 included in the first display apparatus 1000 and the communication unit 1023 included in the second display apparatus 1002.

The communication unit includes a wireless communication device, and a video signal and the like can be supplied by the wireless communication device. Note that instead of the wireless communication device or in addition to the wireless communication device, a connector to which a cable for supplying a video signal and a power supply potential can be connected may be provided. The first display apparatus 1000 and the second display apparatus 1002 can be paired with each other using the communication unit 1013 and the communication unit 1023.

The communication between the first display apparatus 1000 and the second display apparatus 1002 may be direct communication or communication via a relay device. Examples of the relay device that can be used include wireless routers such as Wi-Fi (registered trademark) electronic devices such as smartphones, electronic devices such as PCs (personal computers), and servers connected through the Internet or the like.

The display image 1042 of the first display apparatus 1000A (an image of the three-dimensional virtual object 1041 seen from the position of the first display apparatus 1000A), which is described with reference to FIG. 1 and FIG. 2, can be generated in the control unit 1014.

Alternatively, the display image 1042 of the first display apparatus 1000A can be generated in the control unit 1014 included in the second display apparatus 1002. The first display apparatus 1000 capable of AR display is a display apparatus having the shape of glasses and the like and worn on the head, which has limited available power and space for mounting the control unit 1014. Meanwhile, in the second display apparatus 1002 (e.g., a tablet) with a large display area, the control unit 1024 can be mounted in a larger space and can use higher power than the control unit 1014. Thus, the data of the display image 1042 generated in the control unit 1024 is transmitted from the communication unit 1023 to the communication unit 1013 and displayed on the display portions 1010, which reduces the arithmetic load of the control unit 1014 included in the first display apparatus 1000 and accordingly allows the first display apparatus 1000 to be used for a long time. Note that the control unit 1024 preferably includes a GPU (Graphics Processing Unit).

Note that the display portions 1010 of the first display apparatus 1000 preferably have a display function capable of recognizing three-dimensional images in binocular vision (for example, the left and right display portions preferably have binocular parallax), in which case more dynamic visual expression is possible.

A touch sensor module may be provided in the housing 1011. The touch sensor module has a function of detecting a touch on the outer surface of the housing 1011. A tap operation, a slide operation, or the like by the user can be detected with the touch sensor module, whereby a variety of processing can be executed. For example, processing such as a pause or a restart of a moving image can be executed by a tap operation, and processing such as fast forward and fast rewind can be executed by a slide operation. When the touch sensor module is provided in each of the two housings 1011, the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case where an optical touch sensor is used, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

In addition, the first display apparatus 1000 is provided with a battery so that charging can be performed wirelessly and/or by wire.

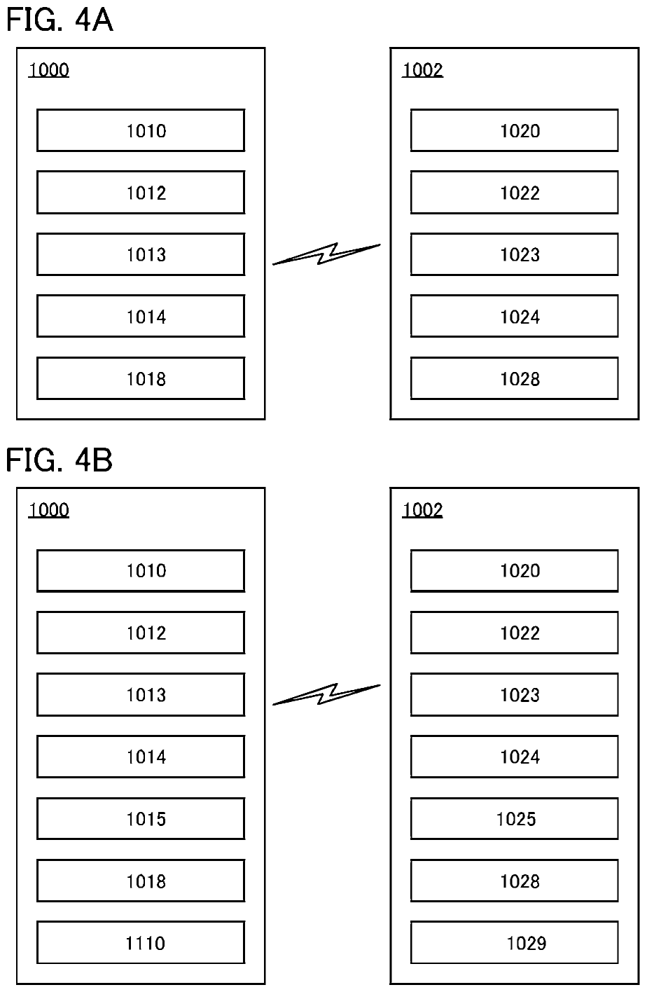

As illustrated in FIG. 4A, the first display apparatus 1000 includes the display portion 1010, the sensor unit 1012, the communication unit 1013, the control unit 1014, and a power supply unit 1018. As illustrated in FIG. 4A, the second display apparatus 1002 includes the display portion 1020, the sensor unit 1022, the communication unit 1013, the control unit 1024, and a power supply unit 1028.

Note that although FIG. 3B and FIG. 4A each illustrate a structure in which the first display apparatus 1000 and the second display apparatus 1002 have the same function, the structure is not limited to this example. For example, as illustrated in FIG. 4B, the first display apparatus 1000 and the second display apparatus 1002 may have different functions.

In FIG. 4B, the first display apparatus 1000 includes the camera unit 1015 and a headphone unit 1110 in addition to the structure illustrated in FIG. 4A. The second display apparatus 1002 includes the camera unit 1025 and a second communication unit 1029 in addition to the structure illustrated in FIG. 4A. The camera unit 1015 may include an imaging unit such as an image sensor. Moreover, a plurality of cameras may be provided so as to cover a plurality of fields of view, such as a telescope field of view and a wide field of view. The second communication unit 1029 may have a communication function different from that of the communication unit 1023. For example, the communication unit 1023 has a function of performing communication with the communication unit 1013, and the second communication unit 1029 may have a function capable of audio call or a communication means capable of electronic payment or the like, utilizing the third-generation mobile communication system (3G), the fourth-generation mobile communication system (4G), the fifth-generation mobile communication system (5G), or the like.

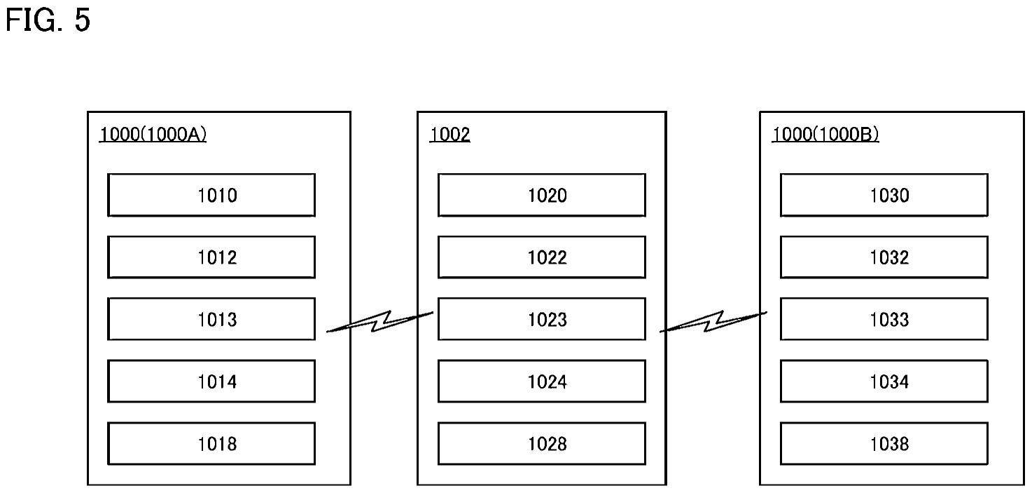

Note that FIG. 3 and FIG. 4 each illustrate an example of communication between the two apparatuses of the first display apparatus 1000 and the second display apparatus 1002; however, one embodiment of the present invention is not limited thereto. For example, as illustrated in FIG. 5, the display system may further include the third display apparatus 1000 (1000B) in addition to the first display apparatus 1000 (1000A) and the second display apparatus 1002. The display system may include a larger number of display apparatuses.

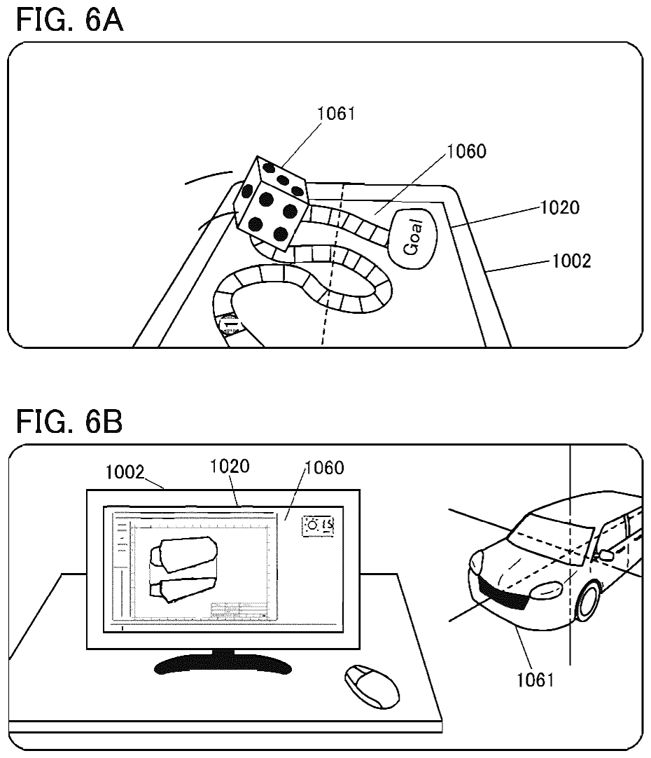

FIG. 1 and FIG. 2 each illustrate an example in which a one-on-one game match (chess) is played using the display system of one embodiment of the present invention; the display system of one embodiment of the present invention can be used for a variety of applications. For example, as the game match other than chess, Shogi, reversi, and other game matches can also be played. The display system of one embodiment of the present invention can be used conveniently because products such as game boards and pieces do not need to be prepared for each game and can be displayed on the first display apparatus and the second display apparatus. The display system can also be used by a large number of people, such as in a game of Sugoroku illustrated in FIG. 6A. FIG. 6A is a schematic diagram showing a view of the first display apparatus 1000 (e.g., a glasses-type display apparatus) like FIG. 2A and FIG. 2B. FIG. 6A illustrates a state in which the user wearing the first display apparatus 1000 can see a display image 1060 displayed on the second display apparatus 1002 through the display portion of the first display apparatus 1000, and a display image 1061 is displayed at a position overlapping with the display image 1060. Note that FIG. 6A illustrates an example in which a display apparatus that can be folded in a dashed line is used as the second display apparatus 1002. The display apparatus that can be folded is preferably used as the second display apparatus 1002 because space saving is possible and excellent storage and convenience are achieved.

In the example illustrated in FIG. 1 and the like, a first game player wearing the first display apparatus 1000A and a second game player wearing the third display apparatus 1000B play the game face to face in the same location; however, the display system of one embodiment of the present invention is not limited to this example. For example, in the case where the communication unit included in the first display apparatus 1000 or the second display apparatus 1002 has a communication function such as the Internet as described later, playing the game with a remote game player (a game player not in the same location) is possible. For example, game players not in the same location respectively have the first display apparatus 1000 and the second display apparatus 1002, thereby enjoying realistic visual experience and game experience. Note that the communication between the display apparatuses not in the same location may be direct communication between the apparatuses or communication via a server provided separately.

The application of the display system of one embodiment of the present invention is not limited to the above-described application for amusement. The display system can be used in the manner illustrated in FIG. 6B, for example: when a desktop PC (personal computer) including the second display apparatus 1002 is used for design (e.g., CAD), the second display apparatus 1002 displays a two-dimensional image (the display image 1060), and the first display apparatus 1000 displays a three-dimensional image (the display image 1061) corresponding to the two-dimensional image. Note that the display image 1061 may be displayed at a position not overlapping with the display image 1060 as illustrated in FIG. 6B. In that case, design can be performed while the three-dimensional image is checked.

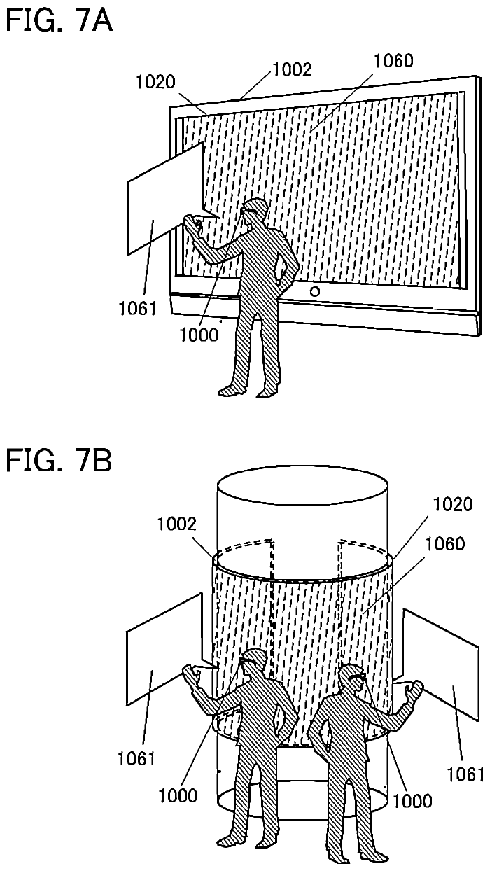

The application of the display system of one embodiment of the present invention is not limited to personal use. For example, as illustrated in FIG. 7A and FIG. 7B, the display system may have a configuration in which the first display apparatus 1000 (e.g., a glasses-type display apparatus) and the second display apparatus 1002 used as digital signage can work in conjunction with each other. FIG. 7A illustrates the first display apparatus 1000 (e.g., a glasses-type display apparatus) and the second display apparatus 1002 used as digital signage with a planar shape. The first display apparatus 1000 displays the display image 1061, which relates to part of content displayed by the display image 1060 of the second display apparatus 1002.

FIG. 7B illustrates the first display apparatuses 1000 (e.g., glasses-type display apparatuses) and the second display apparatus 1002 used as digital signage with a curved surface. The first display apparatus 1000 displays the display image 1061, which relates to part of content displayed by the display image 1060 of the second display apparatus 1002. As illustrated in FIG. 7B, two more persons may wear the first display apparatuses 1000.

As in the examples illustrated in FIG. 7A and FIG. 7B, the first display apparatus 1000 owned privately and the public second display apparatus 1002 (owned by facilities and the like) can display images in conjunction with each other, that is, the display apparatuses with different owners can be linked with each other.

Next, the components of the display apparatuses and the display systems of one embodiment of the present invention illustrated in FIG. 1 to FIG. 7 will be described below.

### <Display Portion and Display Panel>

The display portion 1010, the display portion 1020, and the display panel 1017 each have a function of performing display. For the display portion 1010, the display portion 1020, and the display panel 1017, one or more of a liquid crystal display device, a light-emitting device including an organic EL, and a light-emitting device including a light-emitting diode such as a micro LED can be used, for example. In the case where productivity and emission efficiency are considered, for the display portion 1010, the display portion 1020, and the display panel 1017, a light-emitting device including an organic EL is preferably used.

### <Sensor Unit>

The sensor unit 1012 and the sensor unit 1022 have a function of obtaining information related to the positions of the first display apparatus 1000 and the second display apparatus 1002. More specifically, the sensor unit 1022 has a function of measuring at least one of force, displacement, position, speed, acceleration, angular velocity, rotational frequency, distance, light, magnetism, temperature, sound, time, electric field, current, voltage, electric power, radiation, humidity, gradient, oscillation, a smell, and infrared rays.

The sensor unit 1012 and the sensor unit 1022 may each have a function of sensing a user's gaze with the use of data obtained by the above functions (e.g., imaging data such as light). The gaze can be sensed by, for example, a pupil centre corneal reflection (PCCR) method or a bright/dark pupil effect method.

The sensor unit 1012 preferably has a function of measuring brain waves in addition to the above function of the sensor unit 1022. For example, the sensor unit 1012, which has a plurality of electrodes in contact with the user's head, can have a mechanism of measuring brain waves from a weak current flowing through the electrodes. When the sensor unit 1012 has a function of measuring brain waves, the user can operate the first display apparatus 1000 and/or the second display apparatus 1002 according to his/her thoughts. In this case, the user does not need to use both hands to operate the display apparatus and can perform an input operation or the like with nothing in the hands (with both hands being free).

### <Communication Unit>

The communication unit 1013 and the communication unit 1023 each have a wireless or wired communication function. It is suitable that the communication unit 1013 and the communication unit 1023 have, in particular, a function of wireless communication so that the number of components such as a cable for connection can be reduced.

In the case where the communication unit 1013 and the communication unit 1023 each have a wireless communication function, the communication unit 1013 and the communication unit 1023 can communicate via an antenna. As for the communication means (communication method) between the communication unit 1013 and the communication unit 1023, for example, the communication can be performed in such a manner that each device is connected to a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA2000 (Code Division Multiple Access 2000), or W-CDMA (registered trademark), or a communications standard developed by IEEE such as Wi-Fi (registered trademark), Bluetooth (registered trademark), or ZigBee (registered trademark).

### <Control Unit>

The control unit 1014 and the control unit 1024 each have a function of controlling the display portion. The control unit 1014 and the control unit 1024 each include a pixel circuit, a backup circuit, and an image conversion circuit, for example. Note that the image conversion circuit can perform three-dimensional image data construction processing, conversion processing from three-dimensional image data to two-dimensional image data, and up-conversion or down-conversion processing of image data.

The control unit 1014 and the control unit 1024 interpret and execute instructions from various programs with a processor to process various kinds of data and control programs. Programs that might be executed by the processor may be stored in a memory region of the processor or may be stored in another storage unit.

A CPU and other microprocessors such as a DSP (Digital Signal Processor) and a GPU can be used alone or in combination as the control unit 1014 and the control unit 1024. A structure may be employed in which such a microprocessor is obtained with a PLD (Programmable Logic Device) such as an FPGA (Field Programmable Gate Array) or an FPAA (Field Programmable Analog Array).

The control unit 1014 and the control unit 1024 may each include a main memory. The main memory can include a volatile memory such as a RAM (Random Access Memory) or a nonvolatile memory such as a ROM (Read Only Memory).

For example, a DRAM (Dynamic Random Access Memory) is used as the RAM provided in the main memory, in which case a memory space as a workspace for the control unit 1014 and the control unit 1024 is virtually allocated and used. An operating system, an application program, a program module, program data, and the like that are stored in the storage portion are loaded into the RAM to be executed. The data, program, program module, and the like which are loaded into the RAM are directly accessed and operated by the control unit 1014 and the control unit 1024.

Meanwhile, a BIOS (Basic Input/Output System), firmware, and the like for which rewriting is not needed can be stored in the ROM. As the ROM, a mask ROM, an OTPROM (One Time Programmable Read Only Memory), an EPROM (Erasable Programmable Read Only Memory), or the like can be used. Examples of the EPROM include a UV-EPROM (Ultra-Violet Erasable Programmable Read Only Memory) which can erase stored data by ultraviolet irradiation, an EEPROM (Electrically Erasable Programmable Read Only Memory), and a flash memory.

The control unit 1014 and the control unit 1024 preferably include a processor specialized for parallel arithmetic operation as compared with a CPU. For example, a processor that includes a large number of (several tens to several hundreds of) processor cores capable of performing parallel processing, such as a GPU, a TPU (Tensor Processing Unit), or an NPU (Neural Processing Unit), is preferably included. Accordingly, the control unit 1014 and the control unit 1024 can especially perform arithmetic operation by a neural network at high speed.

### <Storage Unit>

As the storage unit, a storage device using a nonvolatile storage element, such as a flash memory, an MRAM (Magnetoresistive Random Access Memory), a PRAM (Phase change RAM), an ReRAM (Resistive RAM), or an FeRAM (Ferroelectric RAM); a storage device using a volatile storage element, such as a DRAM (Dynamic RAM) or an SRAM (Static RAM); or the like may be used, for example. A recording media drive such as a hard disk drive (HDD) or a solid state drive (SSD) may also be used, for example.

### <Power Supply Unit>

The power supply unit 1018 and the power supply unit 1028 each have a function of supplying electric power to the display portion. As the power supply unit 1018 and the power supply unit 1018, a primary battery or a secondary battery can be used, for example. As the secondary battery, a lithium-ion secondary battery can be preferably used, for example.

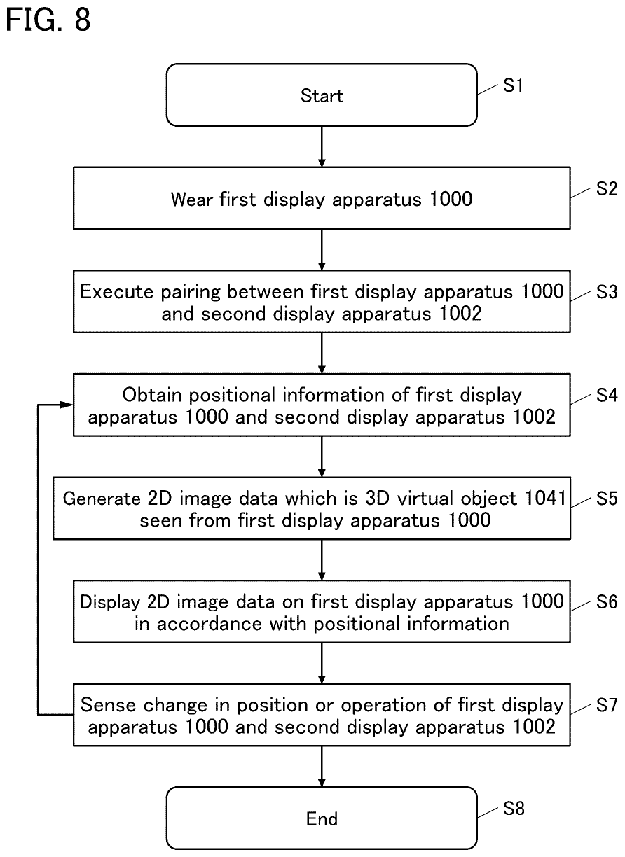

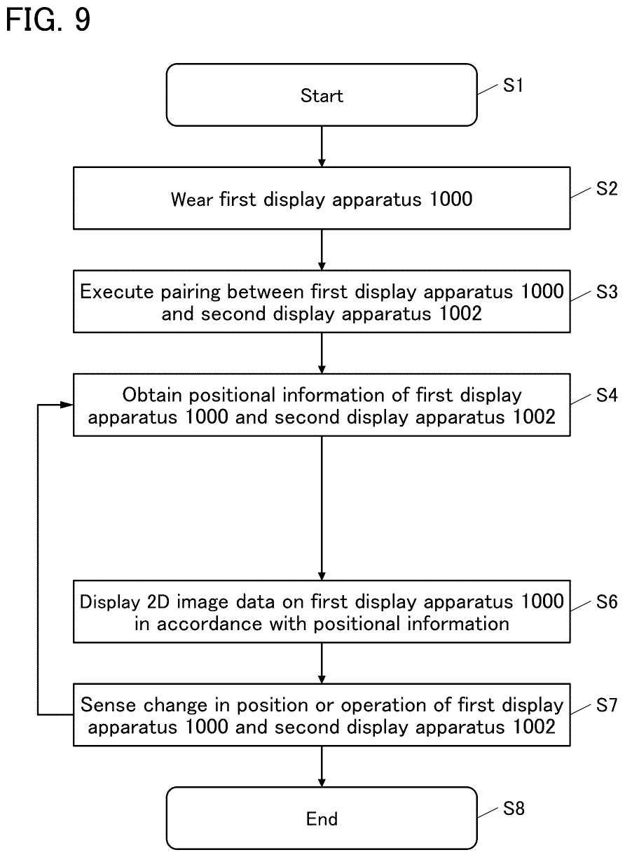

Next, an example of an operation method of the display system of one embodiment of the present invention will be described with reference to FIG. 8 and FIG. 9.

### [Operation Method Example of Display System]

An example of an operation method of the display system will be described below. FIG. 8 is a flowchart for the operation method of the display system.

In Step S1, the operation starts. At this time, the first display apparatus 1000 is in a start-up state (a state where a manipulation is possible), and the second display apparatus 1002 is in a power-on state.

In Step S2, the first display apparatus 1000 is worn. The first display apparatus 1000 recognizes being worn, and the system starts. In Step S2, for example, when the first display apparatus 1000 has a glasses-type shape, an image of the front view of a camera may be presented to the user or an image of another content may be displayed.

In Step S3, pairing between the first display apparatus 1000 and the second display apparatus 1002 is executed. When the pairing is completed, the first display apparatus 1000 and the second display apparatus 1002 are in a state where two-way data communication is possible.

In Step S4, the first display apparatus 1000 obtains positional information of the first display apparatus 1000 and the second display apparatus 1002.

In Step S5, two-dimensional image data (e.g., the display image 1042 illustrated in FIG. 2A), which is a three-dimensional virtual object (e.g., the three-dimensional virtual object 1041 illustrated in FIG. 1) seen from the first display apparatus 1000, is generated.

In Step S6, the image data generated in Step S5 is displayed on the display portions 1010 of the first display apparatus 1000 in accordance with the positional information.

In Step S7, in the case where the sensor unit included in the first display apparatus 1000 or the second display apparatus 1002 senses a change in the position of the first display apparatus 1000 or the second display apparatus 1002, the processing proceeds to Step S4. Also in the case where any operation is performed in the first display apparatus 1000 or the second display apparatus 1002, the processing proceeds to Step S4 so that processing corresponding to the operation is performed.

In Step S8, the processing ends. Step S8 corresponds to detaching the first display apparatus 1000, turning off the power of the first display apparatus 1000 or the second display apparatus 1002, or canceling the pairing between the first display apparatus 1000 and the second display apparatus 1002, for example.

The above is the description of the operation method example of the display system of one embodiment of the present invention. The flowchart shown in FIG. 8 includes Step S5 of generating the two-dimensional image data, which is the three-dimensional virtual object seen from the first display apparatus 1000; however, processing in Step S5 is not necessarily performed. For example, in the case where the first display apparatus 1000 displays only planar content, the operation method of the display system without Step S5 may be employed as illustrated in FIG. 9.

Although the first display apparatus 1000 capable of AR display is described as a display apparatus with a glasses-type shape worn on the head in the above example, one embodiment of the present invention is not limited to this shape. Even a display apparatus that is not worn on the head, such as a smartphone or a tablet, can be used as the first display apparatus 1000 when including an imaging means (e.g., a camera or an image sensor) and being capable of AR display.

As described above, with the use of the display apparatus and the display system of one embodiment of the present invention, a display apparatus with a novel structure or a display system with a novel structure can be provided. With the use of the display apparatus and the display system of one embodiment of the present invention, an operation method of a display apparatus with a novel structure or an operation method of a display system with a novel structure can be provided. With the use of the display apparatus and the display system of one embodiment of the present invention, realistic display and a variety of expressions can be achieved.

This embodiment can be combined with the description in any of the other embodiments.

### Embodiment 2

Hereinafter, a structure example of a display apparatus applicable to the display apparatus of the electronic device described as an example in Embodiment 1 will be described with reference to drawings.

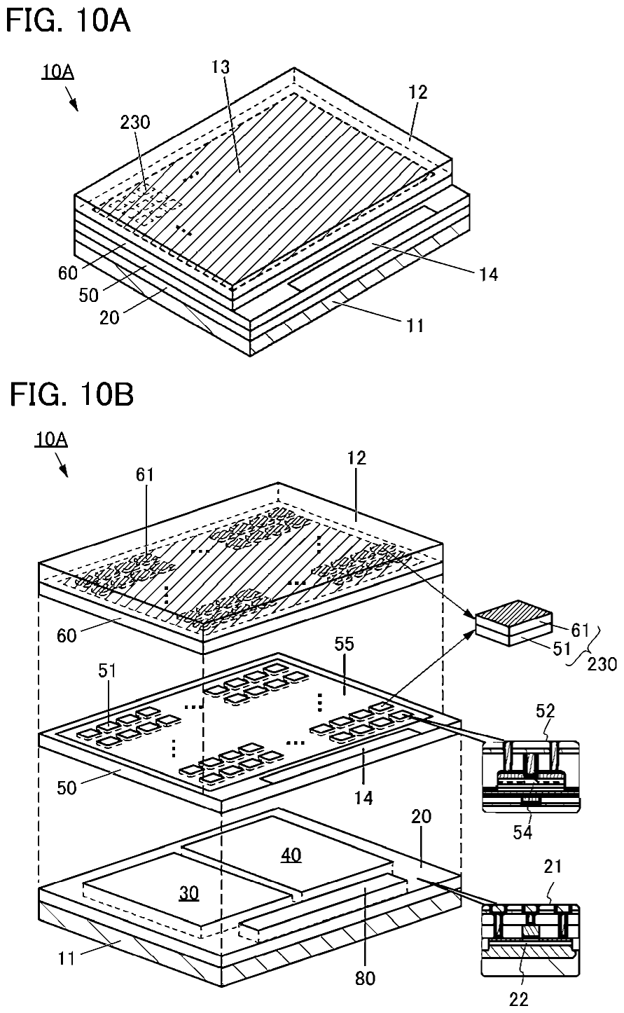

FIG. 10A is a perspective view of a display apparatus 10A applicable to the display apparatus of the electronic device described as an example in Embodiment 1. The display apparatus 10A can be used as each of the first display apparatus 1000 and the second display apparatus 1002.

The display apparatus 10A includes a substrate 11 and a substrate 12. The display apparatus 10A includes a display portion 13 composed of elements provided between the substrate 11 and the substrate 12. The display portion 13 is a region where an image is displayed in the display apparatus 10A. The display portion 13 includes a plurality of pixels 230. The pixel 230 includes a pixel circuit 51 and a light-emitting element 61.

By using the pixels 230 arranged in a matrix of 1920×1080 pixels, the display portion 13 can achieve display with a definition of a so-called full hi-vision (also referred to as “2K definition”, “2K1K”, “2K”, or the like). For example, by using the pixels 230 arranged in a matrix of 3840×2160 pixels, the display portion 13 can achieve display with a definition of a so-called ultra hi-vision (also referred to as “4K definition”, “4K2K”, “4K”, or the like). For example, by using the pixels 230 arranged in a matrix of 7680×4320 pixels, the display portion 13 can achieve display with a definition of a so-called super hi-vision (also referred to as “8K definition”, “8K4K”, “8K”, or the like). By increasing the number of pixels 230, the display portion 13 that can perform display with 16K or 32K definition can also be obtained.

Furthermore, the pixel density (resolution) of the display portion 13 is preferably higher than or equal to 1000 ppi and lower than or equal to 10000 ppi. For example, the resolution may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 13. For example, the display portion 13 is compatible with a variety of screen ratios such as 1:1 (a square), 4:3, 16:9, and 16:10.

In this specification and the like, the term “element” can be replaced with the term “device” in some cases. For example, a display element, a light-emitting element, and a liquid crystal element can be rephrased as a display device, a light-emitting device, and a liquid crystal device, respectively.

Various kinds of signals and power supply potentials are input to the display apparatus 10A from the outside via a terminal portion 14, so that image display can be performed using a display element provided in the display portion 13. Any of a variety of elements can be used as the display element. Typically, a light-emitting element having a function of emitting light, such as an organic EL element or an LED element, a liquid crystal element, a MEMS (Micro Electro Mechanical Systems) element, or the like can be used.

A plurality of layers are provided between the substrate 11 and the substrate 12, and each of the layers is provided with a transistor for a circuit operation, or a display element which emits light. A pixel circuit having a function of controlling an operation of the display element, a driver circuit having a function of controlling the pixel circuit, a functional circuit having a function of controlling the driver circuit, and the like are provided in the plurality of layers.

FIG. 10B is a perspective view schematically illustrating the structures of the layers provided between the substrate 11 and the substrate 12.

A layer 20 is provided over the substrate 11. The layer 20 includes a driver circuit 30, a functional circuit 40, and an input/output circuit 80. The layer 20 includes a transistor 21 containing silicon in a channel formation region 22 (such a transistor is also referred to as a Si transistor). The substrate 11 is, for example, a silicon substrate. A silicon substrate is preferable because it has higher thermal conductivity than a glass substrate. By providing the driver circuit 30, the functional circuit 40, and the input/output circuit 80 in the same layer, wirings electrically connecting the driver circuit 30, the functional circuit 40, and the input/output circuit 80 can be short. As a result, charge and discharge time of a control signal used when the functional circuit 40 controls the driver circuit 30 becomes short, leading to a reduction in power consumption. In addition, charge and discharge time during which a signal is supplied from the input/output circuit 80 to the functional circuit 40 and the driver circuit 30 becomes short, leading to a reduction in power consumption.

The transistor 21 can be a transistor containing single crystal silicon in its channel formation region (also referred to as a “c-Si transistor”), for example. In particular, the use of a transistor containing single crystal silicon in a channel formation region as the transistor provided in the layer 20 can increase the on-state current of the transistor. This enables high-speed driving of circuits included in the layer 20 and is thus preferable. The Si transistor can be formed by microfabrication to have a channel length greater than or equal to 3 nm and less than or equal to 10 nm, for example; thus, a CPU, an accelerator such as a GPU, an application processor, or the like can be integral with the display portion in the display apparatus 10A.

A transistor containing polycrystalline silicon in its channel formation region (also referred to as a “Poly-Si transistor”) may be provided in the layer 20. As the polycrystalline silicon, low-temperature polysilicon (LTPS) may be used. Note that a transistor containing LTPS in its channel formation region is also referred to as an “LTPS transistor”. An OS transistor may be provided in the layer 20.

Any of a variety of circuits such as a shift register, a level shifter, an inverter, a latch, an analog switch, and a logic circuit can be used as the driver circuit 30. The driver circuit 30 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 13, the width of a non-display region (also referred to as a bezel) provided along the outer periphery of the display portion 13 of the display apparatus 10A can be extremely narrow compared with the case where these circuits and the display portion 13 are arranged side by side, whereby the display apparatus 10A can be reduced in size.

The functional circuit 40 has a function of an application processor for controlling the circuits in the display apparatus 10A and generating signals used for controlling the circuits, for example. The functional circuit 40 may include a CPU and a circuit used for correcting image data such as a GPU. The functional circuit 40 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the display apparatus 10A. The functional circuit 40 may include a circuit for compressing and decompressing image data and a power supply circuit, for example.

A layer 50 is provided over the layer 20. The layer 50 includes a pixel circuit group 55 including a plurality of pixel circuits 51. The layer 50 may include a transistor 52 containing a metal oxide in its channel formation region 54. In other words, an OS transistor may be provided in the layer 50. Each of the pixel circuits 51 may include an OS transistor. Note that the layer 50 can be stacked over the layer 20.

A Si transistor may be provided in the layer 50. For example, the pixel circuits 51 may each include a transistor containing single crystal silicon or polycrystalline silicon in its channel formation region. As the polycrystalline silicon, LTPS may be used. For example, the layer 50 can be formed over another substrate and bonded to the layer 20.

As another example, the pixel circuits 51 may each include a plurality of kinds of transistors using different semiconductor materials. In the case where the pixel circuits 51 each include a plurality of kinds of transistors using different semiconductor materials, the transistors may be provided in different layers for each kind of transistor. For example, in the case where the pixel circuits 51 each include a Si transistor and an OS transistor, the Si transistor and the OS transistor may be provided to overlap with each other. Providing the transistors to overlap with each other reduces the area occupied by the pixel circuits 51. Thus, the resolution of the display apparatus 10A can be improved. Note that a structure in which an LTPS transistor and an OS transistor are combined is referred to as LTPO in some cases.

It is preferable to use, as the transistor 52 that is an OS transistor, a transistor including an oxide containing at least one of indium, an element M (the element M is aluminum, gallium, yttrium, or tin), and zinc in a channel formation region. Such an OS transistor has a characteristic of an extremely low off-state current. Thus, it is particularly preferable to use the OS transistor as a transistor provided in the pixel circuit, in which case analog data written to the pixel circuit can be retained for a long period.

A layer 60 is provided over the layer 50. Over the layer 60, the substrate 12 is provided. The substrate 12 is preferably a light-transmitting substrate or a layer formed of a light-transmitting material. The layer 60 includes a plurality of light-emitting elements 61. The layer 60 can be stacked over the layer 50. As the light-emitting element 61, an organic electroluminescent element (also referred to as an organic EL element) or the like can be used, for example. However, the light-emitting element 61 is not limited thereto, and an inorganic EL element formed of an inorganic material may be used, for example. Note that an “organic EL element” and an “inorganic EL element” are collectively referred to as “EL element” in some cases. The light-emitting element 61 may contain an inorganic compound such as quantum dots. For example, when used for a light-emitting layer, the quantum dots can function as a light-emitting material.

As illustrated in FIG. 10B, the display apparatus 10A of one embodiment of the present invention can have a structure in which the light-emitting elements 61, the pixel circuits 51, the driver circuit 30, and the functional circuit 40 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 51 can be arranged extremely densely, and thus the resolution of the pixels can be extremely high. For example, the pixels can be arranged in the display portion 13 of the display apparatus 10A (a region where the pixel circuits 51 and the light-emitting elements 61 are stacked) with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display apparatus 10A described above has an extremely high resolution, and thus can be suitably used for a device for VR such as a head-mounted display or a glasses-type device for AR. For example, even in the case of a structure in which the display portion of the display apparatus 10A is seen through an optical member such as a lens, pixels of the extremely-high-resolution display portion included in the display apparatus 10A are not seen when the display portion is magnified by the lens, so that display providing a high sense of immersion can be performed.

Note that in the case where the display apparatus 10A is used as a wearable display apparatus for VR or AR, the display portion 13 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 13 may have a diagonal size of 1.5 inches or approximately 1.5 inches. When the display portion 13 has a diagonal size less than or equal to 2.0 inches, the number of times of light exposure treatment using a light exposure apparatus (typically, a scanner apparatus) can be one; thus, the productivity of a manufacturing process can be improved.

The display apparatus 10A according to one embodiment of the present invention can be used for an electronic device other than a wearable electronic device. In that case, the display portion 13 can have a diagonal size greater than 2.0 inches. The structure of transistors used in the pixel circuits 51 may be selected as appropriate depending on the diagonal size of the display portion 13. In the case where single crystal Si transistors are used in the pixel circuits 51, for example, the diagonal size of the display portion 13 is preferably greater than or equal to 0.1 inches and less than or equal to 3 inches. In the case where LTPS transistors are used in the pixel circuits 51, the diagonal size of the display portion 13 is preferably greater than or equal to 0.1 inches and less than or equal to 30 inches, further preferably greater than or equal to 1 inch and less than or equal to 30 inches. In the case where LTPO transistors are used in the pixel circuits 51, the diagonal size of the display portion 13 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 13 is preferably greater than or equal to 0.1 inches and less than or equal to 200 inches, further preferably greater than or equal to 50 inches and less than or equal to 100 inches.

A size increase of a display apparatus using single crystal Si transistors is extremely difficult because a size increase of a single crystal Si substrate is difficult. Furthermore, in the case where LTPS transistors are used in a display apparatus, LTPS transistors are unlikely to respond to a size increase (typically to a screen diagonal size greater than 30 inches) since a laser crystallization apparatus is used in the manufacturing process. By contrast, since the manufacturing process does not necessarily require a laser crystallization apparatus or the like or can be performed at a relatively low process temperature (typically, lower than or equal to 450° C.), OS transistors can be used for a display apparatus with a relatively large area (typically, a diagonal size greater than or equal to 50 inches and less than or equal to 100 inches). In addition, LTPO is compatible with a diagonal size between sizes when using LTPS transistors and when using OS transistors (typically, greater than or equal to 1 inch and less than or equal to 50 inches).

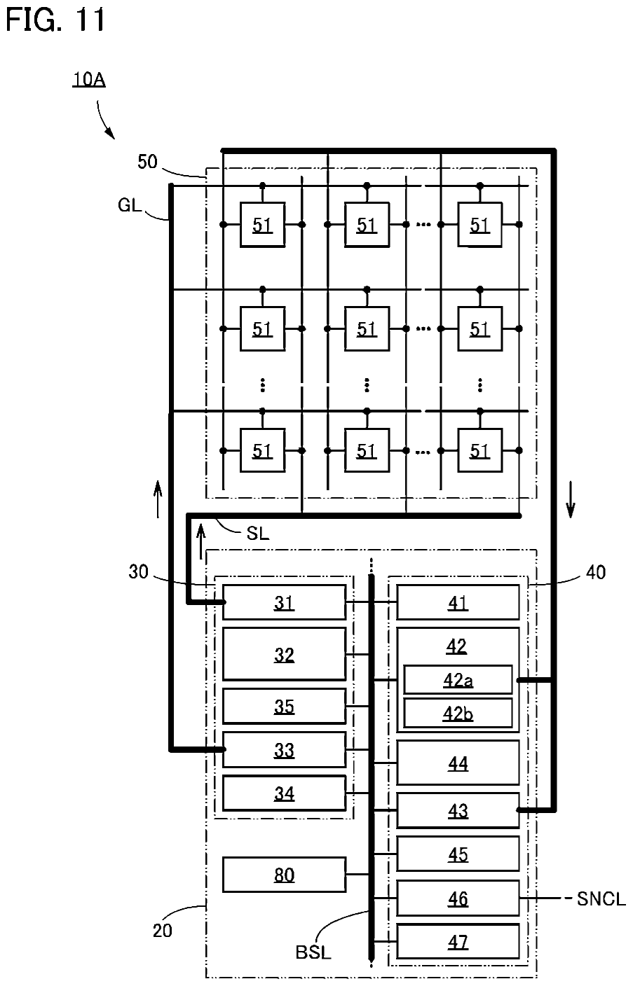

Specific structure examples of the driver circuit 30 and the functional circuit 40 will be described with reference to FIG. 11. FIG. 11 is a block diagram illustrating the pixel circuits 51, the driver circuit 30, and the functional circuit 40 in the display apparatus 10A, a plurality of wirings connecting the pixel circuits 51, the driver circuit 30, and the functional circuit 40, a bus wiring in the display apparatus 10A, and the like.

In the display apparatus 10A illustrated in FIG. 11, the plurality of pixel circuits 51 are arranged in a matrix in the layer 50.

Furthermore, the driver circuit 30, the functional circuit 40, and the input/output circuit 80 are provided in the layer 20 in the display apparatus 10A illustrated in FIG. 11. The driver circuit 30 includes, for example, a source driver circuit 31, a digital-to-analog converter (DAC) circuit 32, an amplifier circuit 35, a gate driver circuit 33, and a level shifter 34. The functional circuit 40 includes, for example, a storage device 41, a GPU (AI accelerator) 42, an EL correction circuit 43, a timing controller 44, a CPU 45, a sensor controller 46, and a power supply circuit 47. The functional circuit 40 has a function of an application processor.

The input/output circuit 80 is compatible with a transmission method such as LVDS (Low Voltage Differential Signaling), and the input/output circuit 80 has a function of dividing control signals, image data, and the like input via the terminal portion 14 between the driver circuit 30 and the functional circuit 40. Furthermore, the input/output circuit 80 has a function of outputting information of the display apparatus 10A to the outside via the terminal portion 14. In the display apparatus 10A in FIG. 11, an example of a structure in which the circuits included in the driver circuit 30 and the circuits included in the functional circuit 40 are each electrically connected to a bus wiring BSL is illustrated.

The source driver circuit 31 has a function of transmitting image data to the pixel circuits 51 included in the pixels 230, for example. Thus, the source driver circuit 31 is electrically connected to the pixel circuits 51 through a wiring SL. Note that a plurality of source driver circuits 31 may be provided.

The digital-to-analog converter circuit 32 has a function of converting image data that has been digitally processed by a GPU, a correction circuit, or the like described later, into analog data, for example. The image data converted into analog data is amplified by the amplifier circuit 35 such as an operational amplifier and is transmitted to the pixel circuits 51 via the source driver circuit 31. Note that the image data may be transmitted to the source driver circuit 31, the digital-to-analog converter circuit 32, and the pixel circuits 51 in this order. The digital-to-analog converter circuit 32 and the amplifier circuit 35 may be included in the source driver circuit 31.

The gate driver circuit 33 has a function of selecting the pixel circuit to which image data is to be transmitted among the pixel circuits 51, for example. Thus, the gate driver circuit 33 is electrically connected to the pixel circuits 51 through a wiring GL. Note that a plurality of gate driver circuits 33 may be provided such that the number of the gate driver circuits 33 corresponds to the number of the source driver circuits 31.

The level shifter 34 has a function of converting signals to be input to the source driver circuit 31, the digital-to-analog converter circuit 32, the gate driver circuit 33, and the like into appropriate levels, for example.

The storage device 41 has a function of storing image data to be displayed by the pixel circuits 51, for example. Note that the storage device 41 can be configured to store the image data as digital data or analog data.

In the case where the storage device 41 stores image data, the storage device 41 is preferably a nonvolatile memory. In that case, a NAND memory or the like can be used as the storage device 41, for example.

In the case where the storage device 41 stores temporary data generated in the GPU 42, the EL correction circuit 43, the CPU 45, or the like, the storage device 41 is preferably a volatile memory. In that case, an SRAM (Static Random Access Memory), a DRAM (Dynamic Random Access Memory), or the like can be used as the storage device 41, for example.

The GPU 42 has a function of performing processing for outputting, to the pixel circuits 51, image data read from the storage device 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 10A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with the properties of the light-emitting device may be provided in the functional circuit 40. The functional circuit 40 includes, for example, the EL correction circuit 43.

The above-described image correction may be performed using artificial intelligence. For example, a current flowing in a pixel circuit (or a voltage applied to the pixel circuit) may be monitored and obtained, a displayed image may be obtained with an image sensor or the like, the current (or voltage) and the image may be used as input data in an arithmetic operation of the artificial intelligence (e.g., an artificial neural network), and the output result may be used to judge whether the image should be corrected.

The arithmetic operation of artificial intelligence can be applied to not only image correction but also upconversion for increasing the definition of image data. As an example, FIG. 11 illustrates the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, an SRCNN (Super-Resolution Convolutional Neural Network) method, and the like.

The algorithm used for the upconversion processing may be different for each region determined in accordance with a gaze point. For example, upconversion processing for a region including the gaze point and the vicinity of the gaze point is performed using an algorithm with a low processing speed but high accuracy, and upconversion processing for a region other than the above region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the definition of image data may be performed. In the case where the definition of image data is higher than the definition of the display portion 13, part of the image data is not displayed on the display portion 13, in some cases. In that case, downconversion processing enables the entire image data to be displayed on the display portion 13.

The timing controller 44 has a function of controlling driving frequency (e.g., frame frequency, frame rate, or refresh rate) for displaying an image, for example. In the case where a still image is displayed on the display apparatus 10A, for example, the driving frequency is lowered by the timing controller 44, so that power consumption of the display apparatus 10A can be reduced.

The CPU 45 has a function of performing general-purpose processing such as execution of an operating system, control of data, and execution of various kinds of arithmetic operations and programs, for example. The CPU 45 has a role in, for example, giving an instruction for a writing operation or a reading operation of image data in the storage device 41, an operation for correcting image data, an operation for a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 11 illustrates a wiring SNCL as a wiring for electrical connection to the sensor.

The sensor can be, for example, a touch sensor that can be provided in the display portion 13. Alternatively, the sensor can be an illuminance sensor, for example.

The power supply circuit 47 has a function of generating voltages to be supplied to the pixel circuits 51, the driver circuit 30, and the functional circuit 40, for example. Note that the power supply circuit 47 may have a function of selecting a circuit to which a voltage is to be supplied. The power supply circuit 47 can stop supply of a voltage to the CPU 45, the GPU 42, and the like during a period in which a still image is displayed so that the power consumption of the whole display apparatus 10A is reduced, for example.

As described above, the display apparatus of one embodiment of the present invention can have a structure in which display elements, pixel circuits, a driver circuit, and the functional circuit 40 are stacked. The driver circuit and the functional circuit, which are peripheral circuits, can be provided so as to overlap with the pixel circuits and thus the width of the bezel can be made extremely small, so that a reduction in size of the display apparatus can be achieved. A structure of the display apparatus of one embodiment of the present invention in which circuits are stacked enables its wirings connecting the circuits to be shortened, resulting in a reduction in weight of the display apparatus. The display apparatus of one embodiment of the present invention can include a display portion with an increased pixel resolution; thus, the display apparatus can have high display quality.

### <Structure Example of Display Module>

Next, a structure example of a display module including the display apparatus 10A will be described.

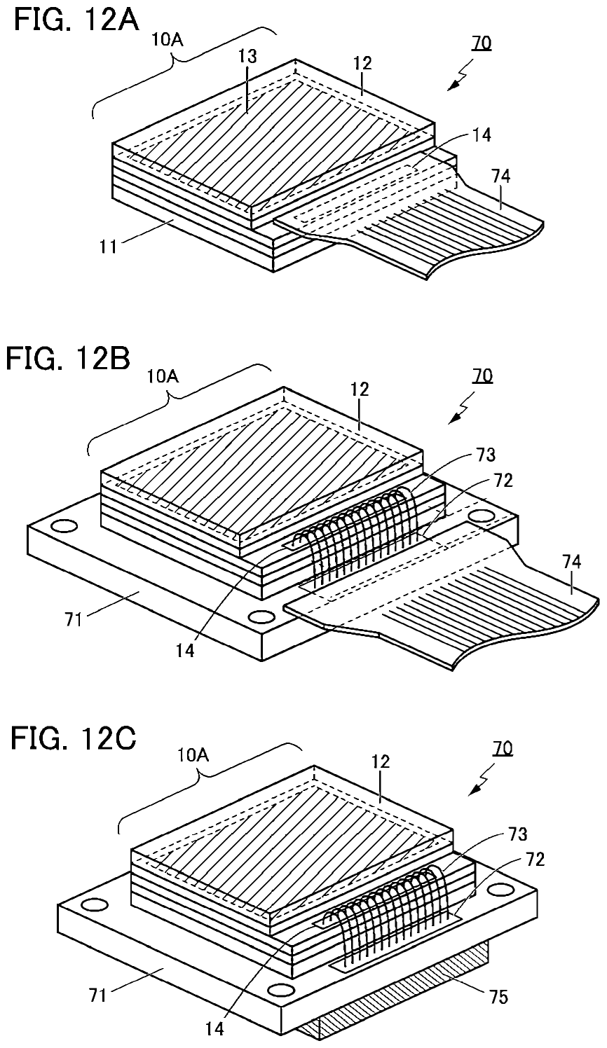

FIG. 12A to FIG. 12C are each a perspective view of a display module 70. The display module 70 illustrated in FIG. 12A has a structure in which an FPC (Flexible printed circuit) 74 is provided on the terminal portion 14 of the display apparatus 10A. The FPC 74 has a structure in which a film formed of an insulator is provided with a wiring. The FPC 74 is flexible. The FPC 74 functions as a wiring for supplying a video signal, a control signal, a power supply potential, and the like to the display apparatus 10A from the outside. An IC may be mounted on the FPC 74.

The display module 70 illustrated in FIG. 12B has a structure in which the display apparatus 10A is provided over a printed wiring board 71. The printed wiring board 71 has a structure in which wirings are provided inside a substrate formed of an insulator and/or on the surface of the substrate.

In the display module 70 illustrated in FIG. 12B, the terminal portion 14 of the display apparatus 10A is electrically connected to a terminal portion 72 of the printed wiring board 71 through a wire 73. The wire 73 can be formed in wire bonding. Ball bonding or wedge bonding can be used as the wire bonding.

After the wire 73 is formed, the wire 73 may be covered with a resin material or the like. Note that the display apparatus 10A and the printed wiring board 71 may be electrically connected to each other by a method other than the wire bonding. For example, the display apparatus 10A and the printed wiring board 71 may be electrically connected to each other using an anisotropic conductive adhesive or a bump.

In the display module 70 illustrated in FIG. 12B, the terminal portion 72 of the printed wiring board 71 is electrically connected to the FPC 74. In the case where the electrode pitch in the terminal portion 14 of the display apparatus 10A is different from the electrode pitch in the FPC 74, for example, the terminal portion 14 may be electrically connected to the FPC 74 via the printed wiring board 71. Specifically, the interval (pitch) between a plurality of electrodes in the terminal portion 14 can be converted into the interval between a plurality of electrodes in the terminal portion 72 using wirings formed on the printed wiring board 71. Accordingly, even when the electrode pitch in the terminal portion 14 is different from the electrode pitch in the FPC 74, electrical connection between the electrodes can be achieved.

The printed wiring board 71 can be provided with a variety of elements such as a resistor, a capacitor element, and a semiconductor element.

As in the display module 70 illustrated in FIG. 12C, the terminal portion 72 may be electrically connected to a connection portion 75 provided on a bottom surface (a surface where the display apparatus 10A is not provided) of the printed wiring board 71. With the use of a socket-type connection portion as the connection portion 75, for example, the display module 70 can be easily attached to and detached from another device.

### <Structure Example of Pixel Circuit>

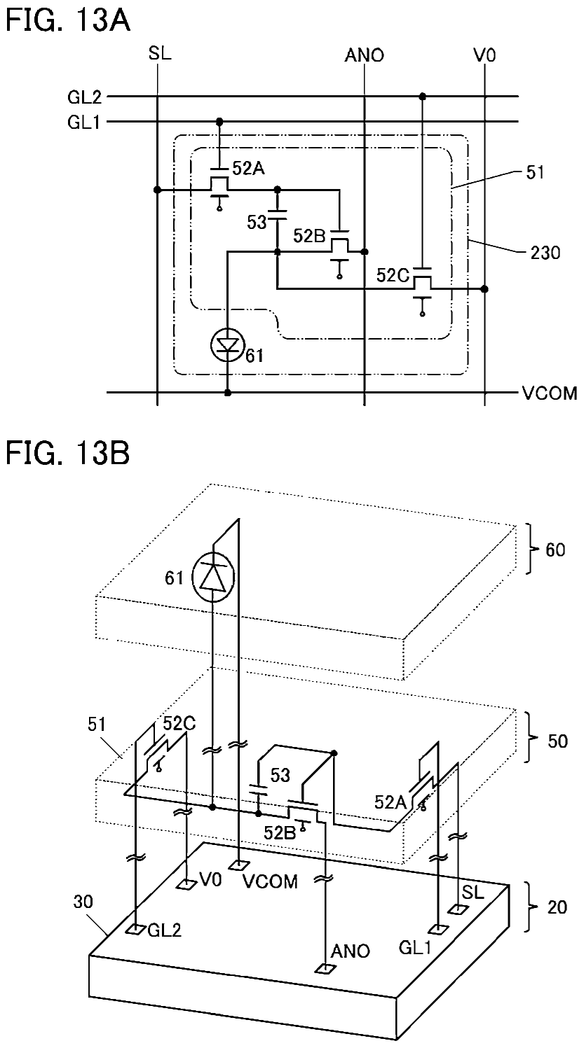

FIG. 13A and FIG. 13B illustrate a structure example of the pixel circuit 51 and the light-emitting element 61 connected to the pixel circuit 51. FIG. 13A illustrates connection of the elements, and FIG. 13B schematically illustrates the vertical position relation of the layer 20 including the driver circuit, the layer 50 including a plurality of transistors of the pixel circuit 51, and the layer 60 including the light-emitting element 61.

The pixel circuit 51 illustrated as an example in FIG. 13A and FIG. 13B includes a transistor 52A, a transistor 52B, a transistor 52C, and a capacitor 53. The transistor 52A, the transistor 52B, and the transistor 52C can be OS transistors. Each of the transistor 52A, the transistor 52B, and the transistor 52C preferably includes a back gate electrode, in which case the structure in which the back gate electrode and the gate electrode are supplied with the same signals or the structure in which the back gate electrode and the gate electrode are supplied with different signals can be used.

The transistor 52B includes the gate electrode electrically connected to the transistor 52A, a first terminal electrically connected to the light-emitting element 61, and a second terminal electrically connected to a wiring ANO. The wiring ANO is a wiring for supplying a potential for supplying a current to the light-emitting element 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to a wiring V0, a second terminal electrically connected to the light-emitting element 61, and the gate electrode having a function of controlling the conduction state or non-conduction state on the basis of the potential of a wiring GL2 which functions as a gate line. The wiring V0 is a wiring for supplying a reference potential and a wiring for outputting a current flowing through the pixel circuit 51 to the driver circuit 30 or the functional circuit 40.

The capacitor 53 includes a first conductive film electrically connected to the gate electrode of the transistor 52B and a second conductive film electrically connected to the second electrode of the transistor 52C.

The light-emitting element 61 includes a first electrode electrically connected to the first electrode of the transistor 52B and a second electrode electrically connected to a wiring VCOM. The wiring VCOM is a wiring for supplying a potential for supplying a current to the light-emitting element 61.

Accordingly, the intensity of light emitted from the light-emitting element 61 can be controlled in accordance with an image signal supplied to the gate electrode of the transistor 52B. Furthermore, variations in voltage between the gate and the source of the transistor 52B can be inhibited by the reference potential of the wiring V0 supplied through the transistor 52C.

A current value that can be used for setting of pixel parameters can be output from the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting element described in one embodiment of the present invention refers to a self-luminous display element such as an organic EL device (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

Note that in the structure illustrated as an example in FIG. 13B, the wirings electrically connecting the pixel circuit 51 and the driver circuit 30 can be shortened, so that wiring resistance of the wirings can be reduced. Thus, data can be written at high speed, which enables high-speed driving of the display apparatus 10A. Therefore, even when the number of the pixel circuits 51 included in the display apparatus 10A is increased, a sufficiently long frame period can be ensured, and thus, the pixel density of the display apparatus 10A can be increased. In addition, the increased pixel density of the display apparatus 10A can increase the resolution of an image displayed by the display apparatus 10A. For example, the pixel density of the display apparatus 10A can be higher than or equal to 1000 ppi, higher than or equal to 5000 ppi, or higher than or equal to 7000 ppi. Thus, the display apparatus 10A can be, for example, a display apparatus for AR or VR and can be suitably used in an electronic device with a short distance between a display portion and the user, such as an HMD.

Although FIG. 13A and FIG. 13B illustrate, as an example, the pixel circuit 51 including three transistors in total, one embodiment of the present invention is not limited thereto. Structure examples and a driving method example of a pixel circuit which can be used for the pixel circuit 51 will be described below.

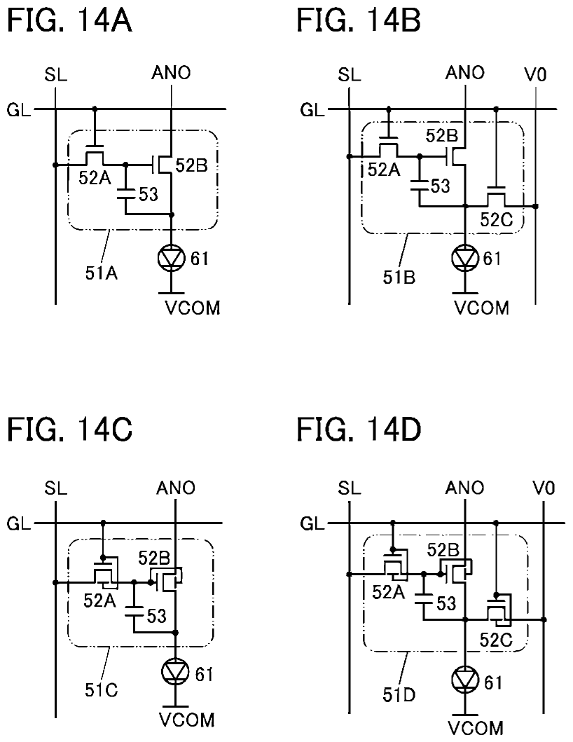

A pixel circuit 51A illustrated in FIG. 14A includes the transistor 52A, the transistor 52B, and the capacitor 53. FIG. 14A illustrates the light-emitting element 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 illustrated in FIG. 13A and the wiring GL1 and the wiring GL2 are replaced with the wiring GL.

A gate of the transistor 52A is electrically connected to the wiring GL, one of a source and a drain of the transistor 52A is electrically connected to the wiring SL, and the other of the source and the drain of the transistor 52A is electrically connected to a gate of the transistor 52B and one electrode of a capacitor C1. One of a source and a drain of the transistor 52B is electrically connected to the wiring ANO and the other of the source and the drain of the transistor 52B is electrically connected to an anode of the light-emitting element 61. The other electrode of the capacitor C1 is electrically connected to the anode of the light-emitting element 61. A cathode of the light-emitting element 61 is electrically connected to the wiring VCOM.

A pixel circuit 51B illustrated in FIG. 14B has a structure in which the transistor 52C is added to the pixel circuit 51A. In addition, the wiring V0 is electrically connected to the pixel circuit 51B.

A pixel circuit 51C illustrated in FIG. 14C is an example of the case where a transistor in which a pair of gates are electrically connected to each other is used as each of the transistor 52A and the transistor 52B of the pixel circuit 51A. A pixel circuit 51D illustrated in FIG. 14D is an example of the case where such transistors are used in the pixel circuit 51B. Thus, the current that can flow through the transistor can be increased. Note that although a transistor in which a pair of gates are electrically connected to each other is used for each of the transistors here, one embodiment of the present invention is not limited thereto. A transistor that includes a pair of gates electrically connected to different wirings may be used. When, for example, a transistor in which one of the gates is electrically connected to the source is used, the reliability can be increased.

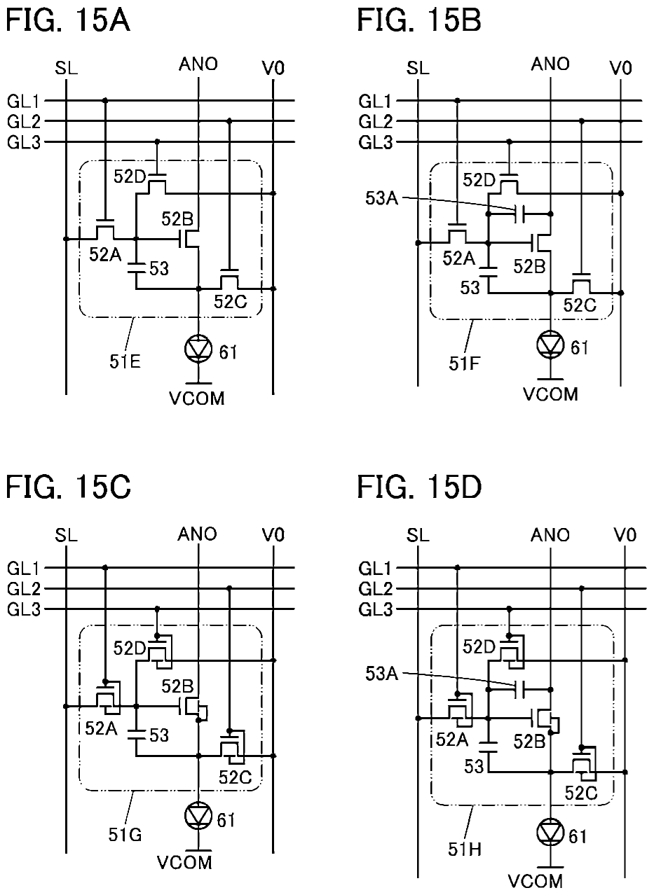

A pixel circuit 51E illustrated in FIG. 15A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and consists of a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are turned on at the same time, the source and the gate of the transistor 52B have the same potential, so that the transistor 52B can be turned off. Thus, a current flowing to the light-emitting element 61 can be blocked forcibly. Such a pixel circuit is suitable for the case of using a display method in which a display period and a non-lighting period are alternately provided.

A pixel circuit 51F illustrated in FIG. 15B is an example of the case where a capacitor 53A is added to the pixel circuit 51E. The capacitor 53A functions as a storage capacitor.

A pixel circuit 51G illustrated in FIG. 15C and a pixel circuit 51H illustrated in FIG. 15D are respectively examples of the cases where transistors each including a pair of gates are used in the pixel circuit 51E and the pixel circuit 51F. A transistor in which a pair of gates are electrically connected to each other is used as each of the transistor 52A, the transistor 52C, and the transistor 52D, and a transistor in which one of gates is electrically connected to a source is used as the transistor 52B.

Next, an example of a method for driving a display apparatus in which the pixel circuit 51E is used will be described. Note that a similar driving method can be applied to display apparatuses in which the pixel circuits 51F, 51G, and 51H are used.

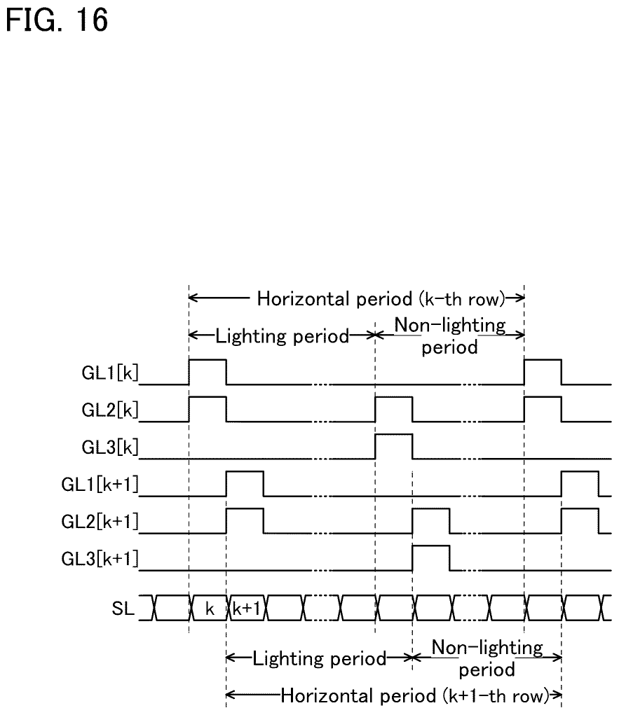

FIG. 16 shows a timing chart of a method for driving the display apparatus in which the pixel circuit 51E is used. Changes in the potentials of a wiring GL1[k], a wiring GL2[k], and a wiring GL3[k] that are gate lines of the k-th row and changes in the potentials of a wiring GL1[k+1], a wiring GL2[k+1], and a wiring GL3[k+1] that are gate lines of the k+1-th row are shown here. FIG. 16 also shows the timing of supplying a signal to the wiring SL functioning as a source line.

Here, an example of the driving method in which one horizontal period is divided into a lighting period and a non-lighting period is shown. A horizontal period of the k-th row is shifted from a horizontal period of the k+1-th row by a selection period of the gate line.

In the lighting period of the k-th row, first, the wiring GL1[k] and the wiring GL2[k] are supplied with a high-level potential and the wiring SL is supplied with a source signal. Thus, the transistor 52A and the transistor 52C are turned on, so that a potential corresponding to the source signal is written from the wiring SL to the gate of the transistor 52B. After that, the wiring GL1[k] and the wiring GL2[k] are supplied with a low-level potential, so that the transistor 52A and the transistor 52C are turned off and the gate potential of the transistor 52B is retained.

Subsequently, in a lighting period of the k+1-th row, data is written by an operation similar to that described above.

Next, the non-lighting period is described. In the non-lighting period of the k-th row, the wiring GL2[k] and the wiring GL3[k] are supplied with a high-level potential. Accordingly, the transistor 52C and the transistor 52D are turned on, and the source and the gate of the transistor 52B are supplied with the same potential, so that almost no current flows through the transistor 52B. Thus, the light-emitting element 61 is turned off. All the pixels that are positioned in the k-th row are turned off. The pixels of the k-th row remain in the non-lighting state until the next lighting period.

Subsequently, in a non-lighting period of the k+1-th row, all the pixels of the k+1-th row are in the non-lighting state in a manner similar to that described above.

Such a driving method described above, in which the pixels are not constantly on through one horizontal period and a non-lighting period is provided in one horizontal period, can be called duty driving. With duty driving, an afterimage phenomenon can be inhibited at the time of displaying moving images; therefore, a display apparatus with high performance in displaying moving images can be obtained. Particularly in a VR device and the like, a reduction in an afterimage can reduce what is called VR sickness.

In the duty driving, the proportion of the lighting period in one horizontal period can be called a duty cycle. For example, a duty cycle of 50% means that the lighting period and the non-lighting period have the same length. Note that the duty cycle can be set freely and can be adjusted appropriately within a range higher than 0% and lower than or equal to 100%, for example.

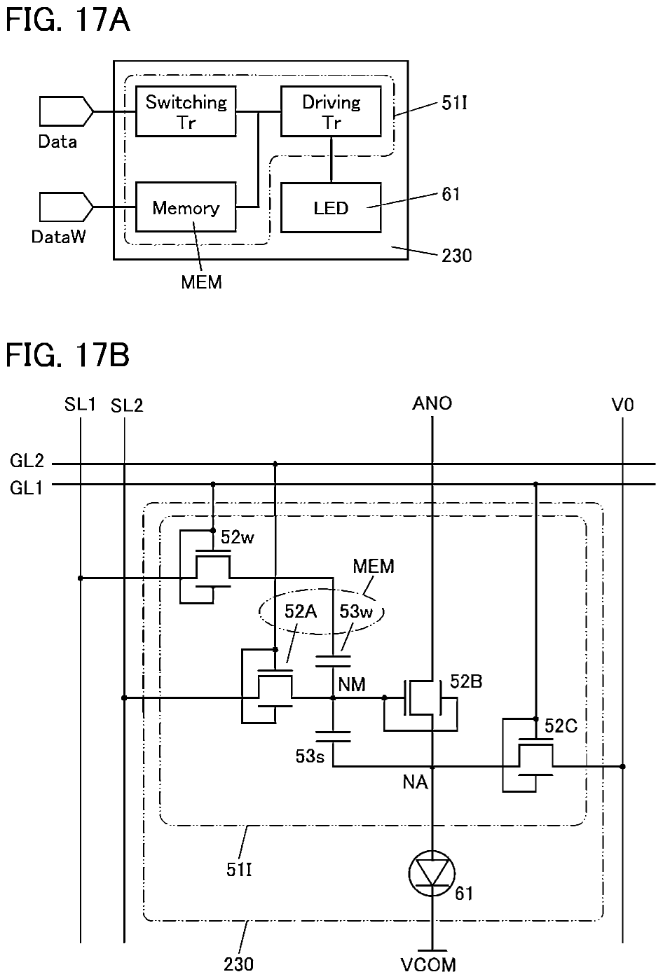

A structure different from the structures of the above-described pixel circuits will be described with reference to FIG. 17A and FIG. 17B.

FIG. 17A is a block diagram of the pixel 230. The pixel illustrated in FIG. 17A includes a memory circuit MEM (Memory) in addition to a switching transistor (Switching Tr), a driving transistor (Driving Tr), and a light-emitting element (LED).

Data DataW is supplied to the memory circuit MEM through a wiring SL2 and the transistor 52A. When the data DataW is supplied to the pixel in addition to image data Data, a current flowing through the light-emitting element becomes large, so that the display apparatus can have high luminance.

FIG. 17B is a specific circuit diagram of a pixel circuit 51I.

The pixel circuit 51I illustrated in FIG. 17B includes a transistor 52w, the transistor 52A, the transistor 52B, the transistor 52C, a capacitor 53s, and a capacitor 53w. FIG. 17B illustrates the light-emitting element 61 connected to the pixel circuit 51I.

The transistor 52w functions as a switching transistor. The transistor 52B functions as a driving transistor. One of a source and a drain of the transistor 52w is electrically connected to one electrode of the capacitor 53w. The other electrode of the capacitor 53w is electrically connected to one of the source and the drain of the transistor 52A. The one of the source and the drain of the transistor 52A is electrically connected to the gate of the transistor 52B. The gate of the transistor 52B is electrically connected to one electrode of the capacitor 53s. The other electrode of the capacitor 53s is electrically connected to one of the source and the drain of the transistor 52B. The one of the source and the drain of the transistor 52B is electrically connected to one of a source and a drain of the transistor 52C. The one of the source and the drain of the transistor 52C is electrically connected to one electrode of the light-emitting element 61. The transistors illustrated in FIG. 17B each include a back gate electrically connected to its gate; however, the connection of the back gate is not limited thereto. The transistors do not necessarily include the back gates.

Here, a node to which the other electrode of the capacitor 53w, the one of the source and the drain of the transistor 52A, the gate of the transistor 52B, and the one electrode of the capacitor 53s are connected is referred to as a node NM. A node to which the other electrode of the capacitor 53s, the one of the source and the drain of the transistor 52B, the one of the source and the drain of the transistor 52C, and the one electrode of the light-emitting element 61 are connected is referred to as a node NA.

A gate of the transistor 52w is electrically connected to the wiring GL1. The gate of the transistor 52C is electrically connected to the wiring GL1. The gate of the transistor 52A is electrically connected to the wiring GL2. The other of the source and the drain of the transistor 52w is electrically connected to a wiring SL1. The other of the source and the drain of the transistor 52C is electrically connected to the wiring V0. The other of the source and the drain of the transistor 52A is electrically connected to the wiring SL2. Note that in this embodiment and the like, the wiring SL1 and the wiring SL2 are collectively referred to as the wiring SL in some cases. Thus, the wiring SL is not limited to one wiring and consists of a plurality of wirings in some cases.

The other of the source and the drain of the transistor 52B is electrically connected to the wiring ANO. The other electrode of the light-emitting element 61 is electrically connected to the wiring VCOM.

The wiring GL1 and the wiring GL2 can have a function of signal lines for controlling the operation of the transistors. The wiring SL1 can have a function of a signal line for supplying the image data Data to the pixel. The wiring SL2 can have a function of a signal line for writing the data DataW to the memory circuit MEM. For example, the wiring SL2 can have a function of a signal line for supplying a correction signal to the pixel. The wiring V0 has a function of a monitor line for obtaining the electrical characteristics of the transistor 52B. A specific potential is supplied from the wiring V0 to the other electrode of the capacitor 53s through the transistor 52C, whereby writing of an image signal can be stable.

The transistor 52A and the capacitor 53w constitute the memory circuit MEM. The node NM is a memory node; when the transistor 52A is turned on, the data DataW supplied from the wiring SL2 can be written to the node NM. The use of an OS transistor with an extremely low off-state current as the transistor 52A allows the potential of the node NM to be retained for a long time.

In the pixel circuit 51I, the image data Data supplied from the wiring SL1 is supplied to the capacitor 53w through the transistor 52w. One of the source and the drain of the transistor 52w and the node NM are capacitively coupled. Thus, the potential of the node NM to which the data DataW is written changes depending on the image data Data. Furthermore, the node NA and the node NM are capacitively coupled through the capacitor 53s. Thus, the potential of the node NA changes depending on the data DataW and the image data Data.

Note that the transistor 52w functions as a selection transistor for determining whether or not the image data Data is to be supplied. The transistor 52C functions as a reset transistor for determining whether or not to set the potential of the node NA to be equal to that of the wiring V0.

The display apparatus of one embodiment of the present invention can detect a defective pixel using the functional circuit 40 provided to overlap with the pixel circuit group 55. Information on the defective pixel can be used to correct a display defect due to the defective pixel, leading to normal display.

Some or all of steps of a correction method described below as an example may be performed by a circuit provided outside the display apparatus. Alternatively, some of the steps of the correction method may be performed by the functional circuit 40 and the other steps may be performed by a circuit provided outside the display apparatus.

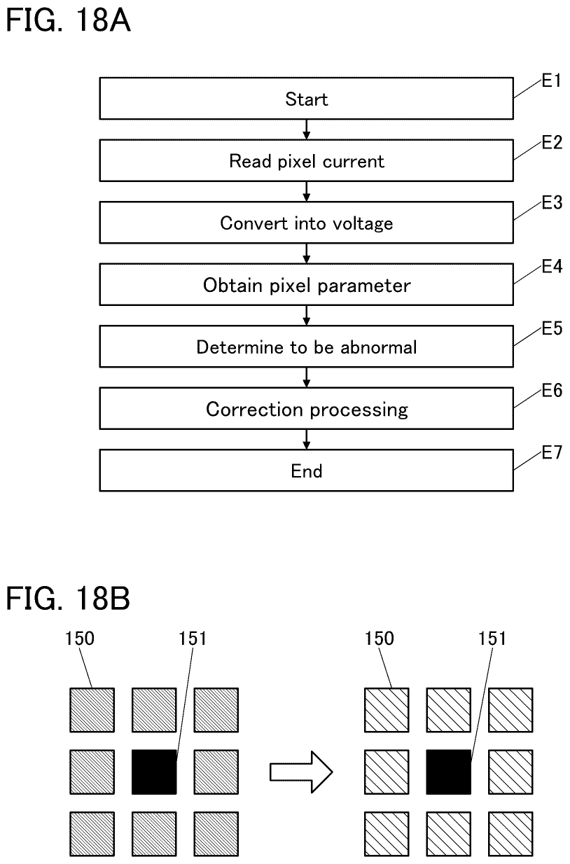

A more specific example of the correction method will be described below. FIG. 18A is a flowchart of the correction method described below.

First, a correction operation starts in Step E1.

Next, currents of the pixels are read in Step E2. For example, each of the pixels can be driven so as to output a current to a monitor line electrically connected to the pixel.

In the case where the pixel circuit group 55 is divided into a plurality of sections 59 as in a later-described display apparatus 10B or the like, current reading operations can be performed simultaneously for each of the sections 59. With the pixel circuit group 55 divided into the plurality of sections 59, the time required to read currents of all pixels can be extremely short.

Then, the read currents are converted into voltages in Step E3. In the case of using a digital signal in later processing, conversion to digital data can be performed in Step E3. For example, analog data can be converted into digital data using an analog-digital converter circuit (ADC).

Next, pixel parameters of the pixels are obtained on the basis of the obtained data in Step E4. Examples of the pixel parameter include the threshold voltage and field-effect mobility of the driving transistor, the threshold voltage of the light-emitting element, and a current value at a certain voltage.

Subsequently, each of the pixels is determined to be abnormal or not on the basis of the pixel parameter in Step E5. For example, a pixel is determined to be abnormal when its pixel parameter has a value exceeding (or lower than) a predetermined threshold value.

Examples of abnormality include a dark spot defect with luminance significantly lower than that corresponding to an input data potential, and a bright spot defect with luminance significantly higher than that corresponding to an input data potential.

The address of the abnormal pixel and the kind of the defect can be specified and obtained in Step E5.

Then, correction processing is performed in Step E6.

An example of the correction processing is described with reference to FIG. 18B. FIG. 18B schematically illustrates 3×3 pixels each of which includes a pair of the pixel circuit 51 and the light-emitting element 61. Here, the pixel at the center is regarded as a pixel 151 having a dark spot defect. FIG. 18B schematically illustrates a state where the pixel 151 is off and pixels 150 around the pixel 151 are on with predetermined luminance.

A dark spot defect is due to a pixel unlikely to have normal luminance even when correction for increasing a data potential input to the pixel is performed. Hence, correction for increasing luminance is performed on the pixels 150 around the pixel 151 having a dark spot defect, as illustrated in FIG. 18B. As a result, a normal image can be displayed even when a dark spot defect is caused.

In the case of a bright spot defect, the luminance of pixels around the defect is decreased, so that the bright spot defect can be less noticeable.

Such a correction method for compensating for an abnormal pixel by pixels around the abnormal pixel is effective particularly in the case of a display apparatus with a high resolution (e.g., 1000 ppi or higher), in which it is difficult to see a plurality of adjacent pixels separately from each other.

It is preferable that correction be performed such that a data potential is not input to a pixel in which abnormality such as a dark spot defect or a bright spot defect has been caused.

As described above, a correction parameter can be set for each pixel. When the correction parameter is applied to image data to be input, correction image data which enables the display apparatus 10A to display an optimal image can be generated.

As well as in an abnormal pixel and pixels around the abnormal pixel, pixel parameters vary in pixels not determined to be abnormal; thus, display unevenness due to the variation might be recognized when an image is displayed, in some cases. Hence, correction parameters for the pixels not determined to be abnormal can be set so as to cancel (level off) the variation of the pixel parameters. For example, a reference value based on the mean value, average value, or the like of pixel parameters of some or all of the pixels can be set, and a correction value used for canceling a difference of a pixel parameter of a certain pixel from the reference value can be set as a correction parameter of the pixel.

For each of pixels around an abnormal pixel, it is preferable to set correction data that takes into consideration both a correction amount for compensating for the abnormal pixel and a correction amount for canceling pixel parameter variation.

Next, the correction operation ends in Step E7.

After that, an image can be displayed on the basis of the correction parameters obtained in the correction operation and image data to be input.

Note that a neural network may be used in a step of the correction operation. In the neural network, correction parameters can be determined on the basis of inference results obtained by machine learning, for example. In the case where correction parameters are determined by a neural network, for example, high-accuracy correction can be performed to make an abnormal pixel less noticeable without using a detailed algorithm for correction.

The above is the description of the correction method.

### Modification Example 1

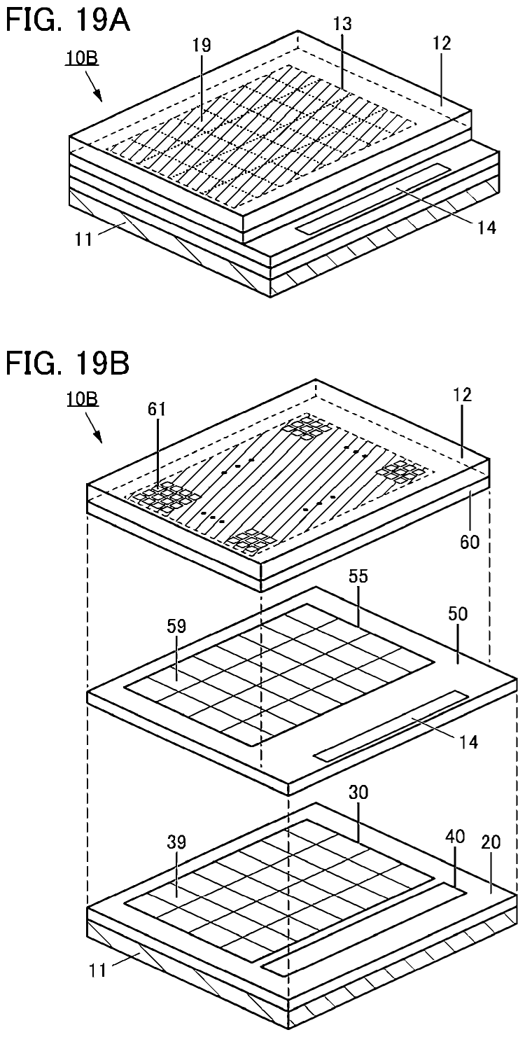

FIG. 19A and FIG. 19B are perspective views of the display apparatus 10B, which is a modification example of the display apparatus 10A. FIG. 19B is a perspective view for illustrating structures of layers included in the display apparatus 10B. Note that description is made mainly on portions different from those of the display apparatus 10A to reduce repeated description.

In the display apparatus 10B, the driver circuit 30 and the pixel circuit group 55 including the plurality of pixel circuits 51 overlap with each other. In the display apparatus 10B, the pixel circuit group 55 is divided into the plurality of sections 59 and the driver circuit 30 is divided into a plurality of sections 39. The plurality of sections 39 each include the source driver circuit 31 and the gate driver circuit 33.

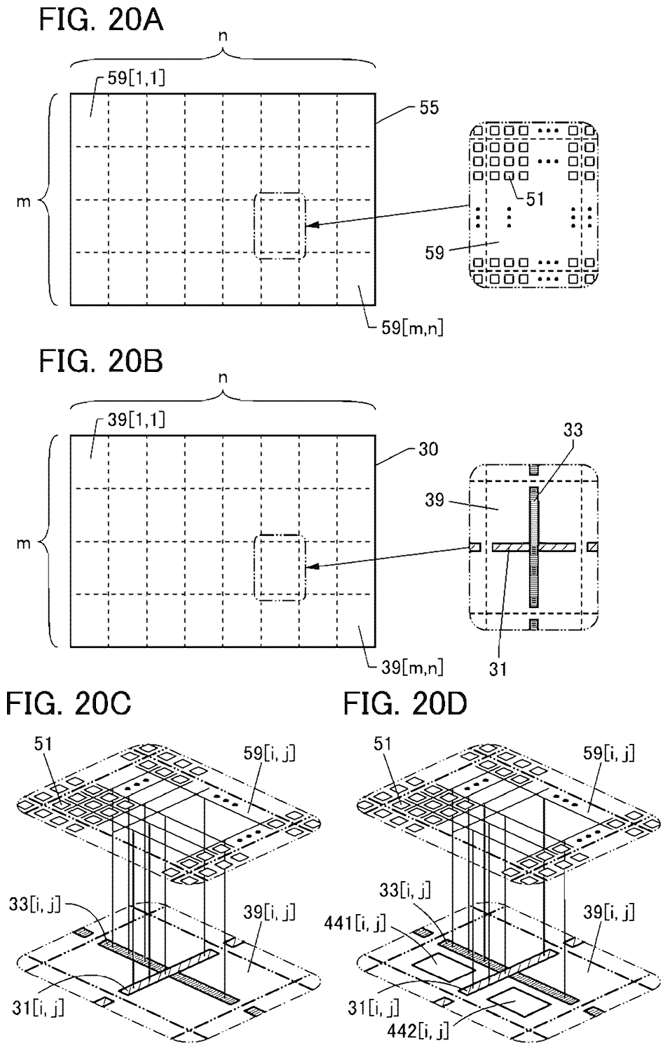

FIG. 20A illustrates a structure example of the pixel circuit group 55 included in the display apparatus 10B. FIG. 20B illustrates a structure example of the driver circuit 30 included in the display apparatus 10B. The sections 59 and the sections 39 are each arranged in a matrix of m rows and n columns (m and n are each an integer greater than or equal to 1). In this specification and the like, the section 59 in the first row and the first column is denoted by a section 59[1,1], and the section 59 in the m-th row and the n-th column is denoted by a section 59[m,n]. Similarly, the section 39 in the first row and the first column is denoted by a section 39[1,1], and the section 39 in the m-th row and the n-th column is denoted by a section 39[m,n]. FIG. 20A and FIG. 20B illustrate a case where m is 4 and n is 8. That is, the pixel circuit group 55 and the driver circuit 30 are each divided into 32 sections.

The plurality of sections 59 each include the plurality of pixel circuits 51, a plurality of wirings SL, and a plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 20C). For example, a section 59[i,j] (i is an integer greater than or equal to 1 and less than or equal to m, and j is an integer greater than or equal to 1 and less than or equal to n) and a section 39[i,j] are provided to overlap with each other. A source driver circuit 31[i,j] included in the section 39[i,j] is electrically connected to the wiring SL included in the section 59[i,j]. A gate driver circuit 33[i,j] included in the section 39[i,j] is electrically connected to the wiring GL included in the section 59[i,j]. The source driver circuit 31[i,j] and the gate driver circuit 33[i,j] have a function of controlling the plurality of pixel circuits 51 included in the section 59[i,j].

When the section 59[i,j] and the section 39[i,j] are provided to overlap with each other, a connection distance (wiring length) between the pixel circuit 51 included in the section 59[i,j] and each of the source driver circuit 31 and the gate driver circuit 33 included in the section 39[i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

In addition, the display apparatus 10B has a structure in which the source driver circuit 31 and the gate driver circuit 33 are provided in each of the sections 39. Thus, the display portion 13 can be divided into the sections 59 corresponding to the sections 39, and image data rewriting can be performed in each section. For example, in the display portion 13, image data rewriting can be performed only in a section where an image has been changed and image data can be retained in a section with no change, so that power consumption can be reduced.

In this embodiment and the like, one section of the display portion 13 divided into the sections 59 is referred to as a sub-display portion 19. Thus, it can also be said that the sub-display portions 19 are divided to correspond to the sections 39. In the display apparatus 10B described with reference to FIG. 19 and FIG. 20, the display portion 13 is divided into 32 sub-display portions 19 (see FIG. 19A). Each of the sub-display portions 19 includes the plurality of pixels 230 illustrated in FIG. 13 and the like. Specifically, one of the sub-display portions 19 includes one of the sections 59 including the plurality of pixel circuits 51, and the plurality of light-emitting elements 61. Each of the sections 39 has a function of controlling the plurality of pixels 230 included in one of the sub-display portions 19.

In the display apparatus 10B, driving frequency at the time of displaying an image can be set freely for each of the sub-display portions 19 by the timing controller 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 19 arranged in a matrix. In addition, the functional circuit 40 has a function of adjusting synchronization between the sub-display portions.

A timing controller 441 and an input/output circuit 442 may be provided for each of the sections 39 (see FIG. 20D). For the input/output circuit 442, an I2C (Inter-Integrated Circuit) interface can be used, for example. The timing controller 441 included in the section 39[i,j] is denoted as a timing controller 441[i,j] in FIG. 20D. Furthermore, the input/output circuit 442 included the section 39[i,j] is denoted as an input/output circuit 442[i,j].

The functional circuit 40 supplies setting signals for the scan direction and driving frequency of the gate driver circuit 33[i,j] and operation parameters, such as the number of pixels in image data reduced for decreasing definition (the number of pixels where image data rewriting is not performed at the time of image data rewriting), to the input/output circuit 442[i,j], for example. The source driver circuit 31[i,j] and the gate driver circuit 33[i,j] operate in accordance with the operation parameters.

In the case where the sub-display portions 19 each include a light-receiving element described later, the input/output circuit 442 outputs information obtained by photoelectric conversion by the light-receiving element to the functional circuit 40.

In the display apparatus 10B in the electronic device of one embodiment of the present invention, the pixel circuit 51 and the driver circuit 30 are stacked and the driving frequency is different in each of the sub-display portions 19 in accordance with the motion of the user's gaze, whereby low power consumption can be achieved.

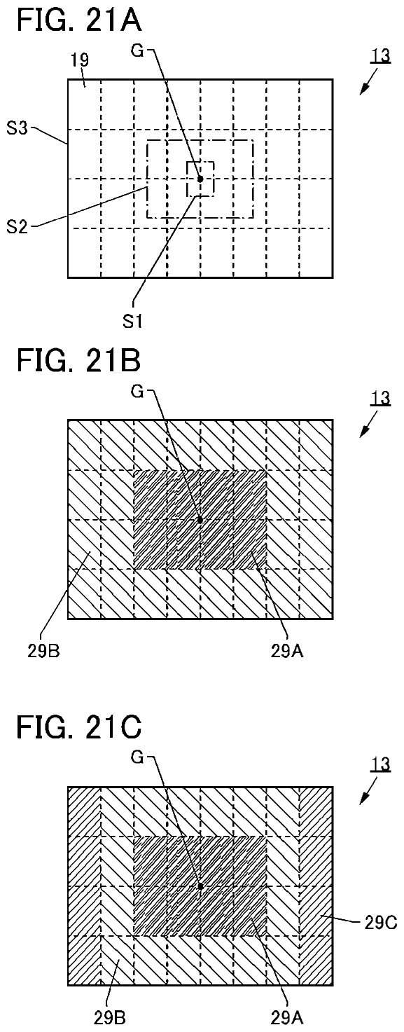

FIG. 21A illustrates the display portion 13 including the sub-display portions 19 in four rows and eight columns. FIG. 21A also illustrates the first region S1 to the third region S3 with a gaze point G as a center. The CPU 45 divides the plurality of sub-display portions 19 between a first section 29A overlapping with the first region S1 or the second region S2 and a second section 29B overlapping with the third region S3. In other words, the CPU 45 divides the plurality of sections 39 between the first section 29A and the second section 29B. In this case, the first section 29A overlapping with the first region S1 or the second region S2 includes a region overlapping with the gaze point G. Furthermore, the second section 29B includes the sub-display portions 19 positioned outside the first section 29A (see FIG. 21B).

The operations of the driver circuits (the source driver circuit 31 and the gate driver circuit 33) included in each of the plurality of sections 39 are controlled by the functional circuit 40. For example, the second section 29B is a section overlapping with the third region S3 including the above-described stable visual field, inducting visual field, and supplementary visual field, and is hard for the user to discriminate. Thus, the user perceives a small reduction in practical display quality (hereinafter also referred to as “practical display quality”) even when the number of times of image data rewriting per unit time (hereinafter also referred to as “image rewriting frequency”) at the time of displaying an image is smaller in the second section 29B than in the first section 29A. In other words, a reduction in practical display quality is small even when driving frequency of the sub-display portion 19 included in the second section 29B (also referred to as “second driving frequency”) is lower than driving frequency of the sub-display portions 19 included in the first section 29A (also referred to as “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be inhibited. According to one embodiment of the present invention, both display quality maintenance and a reduction in power consumption can be achieved.

The first driving frequency can be higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency.

A section of the sub-display portions 19 overlapping with the third region S3 that is farther from the first section 29A may be set as a third section 29C (see FIG. 21C), and driving frequency of the sub-display portions 19 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as the transistor 52A.

In some cases, an image whose brightness, contrast, color tone, or the like is greatly different from that of the previous image is displayed as in the case where a video scene displayed on the display portion 13 is changed, for example. Such a case causes a mismatch of the timing at which an image is changed between the first section 29A and a section whose driving frequency is lower than that of the first section 29A. This might cause a great difference in the brightness, contrast, color tone, or the like between the sections, leading to the loss of the practical display quality. In such a case where a video scene is changed, image data rewriting can be temporarily performed in the section other than the first section 29A at a driving frequency which is the same as that of the first section 29A, and then the driving frequency of the section other than the first section 29A can be decreased.

Furthermore, in the case where the fluctuation amount of the gaze point G is judged to be exceeding a certain value, image data rewriting may be performed in the section other than the first section 29A at a driving frequency which is the same as that of the first section 29A, and the driving frequency of the section other than the first section 29A may be decreased when the fluctuation amount is judged to be within the certain value. In the case where the fluctuation amount of the gaze point G is judged to be small, the driving frequency of the section other than the first section 29A may be further decreased.

In the case where the display apparatus 10B does not include a frame memory, which is a storage device for temporarily retaining image data, or includes one frame memory for the entire display portion 13, each of the second driving frequency and the third driving frequency needs to be an integral submultiple of the first driving frequency.

When the plurality of sub-display portions 19 are provided with respective frame memories, each of the second driving frequency and the third driving frequency can be set to a given value without limitation to an integral submultiple of the first driving frequency. When the second driving frequency and the third driving frequency are set to given values, the degree of freedom in setting the driving frequencies can be increased. As a result, a reduction in the practical display quality can be small.

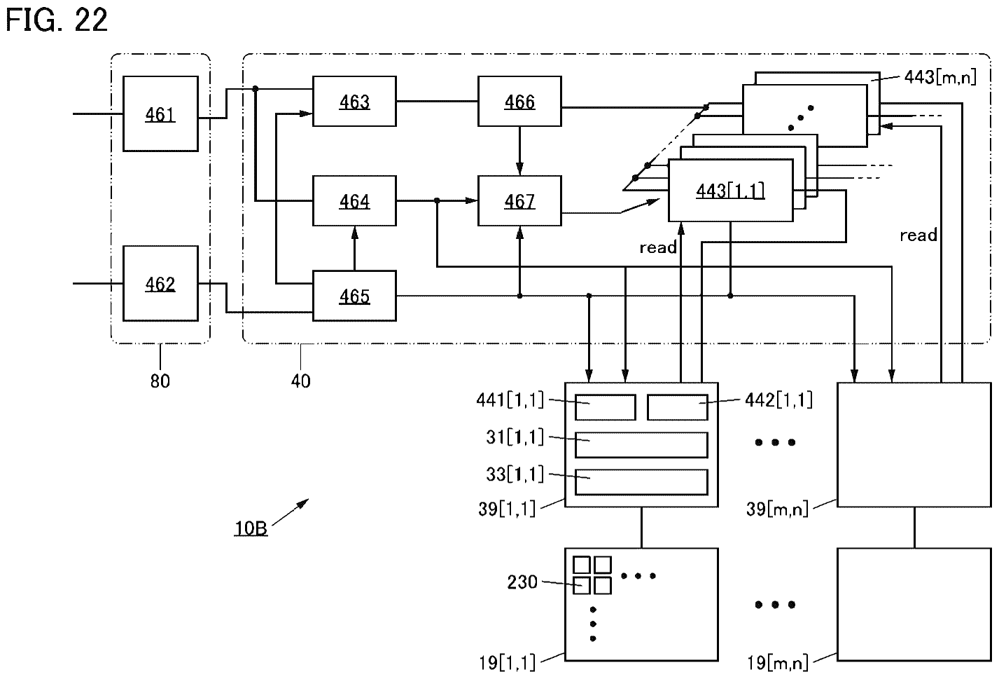

FIG. 22 is a block diagram illustrating a structure example of the display apparatus 10B including a frame memory 443 for each of the sub-display portions 19. In FIG. 22, the input/output circuit 80 includes an image information input portion 461 and a clock signal input portion 462. The functional circuit 40 includes an image data temporary retention portion 463, an operation parameter setting portion 464, an internal clock signal generating portion 465, an image processing portion 466, a memory controller 467, and a plurality of frame memories 443.

Each of the plurality of frame memories 443 has a function of retaining image data to be displayed on one of the plurality of sub-display portions 19. For example, a frame memory 443[1,1] has a function of retaining image data to be displayed on a sub-display portion 19[1,1]. Similarly, a frame memory 443[m,n] has a function of retaining image data to be displayed on a sub-display portion 19[m,n].

Each of the plurality of sub-display portions 19 is electrically connected to one of the plurality of sections 39. In FIG. 22, each of the plurality of sections 39 includes the source driver circuit 31, the gate driver circuit 33, the timing controller 441, and the input/output circuit 442.

Image data to be displayed on the display portion 13 and operation parameters of the display apparatus 10B are supplied to the image information input portion 461 from the outside. A clock signal is supplied to the clock signal input portion 462 from the outside. The clock signal is supplied to the internal clock signal generating portion 465 via the clock signal input portion 462.

The internal clock signal generating portion 465 has a function of generating a clock signal used in the display apparatus 10B (also referred to as “internal clock signal”) with the use of the clock signal supplied from the outside. The internal clock signal is supplied to the image data temporary retention portion 463, the operation parameter setting portion 464, the memory controller 467, the section 39, and the like and used for matching operation timing between the circuits included in the display apparatus 10B, for example.

The image data input via the image information input portion 461 is supplied to the image data temporary retention portion 463. The operation parameters input via the image information input portion 461 are supplied to the operation parameter setting portion 464.

The image data temporary retention portion 463 retains the supplied image data, and supplies the image data to the image processing portion 466 in synchronization with the internal clock signal. Providing the image data temporary retention portion 463 can eliminate a mismatch between the timing at which image data is supplied from the outside and the timing at which the image data is processed in the display apparatus 10B.

The operation parameter setting portion 464 has a function of retaining the supplied operation parameters. The operation parameters include information for determining the driving frequency, scan direction, definition, or the like for each of the plurality of sub-display portions 19.

The image processing portion 466 has a function of performing arithmetic processing of the image data retained in the image data temporary retention portion 463. For example, the image processing portion 466 has a function of performing contrast adjustment, brightness adjustment, and gamma correction of the image data. Furthermore, the image processing portion 466 has a function of dividing the image data retained in the image data temporary retention portion 463 for the sub-display portions 19.

The memory controller 467 has a function of controlling the operations of the plurality of frame memories 443. The image data is retained in the plurality of frame memories 443 after being divided by the image processing portion 466 for the sub-display portions 19. Each of the plurality of frame memories 443 has a function of supplying image data to the corresponding section 39 in response to a read request signal (read) from the section 39.

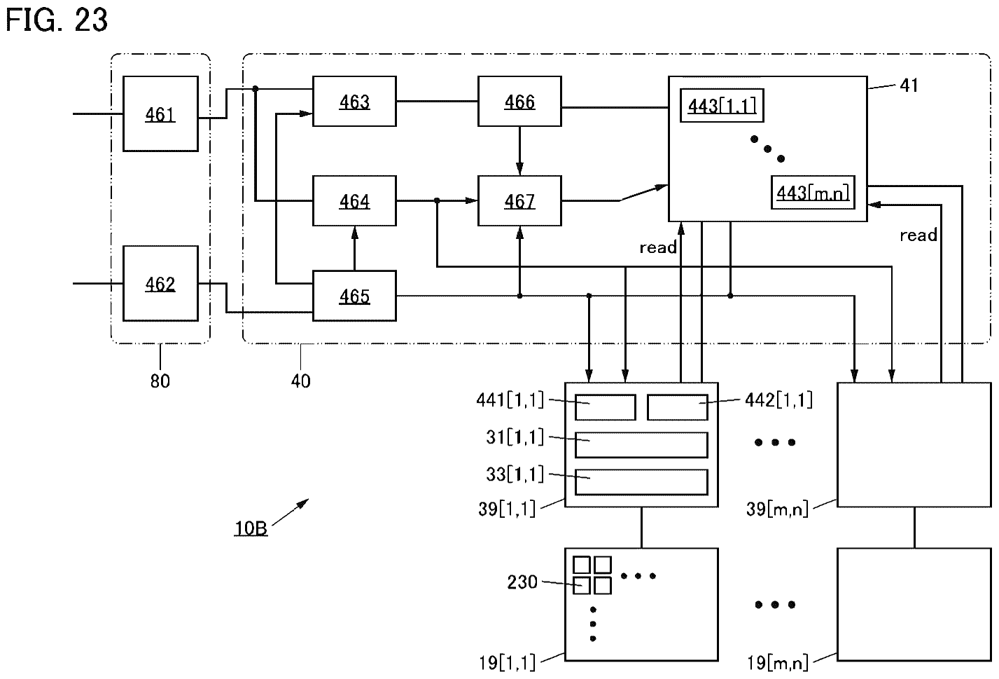

Note that the storage device 41 may be used as the frame memories 443 as illustrated in FIG. 23. In other words, image data divided for the sub-display portions 19 may be retained in the storage device 41.

The frame memories 443 may be provided in a component other than the functional circuit 40. Alternatively, the frame memory 443 may be provided in a semiconductor device other than the display apparatus 10B.

Note that sections set for the display portion 13 are not limited to the three sections of the first section 29A, the second section 29B, and the third section 29C. The display portion 13 may include four or more sections. When a plurality of sections are set for the display portion 13 and the driving frequencies of the sections are gradually decreased, a reduction in the practical display quality can be smaller.

The above-described upconversion processing may be performed on an image to be displayed on the first section 29A. When an image obtained by the upconversion processing is displayed on the first section 29A, the display quality can be increased. The above-described upconversion processing may be performed on an image to be displayed on the section other than the first section 29A. When an image obtained by the upconversion processing is displayed on the section other than the first section 29A, a reduction in the practical display quality that occurs in the case where the driving frequencies of the sections other than the first section 29A are decreased can be smaller.

Note that the upconversion processing of an image to be displayed on the first section 29A may be performed using an algorithm with high accuracy, and the upconversion processing of an image to be displayed on the sections other than the first section 29A may be performed using an algorithm with low accuracy. A reduction in the practical display quality that occurs in the case where the driving frequencies of the sections other than the first section 29A are decreased can be smaller also in such a case.

When image data rewriting performed in each of the sub-display portions 19 is performed concurrently in all of the sub-display portions 19, high-speed rewriting can be achieved. In other words, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of line sequential driving. In the case where the display portion 13 is not divided into the sub-display portions 19 and the definition is 4000×2000 pixels, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select pixels in 2000 rows in approximately 8.3 msec, and the time for selecting pixels in one row, that is, the time for writing image data to each pixel is approximately 4.17 usec. In other words, it becomes more difficult to ensure sufficient time for rewriting image data as the definition of the display portion increases or as the frame frequency increases.

The display portion 13 of the display apparatus 10B described as an example in this embodiment is divided into four parts in the row direction. Thus, the time for writing image data to each pixel in one sub-display portion 19 can be four times as long as that of the case where the display portion 13 is not divided. According to one embodiment of the present invention, the time for rewriting image data can be easily ensured even in the case where frame frequency is 240 Hz or 360 Hz; thus, a display apparatus with high display quality can be achieved.

Since the display portion 13 of the display apparatus 10B described as an example in this embodiment is divided into four parts in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 13 of the display apparatus 10B described as an example in this embodiment is divided into eight parts in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be inhibited and the time for rewriting image data can be easily ensured.

According to the display apparatus 10B of one embodiment of the present invention, sufficient time for writing image data can be easily ensured, and thus high-speed rewriting of a display image can be achieved. Thus, a display apparatus with high display quality can be achieved. In particular, a display apparatus that excels in displaying a moving image can be achieved.

### Modification Example 2

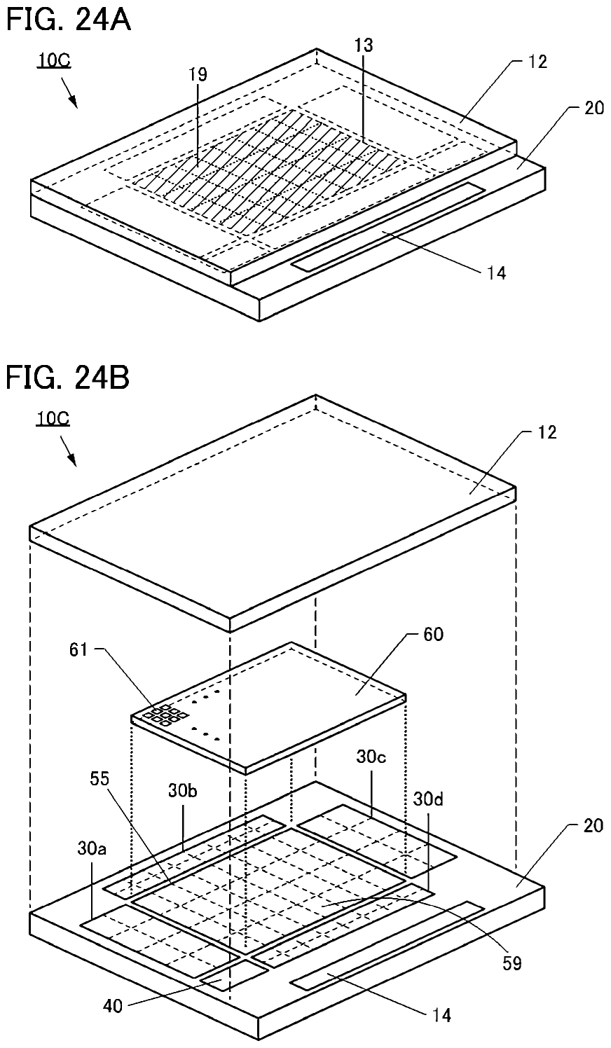

FIG. 24A and FIG. 24B are perspective views of a display apparatus 10C, which is a modification example of the display apparatus 10A. Note that the display apparatus 10C is also a modification example of the display apparatus 10B. FIG. 24B is a perspective view illustrating structures of layers included in the display apparatus 10C. Note that description is made mainly on portions different from those of the display apparatus 10A and the display apparatus 10B to reduce repeated description.

The pixel circuit group 55 including the plurality of pixel circuits 51, the driver circuit 30, the functional circuit 40, and the terminal portion 14 may be provided in the same layer. In the display apparatus 10C, the pixel circuit group 55, the driver circuit 30, the functional circuit 40, and the terminal portion 14 are provided in the layer 20. Since the pixel circuit group 55, the driver circuit 30, and the functional circuit 40 are provided in the same layer, wirings electrically connecting the circuits can be short. Thus, wiring resistance and parasitic capacitance are reduced, leading to lower power consumption.

In the case where a c-Si transistor is used as a transistor included in the display apparatus 10C, for example, a single crystal silicon substrate can be used as the layer 20 and the pixel circuit group 55, the driver circuit 30, the functional circuit 40, and the terminal portion 14 can be provided. When a single crystal silicon substrate is used as the layer 20, the substrate 11 can be omitted. As a result, a reduction in the weight of the display apparatus 10C can be achieved. In addition, the cost of manufacturing the display apparatus 10C can be reduced. Thus, the productivity of the display apparatus 10C can be improved.

Note that a transistor used in the display apparatus 10C is not limited to a c-Si transistor. Any of a variety of transistors such as a Poly-Si transistor or an OS transistor can be employed as the transistor used in the display apparatus 10C.

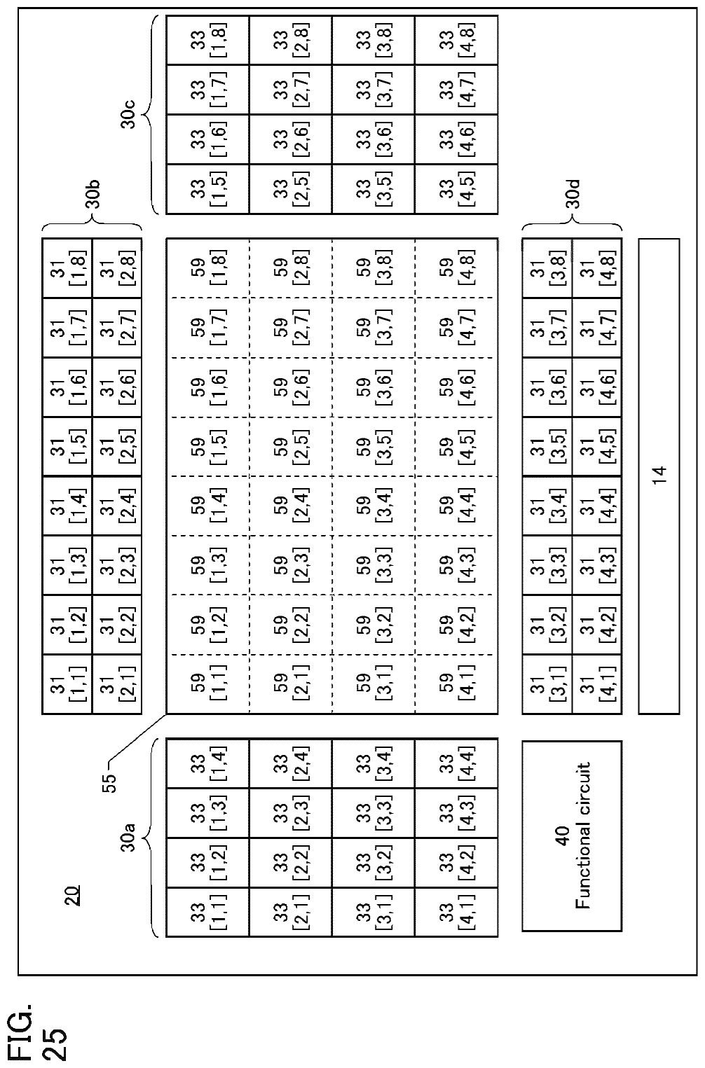

In the display apparatus 10C illustrated in FIG. 24, the display portion 13 is composed of the sub-display portions 19 arranged in a matrix of m rows and n columns. Accordingly, the pixel circuit group 55 is divided into the sections 59 arranged in a matrix of m rows and n columns. FIG. 25 illustrates a planar layout of the layer 20. FIG. 25 illustrates the sections 59 of the case where m is 4 and n is 8.

The driver circuit 30 is provided in the display apparatus 10C as four divided regions: a driver circuit 30a, a driver circuit 30b, a driver circuit 30c, and a driver circuit 30d. The driver circuit 30a, the driver circuit 30b, the driver circuit 30c, and the driver circuit 30d are provided outside the pixel circuit group 55. Specifically, the driver circuit 30a is provided on a first side of the four sides of the pixel circuit group 55, the driver circuit 30c is provided on a third side that faces the first side with the pixel circuit group 55 positioned therebetween, the driver circuit 30b is provided on a second side, and the driver circuit 30d is provided on a fourth side that faces the second side with the pixel circuit group 55 positioned therebetween.

The driver circuit 30a and the driver circuit 30c each include 16 gate driver circuits 33. The driver circuit 30b and the driver circuit 30d each include 16 source driver circuits 31. One of the gate driver circuits 33 is electrically connected to the plurality of pixel circuits 51 included in the section 59. One of the source driver circuits 31 is electrically connected to the plurality of pixel circuits 51 included in the section 59.

The gate driver circuit 33 electrically connected to the section 59[1,1] is denoted as a gate driver circuit 33[1,1], and the source driver circuit 31 electrically connected to the section 59[1,1] is denoted as a source driver circuit 31[1,1] in FIG. 25. Similarly, the gate driver circuit 33 electrically connected to a section 59[4,8] is denoted as a gate driver circuit 33[4,8], and the source driver circuit 31 electrically connected to the section 59[4,8] is denoted as a source driver circuit 31[4,8].

The driver circuit 30a includes the gate driver circuit 33[1,1] to a gate driver circuit 33[1,4], a gate driver circuit 33[2,1] to a gate driver circuit 33[2,4], a gate driver circuit 33[3,1] to a gate driver circuit 33[3,4], and a gate driver circuit 33[4,1] to a gate driver circuit 33[4,4]. The driver circuit 30b includes the source driver circuit 31[1,1] to a source driver circuit 31[1,8] and a source driver circuit 31[2,1] to a source driver circuit 31[2,8]. The driver circuit 30c includes a gate driver circuit 33[1,5] to a gate driver circuit 33[1,8], a gate driver circuit 33[2,5] to a gate driver circuit 33[2,8], a gate driver circuit 33[3,5] to a gate driver circuit 33[3,8], and a gate driver circuit 33[4,5] to the gate driver circuit 33[4,8]. The driver circuit 30d includes a source driver circuit 31[3,1] to a source driver circuit 31[3,8] and a source driver circuit 31[4,1] to the source driver circuit 31[4,8].

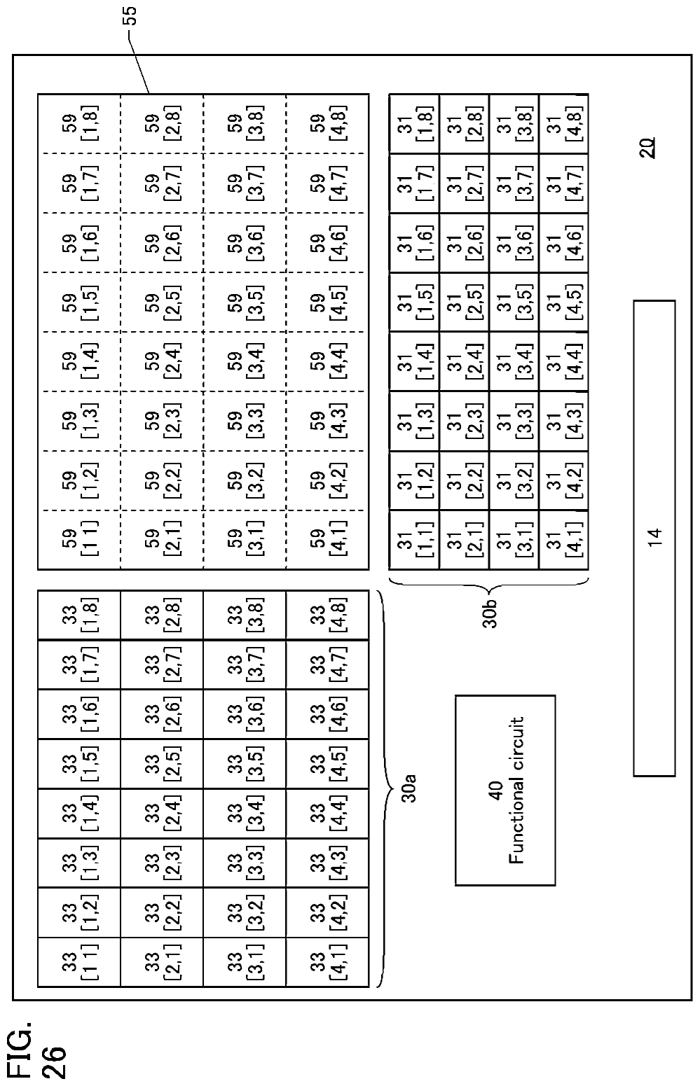

The positions of the pixel circuit group 55, the driver circuit 30, and the functional circuit 40 provided in the layer 20 are not limited to those illustrated in FIG. 25. For example, a structure illustrated in FIG. 26 may be employed. In FIG. 26, the driver circuit 30 is provided as two divided regions: the driver circuit 30a and the driver circuit 30b. For example, the driver circuit 30a includes 32 gate driver circuits 33 (the gate driver circuit 33[1,1] to the gate driver circuit 33[4,8]) and the driver circuit 30b includes 32 source driver circuits 31 (the source driver circuit 31[1,1] to the source driver circuit 31[4,8]).

Note that the display apparatus 10B and the display apparatus 10C according to one embodiment of the present invention are each an example in which the display portion 13 is divided into the 32 sub-display portions 19. However, the division number of the display portion 13 in each of the display apparatus 10B and the display apparatus 10C of one embodiment of the present invention may be 16, 64, 128, or the like, without limitation to 32. As the division number of the display portion 13 increases, a reduction in practical display quality perceived by the user can be smaller.

### Embodiment 3

In this embodiment, structure examples of a display apparatus that can be employed for the electronic device of one embodiment of the present invention will be described. A display apparatus described below as an example can be employed for the first display apparatus 1000, the second display apparatus 1002, and the like in Embodiment 1.

One embodiment of the present invention is a display apparatus including a light-emitting element (also referred to as a light-emitting device). The display apparatus includes two or more light-emitting elements of different emission colors. The light-emitting elements each include a pair of electrodes and an EL layer therebetween. The light-emitting elements are preferably organic EL elements (organic electroluminescent elements). The two or more light-emitting elements of different emission colors include EL layers containing different light-emitting materials. For example, when three kinds of light-emitting elements that emit red (R), green (G), and blue (B) light are included, a full-color display apparatus can be achieved.

In the case of manufacturing a display apparatus including a plurality of light-emitting elements of different emission colors, layers (light-emitting layers) containing at least light-emitting materials each need to be formed in an island shape. In the case of separately forming some or all parts of EL layers, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve the high resolution and high aperture ratio of the display apparatus. In addition, the outline of the layer might blur during evaporation, so that the thickness of an end portion might be reduced. That is, the thickness of an island-shaped light-emitting layer might vary from place to place. In addition, in the case of manufacturing a display apparatus with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display apparatus with high resolution and a high aperture ratio, which has been difficult to achieve. Moreover, since the EL layers can be formed separately, it is possible to achieve a display apparatus that performs extremely clear display with high contrast and high display quality. Note that fine patterning of the EL layers may be performed using both a metal mask and photolithography, for example.

In addition, some or all parts of the EL layers can be physically divided. This can inhibit leakage current flowing between adjacent light-emitting elements through a layer (also referred to as a common layer) shared by the light-emitting elements. Thus, it is possible to prevent crosstalk due to unintended light emission, so that a display apparatus with extremely high contrast can be achieved. In particular, a display apparatus having high current efficiency at low luminance can be achieved.

In one embodiment of the present invention, the display apparatus can be also obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, some or all parts of the EL layers are divided by photolithography. Thus, leakage current through the common layer is suppressed; accordingly, a high-contrast display apparatus can be achieved. In particular, when an element has a tandem structure in which a plurality of light-emitting layers are stacked with a highly conductive intermediate layer therebetween, leakage current through the intermediate layer can be effectively prevented, so that a display apparatus with high luminance, high resolution, and high contrast can be achieved.

Furthermore, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit degradation of the EL layer and can achieve a highly reliable display apparatus.

Moreover, between two adjacent light-emitting elements, there is a region (a concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as LFP: Local Filling Planarization) functioning as a planarization film. The resin layer has a function of a planarization film. This structure can inhibit disconnection of the common layer or the common electrode and can achieve a highly reliable display apparatus.

More specific structure examples of the display apparatus according to one embodiment of the present invention will be described below with reference to drawings.

### Structure Example 1

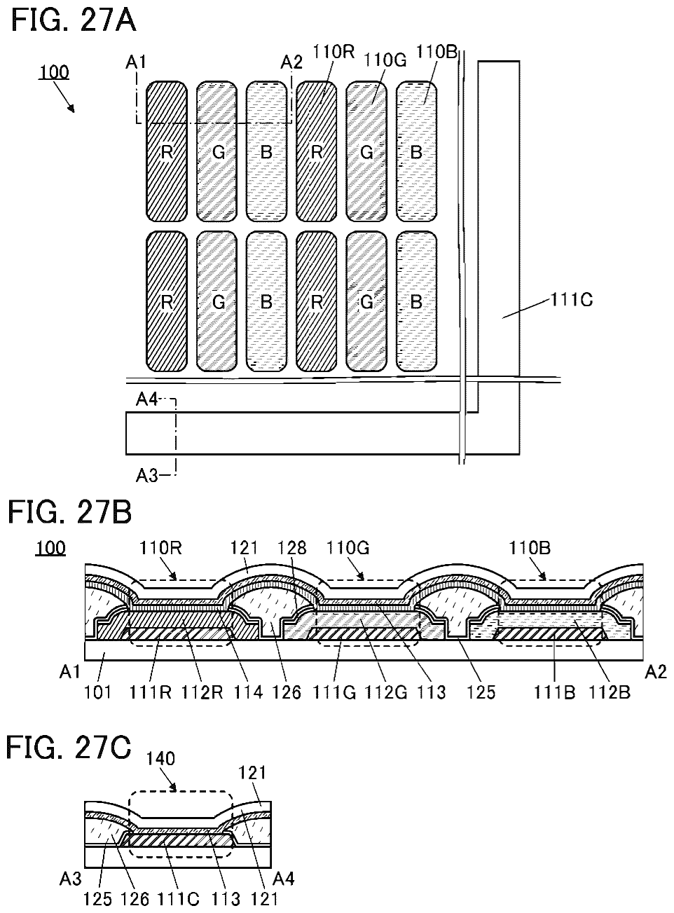

FIG. 27A illustrates a schematic top view of a display apparatus 100 according to one embodiment of the present invention. The display apparatus 100 includes, over a substrate 101, a plurality of light-emitting elements 110R exhibiting red, a plurality of light-emitting elements 110G exhibiting green, and a plurality of light-emitting elements 110B exhibiting blue. In FIG. 27A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 27A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given, for example. As the light-emitting substance contained in the EL element, not only an organic compound but also an inorganic compound (a quantum dot material or the like) can be used.

FIG. 27A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or may be provided across two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

FIG. 27B and FIG. 27C are schematic cross-sectional views corresponding to the dashed-dotted line A1-A2 and the dashed-dotted line A3-A4 in FIG. 27A. FIG. 27B illustrates a schematic cross-sectional view of the light-emitting element 110R, the light-emitting element 110G, and the light-emitting element 110B, and FIG. 27C illustrates a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can be also referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display apparatus can be obtained. In contrast, when the pixel electrodes have reflective properties and the common electrode 113 has a light-transmitting property, a top-emission display apparatus can be obtained. Note that when both the pixel electrodes and the common electrode 113 have light-transmitting properties, a dual-emission display apparatus can be also obtained.

A protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode has a tapered shape, the organic layer 112 provided along a side surface of the pixel electrode also has a tapered shape. When the side surface of the pixel electrode has a tapered shape, coverage with the EL layer provided along the side surface of the pixel electrode can be improved. Furthermore, when the side surface of the pixel electrode has a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. In contrast, an organic film formed using an FMM (Fine Metal Mask) or the like has a thickness that tends to gradually decrease with decreasing the distance from an end portion, and has a top surface forming a slope in the range of greater than or equal to 1 μm and less than or equal to 10 μm, for example. Thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to fill end portions of the organic layers 112 and a region between the two organic layers 112. The top surface of the resin layer 126 has a smooth convex shape, and the common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can be also referred to as LFP (Local Filling Planarization).

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with a top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 as described in this embodiment to protect the side surfaces of the organic layer.

An insulating layer containing an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method achieving good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 is provided to cover the common electrode 113.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat; therefore, when a structural object (e.g., a color filter, an electrode of a touch sensor, a lens array, or the like) is provided above the protective layer 121, the structural object can be less affected by an uneven shape caused by a lower structure.

FIG. 27C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 27C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

The above is the description of the structure example of the display apparatus.

### [Pixel Layout]

Pixel layout different from that in FIG. 27A will be mainly described below. There is no particular limitation on the arrangement of light-emitting elements (subpixels), and a variety of methods can be employed.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting element.

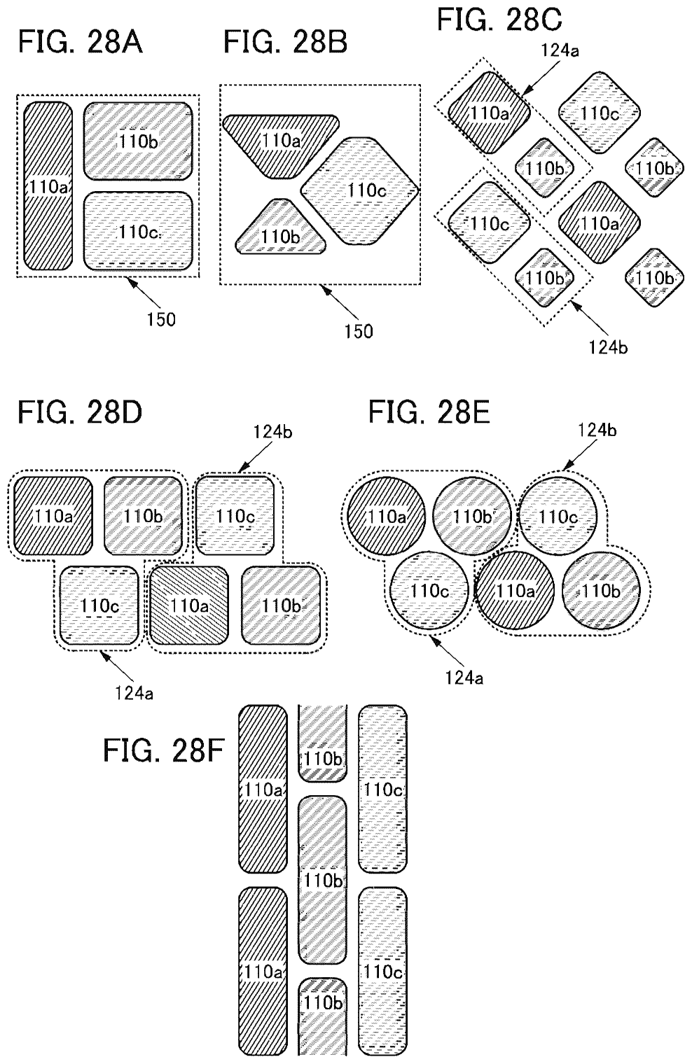

A pixel 150 illustrated in FIG. 28A employs an S-stripe arrangement. The pixel 150 illustrated in FIG. 28A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 28B includes the light-emitting element 110a having a rough trapezoidal top surface shape with rounded corners, the light-emitting element 110b having a rough triangle top surface shape with rounded corners, and the light-emitting element 110c having a rough tetragonal or rough hexagonal top surface shape with rounded corners. The light-emitting element 110a has a larger light-emitting area than the light-emitting element 110b. In this manner, the shapes and sizes of the light-emitting elements can be determined independently. For example, the size of a light-emitting element with higher reliability can be made smaller. For example, the light-emitting element 110a may be a green-light-emitting element, the light-emitting element 110b may be a red-light-emitting element, and the light-emitting element 110c may be a blue-light-emitting element.

Pixels 124a and 124b illustrated in FIG. 28C employ a PenTile arrangement. FIG. 28C illustrates an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red-light-emitting element, the light-emitting element 110b may be a green-light-emitting element, and the light-emitting element 110c may be a blue-light-emitting element.

The pixels 124a and 124b illustrated in FIG. 28D and FIG. 28E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red-light-emitting element, the light-emitting element 110b may be a green-light-emitting element, and the light-emitting element 110c may be a blue-light-emitting element.

FIG. 28D illustrates an example in which each light-emitting element has a rough tetragonal top surface shape with rounded corners, and FIG. 28E illustrates an example in which each light-emitting element has a circular top surface shape.

FIG. 28F illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red-light-emitting element, the light-emitting element 110b may be a green-light-emitting element, and the light-emitting element 110c may be a blue-light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element sometimes has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, the top surface of the EL layer has a polygonal shape with rounded corners, an elliptical shape, a circular shape, or the like in a some cases. For example, when a resist mask with a square top surface shape is intended to be formed, a resist mask with a circular top surface shape might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in appropriate combination with the other embodiments described in this specification.

### Embodiment 4

In this embodiment, other structure examples of a display apparatus (display panel) that can be used for the electronic device of one embodiment of the present invention are described. Display apparatuses (display panels) described below as examples can be used as the first display apparatus 1000, the second display apparatus 1002, and the like in Embodiment 1.

Display apparatuses in this embodiment can be high-resolution display apparatuses. For example, display apparatuses according to one embodiment of the present invention can be used for display portions of information terminal devices (wearable devices) such as wristwatch-type and bracelet-type information terminal devices and display portions of wearable devices that can be worn on a head, such as VR devices like head-mounted displays and glasses-type AR devices.

### [Display Module]

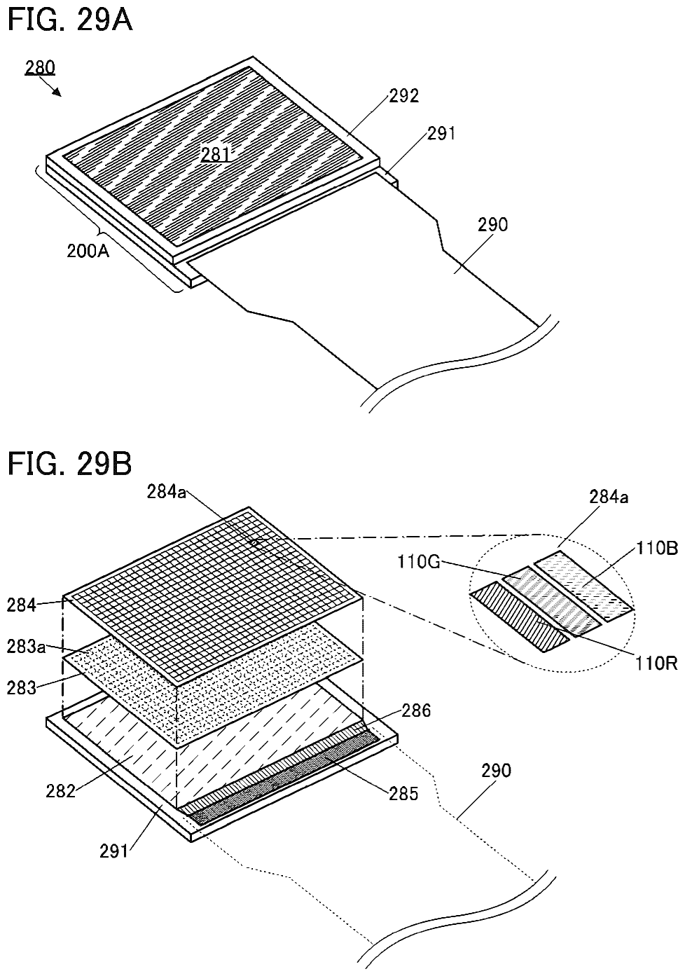

FIG. 29A is a perspective view of a display module 280. The display module 280 includes a display apparatus 200A and an FPC 290. Note that a display panel included in the display module 280 is not limited to the display apparatus 200A and may be any of a display apparatus 200B to a display apparatus 200G described later.

The display module 280 includes a substrate 291 and a substrate 292. The display module 280 includes a display portion 281. The display portion 281 is a region where an image is displayed.

FIG. 29B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 29B. The pixel 284a includes the light-emitting element 110R that emits red light, the light-emitting element 110G that emits green light, and the light-emitting element 110B that emits blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor element for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. In addition, an IC may be mounted on the FPC 290.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even in the case of a structure in which the display portion of the display module 280 is seen through a lens, pixels of the extremely-high-resolution display portion 281 included in the display module 280 are not seen even when the display portion is enlarged by the lens, so that display providing a high sense of immersion can be performed. Without being limited thereto, the display module 280 can be also suitably used for an electronic device having a comparatively small display portion. For example, the display module 280 can be suitably used for a display portion of a wearable electronic device, such as a wristwatch.

### [Display Apparatus 200A]

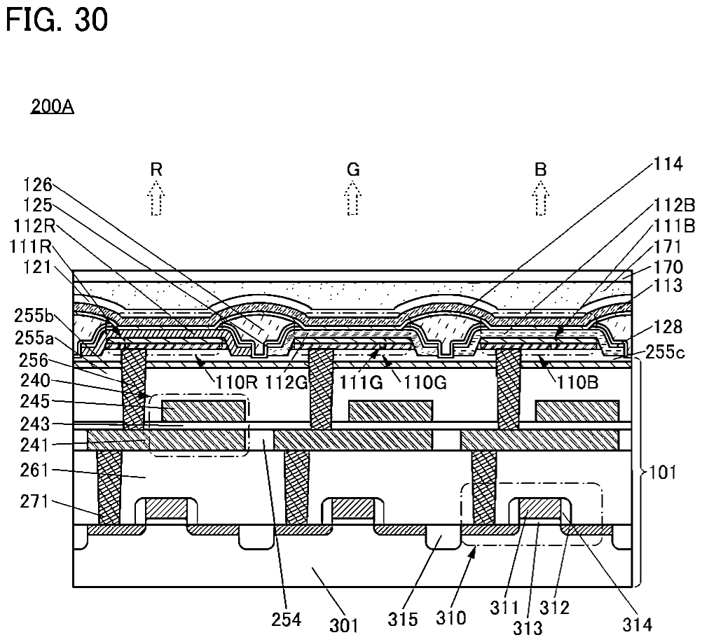

The display apparatus 200A illustrated in FIG. 30 includes a substrate 301, the light-emitting elements 110R, 110G, and 110B, capacitors 240, and transistors 310.

The substrate 301 corresponds to the substrate 291 in FIG. 29A and FIG. 29B.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layers 314 are provided to cover side surfaces of the conductive layer 311.

In addition, an element isolation layer 315 is provided between two adjacent transistors 310 to be embedded in the substrate 301

Furthermore, an insulating layer 261 is provided to cover the transistors 310, and the capacitors 240 are provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240. An insulating layer 255b is provided over the insulating layer 255a. An insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example in which the insulating layer 255c is partly etched and a concave portion is formed, the concave portion is not necessarily provided in the insulating layer 255c.

The light-emitting element 110R, the light-emitting element 110G, and the light-emitting element 110B are provided over the insulating layer 255c. Embodiment 3 can be referred to for the structures of the light-emitting element 110R, the light-emitting element 110G, and the light-emitting element 110B. Here, a stacked-layer structure including the substrate 301 and the components thereover up to the insulating layer 255c corresponds to the substrate 101 in Embodiment 3.

In the display apparatus 200A, since the light-emitting devices of different colors are separately formed, a change in chromaticity between light emission at low luminance and light emission at high luminance is small. Furthermore, since the organic layers 112R, 112G, and 112B are separated from each other, crosstalk generated between adjacent subpixels can be inhibited while the display panel has high resolution. It is thus possible to achieve a display apparatus that has high resolution and high display quality.

In a region between adjacent light-emitting elements, the insulating layer 125, the resin layer 126, and the layer 128 are provided.

The pixel electrode 111R, the pixel electrode 111G, and the pixel electrode 111B of the light-emitting elements are each electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. The top surface of the insulating layer 255c and the top surface of the plug 256 are level with or substantially level with each other. A variety of conductive materials can be used for the plugs.

In addition, the protective layer 121 is provided over the light-emitting elements 110R, 110G, and 110B. A substrate 170 is attached onto the protective layer 121 with an adhesive layer 171.

An insulating layer covering an end portion of the top surface of the pixel electrode 111 is not provided between two adjacent pixel electrodes 111. Thus, the distance between adjacent light-emitting elements can be extremely narrowed. Accordingly, the display apparatus can have high resolution or high definition.

### [Display Apparatus 200B]

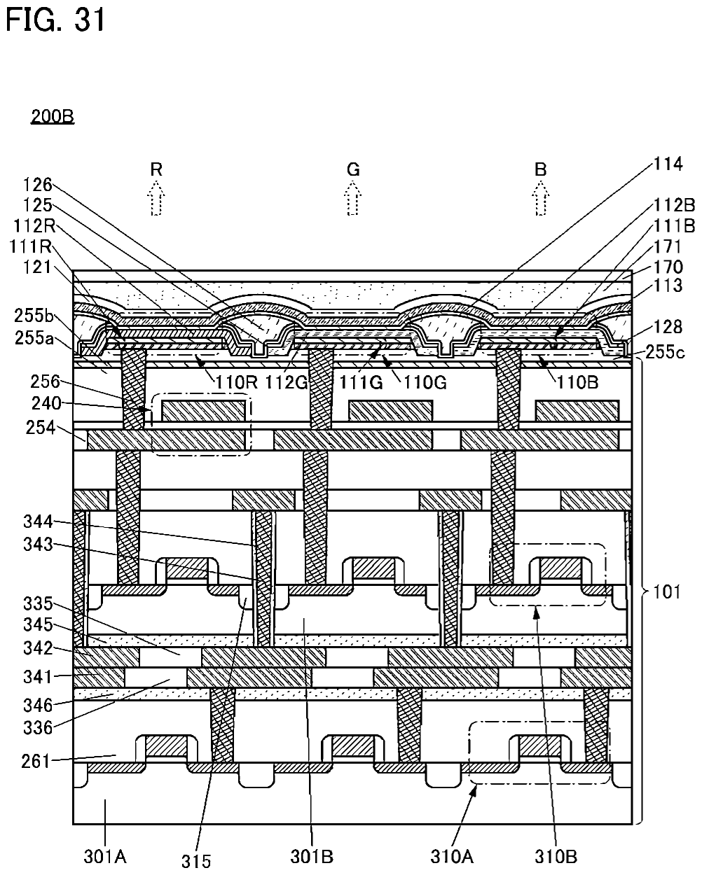

The display apparatus 200B illustrated in FIG. 31 has a structure in which transistors 310A and transistors 310B in each of which a channel is formed in a semiconductor substrate are stacked. Note that in the following description of the display panel, the description of portions similar to those of the above display panel is omitted in some cases.

The display apparatus 200B has a structure in which a substrate 301B provided with the transistors 310B, the capacitors 240, and the light-emitting devices is attached to a substrate 301A provided with the transistors 310A.

Here, an insulating layer 345 is provided on a bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 121 or an insulating layer 332 described later can be used.

The substrate 301B is provided with plugs 343 that penetrate the substrate 301B and the insulating layer 345. Here, insulating layers 344 each functioning as a protective layer are preferably provided to cover side surfaces of the plugs 343.

A conductive layer 342 is provided under the insulating layer 345 on the substrate 301B. The conductive layer 342 is embedded in an insulating layer 335, and bottom surfaces of the conductive layer 342 and the insulating layer 335 are planarized. Furthermore, the conductive layer 342 is electrically connected to the plug 343.

In contrast, a conductive layer 341 is provided over the insulating layer 346 over the substrate 301A. The conductive layer 341 is embedded in an insulating layer 336, and the top surfaces of the conductive layer 341 and the insulating layer 336 are planarized.

The same conductive material is preferably used for the conductive layer 341 and the conductive layer 342. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 341 and the conductive layer 342. Accordingly, it is possible to employ a Cu-to-Cu (copper-to-copper) direct bonding technique (a technique for achieving electrical continuity by connecting Cu (copper) pads to each other).

### [Display Apparatus 200C]

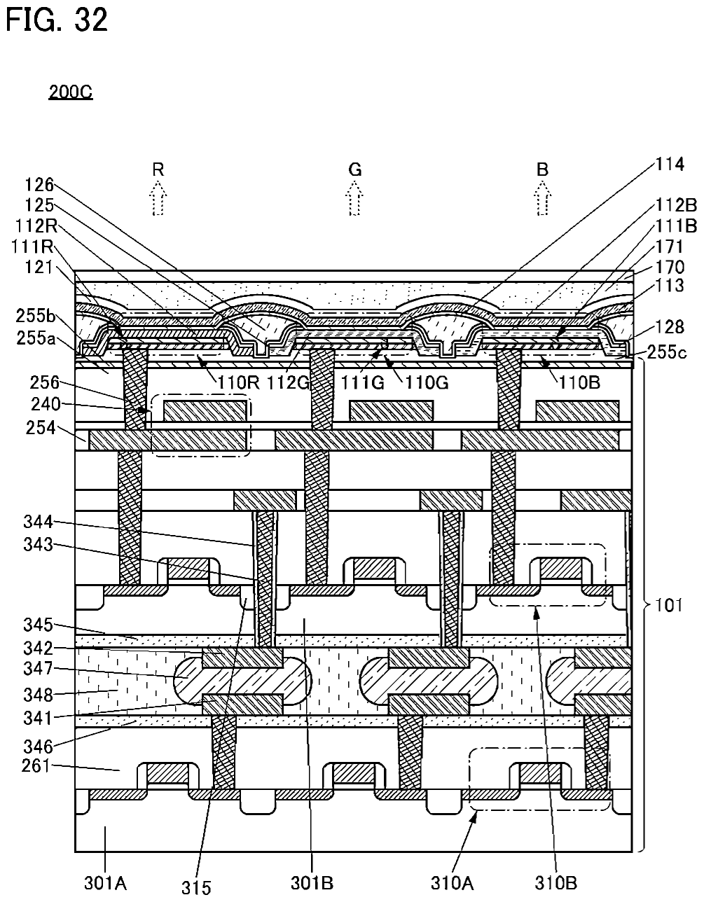

The display apparatus 200C illustrated in FIG. 32 has a structure where the conductive layer 341 and the conductive layer 342 are bonded to each other with a bump 347.

As illustrated in FIG. 32, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder is used for the bump 347 in some cases. An adhesive layer 348 may be provided between the insulating layer 345 and the insulating layer 346. In the case where the bump 347 is provided, a structure without the insulating layer 335 and the insulating layer 336 may be employed.

### [Display Apparatus 200D]

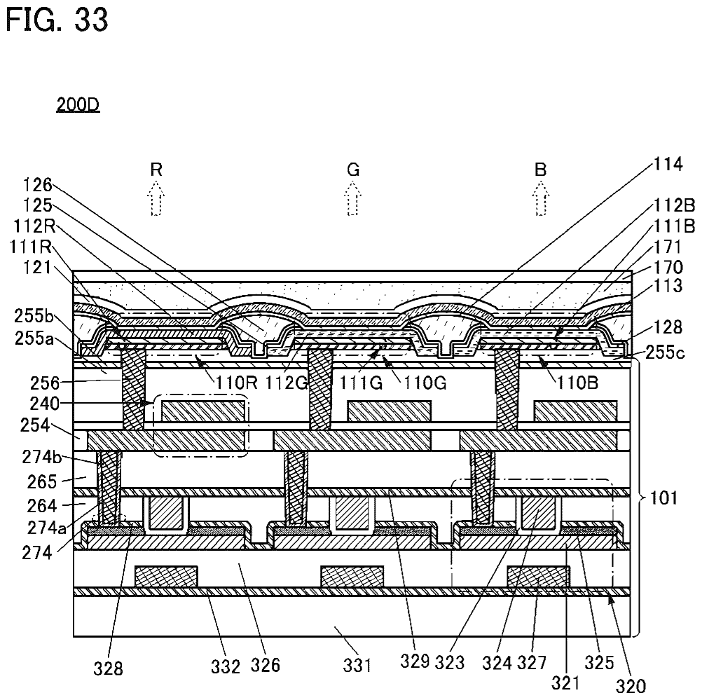

The display apparatus 200D illustrated in FIG. 33 differs from the display apparatus 200A mainly in a transistor structure.

A transistor 320 is a transistor (an OS transistor) in which a metal oxide (also referred to as an oxide semiconductor) is employed in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 29A and FIG. 29B.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided on and in contact with the semiconductor layer 321, and functions as a source electrode and a drain electrode.

An insulating layer 328 is provided to cover the top surfaces and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. For the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with the top surface of the semiconductor layer 321 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like to the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers side surfaces of openings in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material in which hydrogen and oxygen are less likely to diffuse is preferably used for the conductive layer 274a.

### [Display Apparatus 200E]

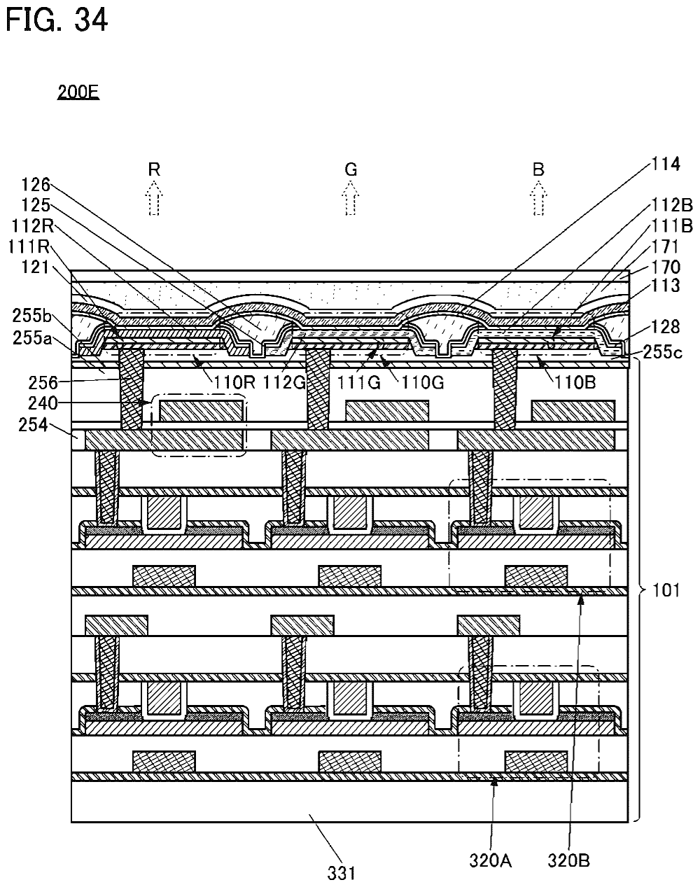

The display apparatus 200E illustrated in FIG. 34 has a structure in which a transistor 320A and a transistor 320B each including an oxide semiconductor in a semiconductor where a channel is formed are stacked.

The display apparatus 200D described above can be referred to for the transistor 320A, the transistor 320B, and other peripheral structures.

Note that although the structure in which two transistors including an oxide semiconductor are stacked is described here, the present invention is not limited thereto. For example, a structure may be employed in which three or more transistors are stacked.

### [Display Apparatus 200F]

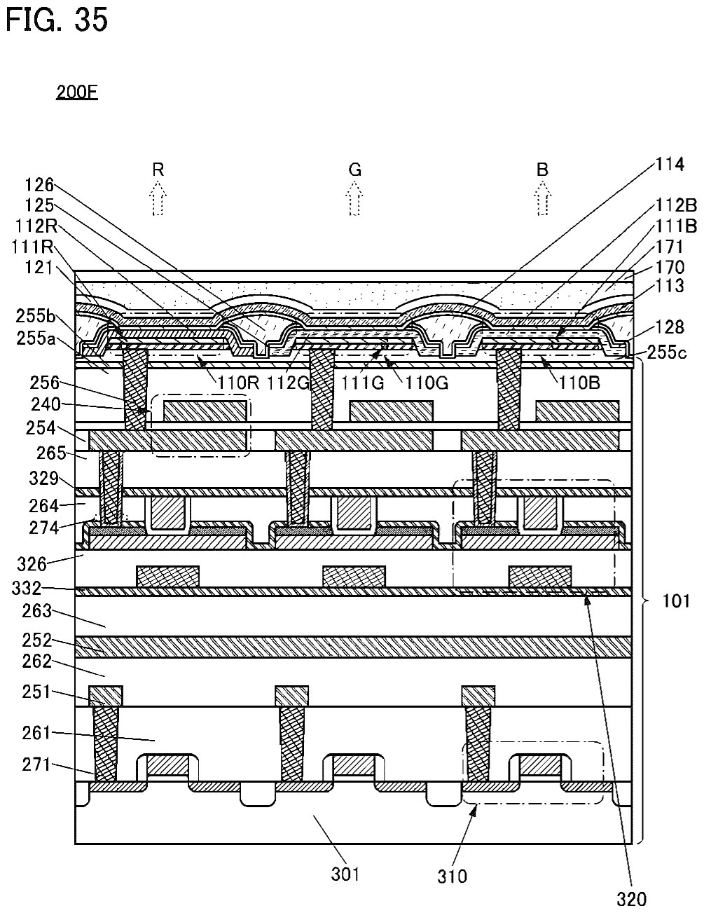

The display apparatus 200F illustrated in FIG. 35 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit (a gate line driver circuit or a source line driver circuit) for driving the pixel circuit. Furthermore, the transistor 310 and the transistor 320 can be used as transistors included in a variety of circuits such as an arithmetic circuit or a memory circuit.

With such a structure, not only the pixel circuit but also the driver circuit and the like can be formed directly under the light-emitting devices; thus, the display panel can be downsized as compared with the case where the driver circuit is provided around a display region.

### [Display Apparatus 200G]

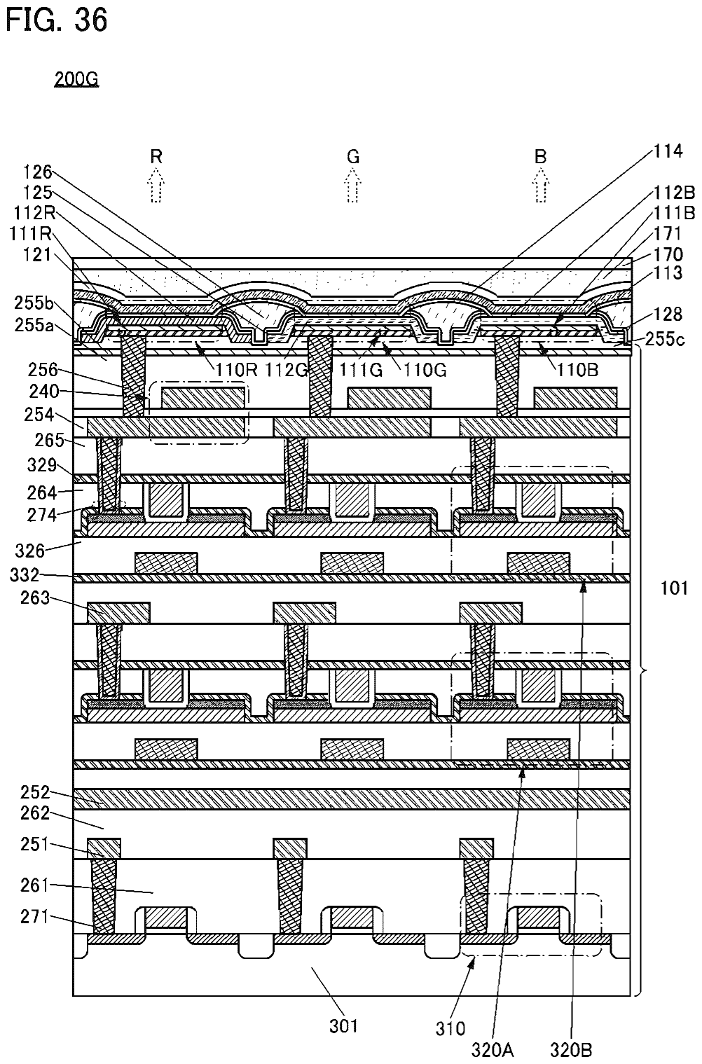

A display apparatus 200G illustrated in FIG. 36 has a structure in which the transistor 310 whose channel is formed in the substrate 301, the transistor 320A including a metal oxide in the semiconductor layer where the channel is formed, and the transistor 320B are stacked.

The transistor 320A can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 320B may be used as a transistor included in the pixel circuit or a transistor included in the driver circuit. The transistor 310, the transistor 320A, and the transistor 320B can also be used as transistors included in a variety of circuits such as an arithmetic circuit and a memory circuit.

At least part of this embodiment can be implemented in appropriate combination with the other embodiments described in this specification.

### Embodiment 5

In this embodiment, a light-emitting device (light-emitting element) that can be used in the display apparatus of one embodiment of the present invention will be described.

In this specification and the like, a device manufactured using a metal mask or an FMM (a fine metal mask, a high-resolution metal mask) may be referred to as a device having an MM (a metal mask) structure. In this specification and the like, a device manufactured without using a metal mask or an FMM may be referred to as a device having an MML (a metal maskless) structure.

In this specification and the like, a structure in which at least light-emitting layers of light-emitting devices with different emission wavelengths are separately formed may be referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

As the light-emitting device, an OLED (Organic Light Emitting Diode) or a QLED (Quantum-dot Light Emitting Diode) is preferably used, for example. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material). An LED (Light Emitting Diode) such as a micro LED can also be used as the light-emitting device.

The emission color of the light-emitting device can be infrared, red, green, blue, cyan, magenta, yellow, white, or the like. When the light-emitting device has a microcavity structure, the color purity can be increased.

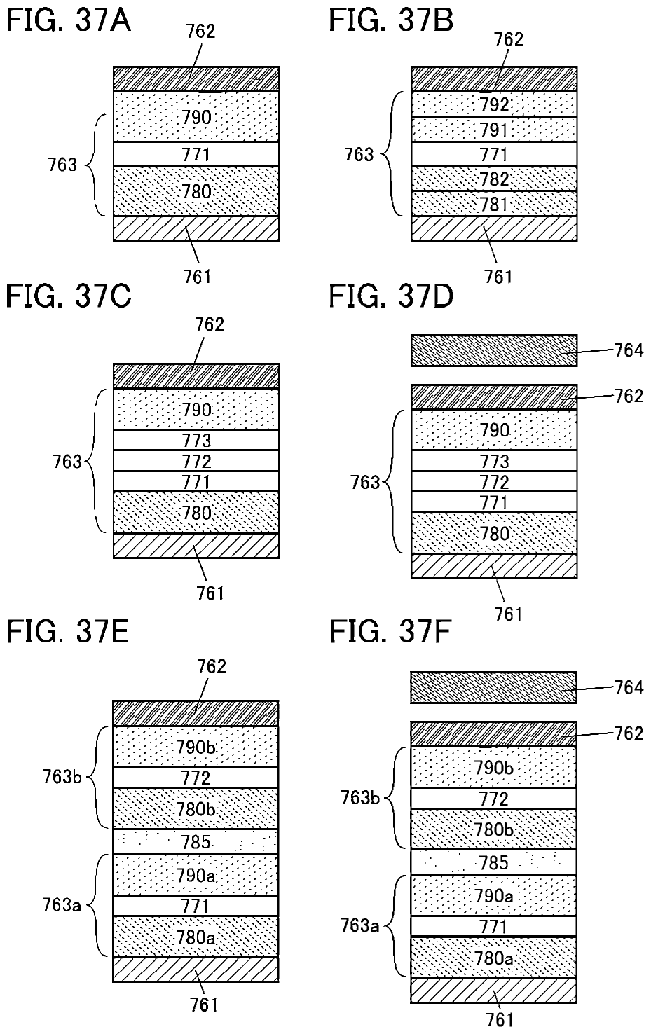

As illustrated in FIG. 37A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). The layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 37A is referred to as a single structure in this specification.

FIG. 37B is a modification example of the EL layer 763 included in the light-emitting device illustrated in FIG. 37A. Specifically, the light-emitting device illustrated in FIG. 37B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected into the light-emitting layer 771, and the efficiency of the recombination of carriers in the light-emitting layer 771 can be enhanced.

Note that structures in which a plurality of light-emitting layers (light-emitting layers 771, 772, and 773) are provided between the layer 780 and the layer 790 as illustrated in FIG. 37C and FIG. 37D are other variations of the single structure. Although FIG. 37C and FIG. 37D illustrate the examples where three light-emitting layers are included, the light-emitting device having a single structure may include two or four or more light-emitting layers. In addition, the light-emitting device having a single structure may include a buffer layer between two light-emitting layers.

A structure in which a plurality of light-emitting units (a light-emitting unit 763a and a light-emitting unit 763b) are connected in series with a charge-generation layer 785 (also referred to as an intermediate layer) therebetween as illustrated in FIG. 37E and FIG. 37F is referred to as a tandem structure in this specification. Note that a tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability.

Note that FIG. 37D and FIG. 37F illustrate examples in which the display apparatus includes a layer 764 overlapping with the light-emitting device. FIG. 37D illustrates an example in which the layer 764 overlaps with the light-emitting device illustrated in FIG. 37C, and FIG. 37F illustrates an example in which the layer 764 overlaps with the light-emitting device illustrated in FIG. 37E.

One or both of a color conversion layer and a color filter (a coloring layer) can be used as the layer 764.

In FIG. 37C and FIG. 37D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 37D, blue light emitted from the light-emitting device can be converted into light with a longer wavelength, and red or green light can be extracted.

Alternatively, light-emitting substances that emit light of different colors may be used for the light-emitting layer 771, the light-emitting layer 772, and the light-emitting layer 773. White light can be obtained when the light-emitting layer 771, the light-emitting layer 772, and the light-emitting layer 773 emit light of complementary colors. The light-emitting device having a single structure preferably includes a light-emitting layer containing a light-emitting substance emitting blue light and a light-emitting layer containing a light-emitting substance emitting visible light with a longer wavelength than blue light, for example.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer containing a light-emitting substance emitting blue (B) light and a light-emitting layer containing a light-emitting substance emitting yellow light are preferably included. Such a structure may be referred to as a BY single structure.

A color filter may be provided as the layer 764 illustrated in FIG. 37D. When white light passes through the color filter, light of a desired color can be obtained.

The light-emitting device that emits white light preferably contains two or more kinds of light-emitting substances. To obtain white light emission, two or more kinds of light-emitting substances are selected such that they emit light of complementary colors. For example, when an emission color of a first light-emitting layer and an emission color of a second light-emitting layer are complementary colors, the light-emitting device can emit white light as a whole. The same applies to a light-emitting device including three or more light-emitting layers.

In FIG. 37E and FIG. 37F, light-emitting substances that emit light of the same color, or moreover, the same light-emitting substance may be used for the light-emitting layer 771 and the light-emitting layer 772.

For example, in light-emitting devices included in subpixels emitting light of different colors, a light-emitting substance that emits blue light can be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 37F, blue light emitted from the light-emitting device can be converted into light with a longer wavelength, and red or green light can be extracted.

In the case where the light-emitting device having the structure illustrated in FIG. 37E or FIG. 37F is used for the subpixels emitting different colors, the subpixels may use different light-emitting substances. Specifically, in the light-emitting device included in the subpixel emitting red light, a light-emitting substance that emits red light can be used for each of the light-emitting layer 771 and the light-emitting layer 772. Similarly, in the light-emitting device included in the subpixel emitting green light, a light-emitting substance that emits green light can be used for each of the light-emitting layer 771 and the light-emitting layer 772. In the light-emitting device included in the subpixel emitting blue light, a light-emitting substance that emits blue light can be used for each of the light-emitting layer 771 and the light-emitting layer 772. A display apparatus with such a structure includes a light-emitting device with a tandem structure and can be regarded to have an SBS structure. Thus, the display apparatus can take advantages of both the tandem structure and the SBS structure. Accordingly, a highly reliable light-emitting device capable of high luminance light emission can be obtained.

In FIG. 37E and FIG. 37F, light-emitting substances emitting light of different colors may be used for the light-emitting layer 771 and the light-emitting layer 772. White light can be obtained when the light-emitting layer 771 and the light-emitting layer 772 emit light of complementary colors. A color filter may be provided as the layer 764 illustrated in FIG. 37F. When white light passes through the color filter, light of a desired color can be obtained.

Although FIG. 37E and FIG. 37F illustrate examples where the light-emitting unit 763a includes one light-emitting layer 771 and the light-emitting unit 763b includes one the light-emitting layer 772, one embodiment of the present invention is not limited thereto. Each of the light-emitting unit 763a and the light-emitting unit 763b may include two or more light-emitting layers.

Although FIG. 37E and FIG. 37F each illustrate the light-emitting device including two light-emitting units, one embodiment of the present invention is not limited thereto. The light-emitting device may include three or more light-emitting units.

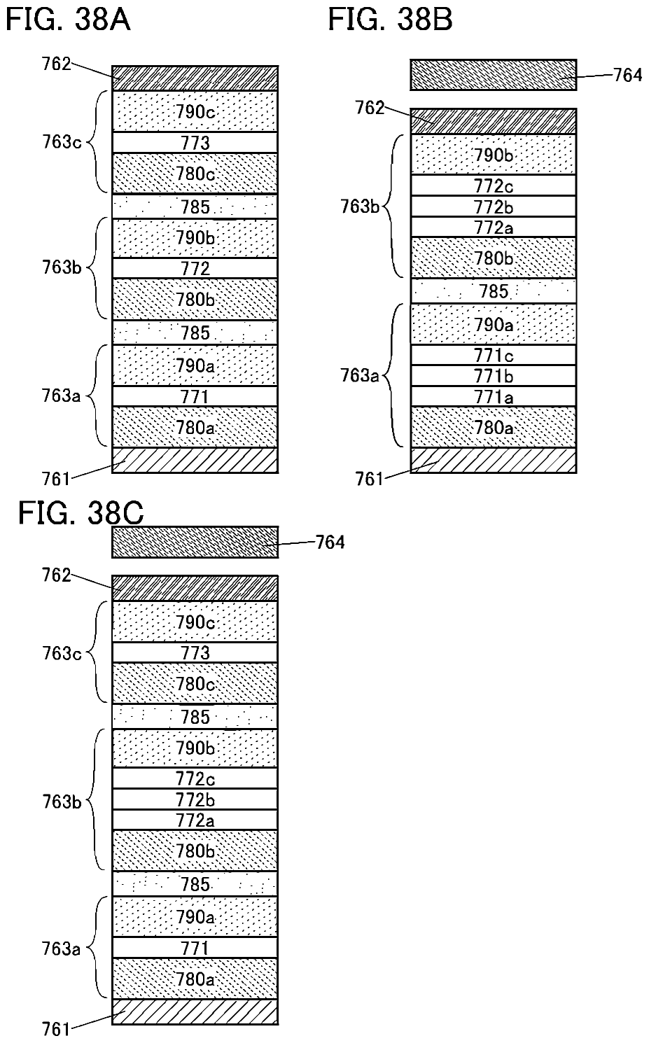

Specifically, the light-emitting device may have any of structures illustrated in FIG. 38A to 38C.

FIG. 38A illustrates a structure including three light-emitting units. Note that a structure including two light-emitting units and a structure including three light-emitting units may be referred to as a two-unit tandem structure and a three-unit tandem structure, respectively.

As illustrated in FIG. 38A, a plurality of light-emitting units (the light-emitting unit 763a, the light-emitting unit 763b, and the light-emitting unit 763c) are connected in series through the charge-generation layers 785. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

Note that in the structure illustrated in FIG. 38A, the light-emitting layer 771, the light-emitting layer 772, and the light-emitting layer 773 preferably contain light-emitting substances that emit light of the same color. Specifically, a structure in which the light-emitting layer 771, the light-emitting layer 772, and the light-emitting layer 773 each contain a red (R) light-emitting substance (what is called a three-unit tandem structure of R\R\R), a structure in which the light-emitting layer 771, the light-emitting layer 772, and the light-emitting layer 773 each contain a green (G) light-emitting substance (what is called a three-unit tandem structure of G\G\G), or a structure in which the light-emitting layer 771, the light-emitting layer 772, and the light-emitting layer 773 each contain a blue (B) light-emitting substance (what is called a three-unit tandem structure of B\B\B) can be employed.

Note that the structure containing the light-emitting substances that emit light of the same color is not limited to the above structure. For example, a light-emitting device with a tandem structure may be employed in which light-emitting units each containing a plurality of light-emitting substances are stacked as illustrated in FIG. 38B. FIG. 38B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a, and the light-emitting unit 763b includes the layer 780b, a light-emitting layer 772a, a light-emitting layer 772b, a light-emitting layer 772c, and the layer 790b.

In the structure illustrated in FIG. 38B, light-emitting substances for the light-emitting layer 771a, the light-emitting layer 771b, and the light-emitting layer 771c are selected so as to emit light of complementary colors to obtain white (W) light emission. Furthermore, light-emitting substances for the light-emitting layer 772a, the light-emitting layer 772b, and the light-emitting layer 772c are selected so as to emit light of complementary colors to obtain white (W) light emission. That is, the structure illustrated in FIG. 38C is a two-unit tandem structure of WWW. Note that there is no particular limitation on the stacking order of the light-emitting substances emitting light of complementary colors for the light-emitting layer 771a, the light-emitting layer 771b, and the light-emitting layer 771c. The practitioner can select the optimal stacking order as appropriate. Although not illustrated, a three-unit tandem structure of W\W\W or a tandem structure with four or more units may be employed.

In the case of a light-emitting device with a tandem structure, any of the following structures may be employed, for example: a two-unit tandem structure of BY including a light-emitting unit that emits yellow (Y) light and a light-emitting unit that emits blue (B) light; a two-unit tandem structure of R·G\B including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order.

Alternatively, a light-emitting unit containing one light-emitting substance and a light-emitting unit containing a plurality of light-emitting substances may be used in combination as illustrated in FIG. 38C.

Specifically, in the structure illustrated in FIG. 38C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes a layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 38C, for example, a three-unit tandem structure of B\R·G·YG\B in which the light-emitting unit 763a is a light-emitting unit emitting blue (B) light, the light-emitting unit 763b is a light-emitting unit emitting red (R), green (G), and yellow-green (YG) light, and the light-emitting unit 763c is a light-emitting unit emitting blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Also in FIG. 37C and FIG. 37D, the layer 780 and the layer 790 may each independently have a stacked-layer structure of two or more layers as illustrated in FIG. 37B.

In FIG. 37E and FIG. 37F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting device will be described.

A conductive film transmitting visible light is used as the electrode through which light is extracted, which is either the lower electrode 761 or the upper electrode 762. A conductive film that reflects visible light is preferably used for the electrode through which light is not extracted. In the case where a display apparatus includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also for the electrode through which light is not extracted. In this case, this electrode is preferably provided between the reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Accordingly, one of the pair of electrodes of the light-emitting device is preferably an electrode having a transmitting property and a reflecting property with respect to visible light (transflective electrode), and the other is preferably an electrode having a reflecting property with respect to visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer having a visible-light-transmitting property (also referred to as a transparent electrode).

The light transmittance of the transparent electrode is higher than or equal to 40%. For example, an electrode having a visible light (light with wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be contained. Each layer included in the light-emitting device can be formed, for example, by an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material with a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer that injects holes from an anode to the hole-transport layer and contains a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can also be used.

For example, a hole-transport material and a material containing an oxide of a metal belonging to Group 4 to Group 8 of the periodic table (typically, molybdenum oxide) may be used as the material having a high hole-injection property.

The hole-transport layer is a layer transporting holes, which are injected from the anode by the hole-injection layer, to the light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a x-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a T-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2-(1,3-phenylene)bis[9-phenyl-1,10-phenanthroline] (abbreviation: mPPhen2P), diquinoxalino[2,3-a:2′,3′-c] phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 6

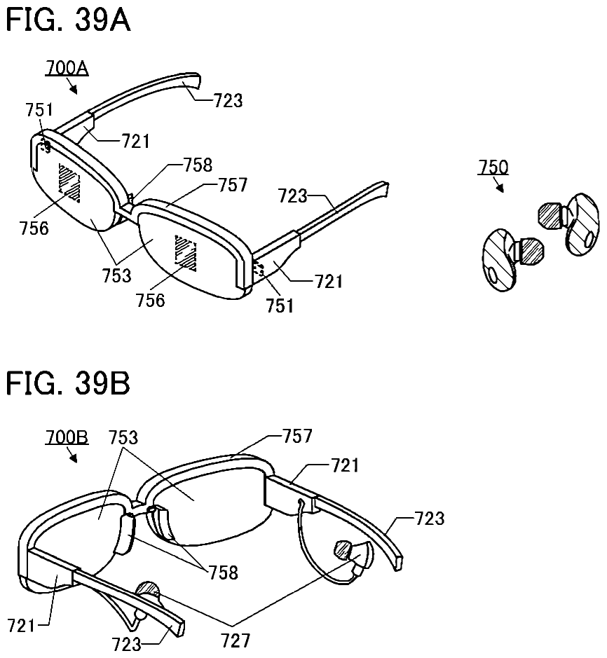

In this embodiment, electronic devices that can be used as the display apparatus of one embodiment of the present invention will be described with reference to FIG. 39A to FIG. 44B.

Electronic devices in this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminal devices (wearable devices) and wearable devices capable of being worn on a head, such as a VR device like a head-mounted display, a glasses-type AR device illustrated in FIG. 3A or the like, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

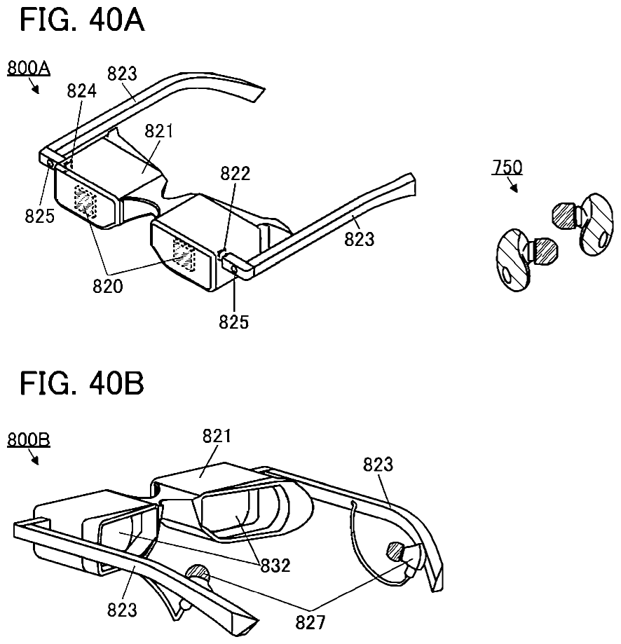

Examples of a wearable device that can be worn on a head are described with reference to FIG. 39A, FIG. 39B and FIG. 40A, and FIG. 40B. These wearable devices have at least one of a function of displaying AR content and a function of displaying VR content. Note that these wearable devices may have a function of displaying SR (Substitutional Reality) or MR (Mixed Reality) content, in addition to AR and VR content. The electronic device having a function of displaying content of AR, VR, SR, MR, and the like enables the user to reach a higher level of immersion.

An electronic device 700A illustrated in FIG. 39A and an electronic device 700B illustrated in FIG. 39B each include a pair of display panels 751, a pair of housings 721, a communication portion (not illustrated), a pair of wearing portions 723, a control unit (not illustrated), an imaging unit (not illustrated), a pair of optical members 753, a frame 757, and a pair of nose pads 758. Note that the electronic device 700A illustrated in FIG. 39A is an example of an electronic device in which earphones 750 connected by wireless communication are added to the first display apparatus 1000 shown in FIG. 3A.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the imaging unit. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device and can supply a video signal and the like with the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 40A and an electronic device 800B illustrated in FIG. 40B each include a pair of display portions 820, a housing 821, a communication unit 822, a pair of wearing portions 823, a control unit 824, a pair of imaging units 825, and a pair of lenses 832.

The display apparatus of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 40A and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The imaging unit 825 has a function of obtaining information on the external environment. Data obtained by the imaging unit 825 can be output to the display portion 820. An image sensor can be used for the imaging unit 825. Moreover, a plurality of cameras may be provided so as to cover a plurality of fields of view, such as a telescope field of view and a wide field of view.

Although an example of including the imaging unit 825 is described here, a range sensor (hereinafter, also referred to as a sensing portion) that is capable of measuring the distance from an object may be provided. That is, the imaging unit 825 is one embodiment of the sensing portion. As the sensing portion, an image sensor or a range image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication unit (not illustrated) and have a wireless communication function. The earphones 750 can receive information (e.g., audio data) from the electronic device with the wireless communication function. For example, the electronic device 700A illustrated in FIG. 39A has a function of transmitting information to the earphones 750 with the wireless communication function. As another example, the electronic device 800A illustrated in FIG. 40A has a function of transmitting information to the earphones 750 with the wireless communication function.

The electronic device may include an earphone portion. The electronic device 700B illustrated in FIG. 39B includes earphone portions 727. For example, the earphone portion 727 and the control unit can be connected to each other by wire. Part of a wiring that connects the earphone portion 727 and the control unit may be positioned inside the housing 721 or the wearing portion 723.

Similarly, the electronic device 800B illustrated in FIG. 40B includes earphone portions 827. For example, the earphone portion 827 and the control unit 824 can be connected to each other by wire. Part of a wiring that connects the earphone portion 827 and the control unit 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggle-type device (e.g., the electronic device 800A and the electronic device 800B) are preferable as the electronic device of one embodiment of the present invention. The glasses-type electronic device and the goggle-type electronic device shown above are suitable as the first display apparatus 1000 described in Embodiment 1.

The electronic device of one embodiment of the present invention can transmit information to earphones by wire or wirelessly.

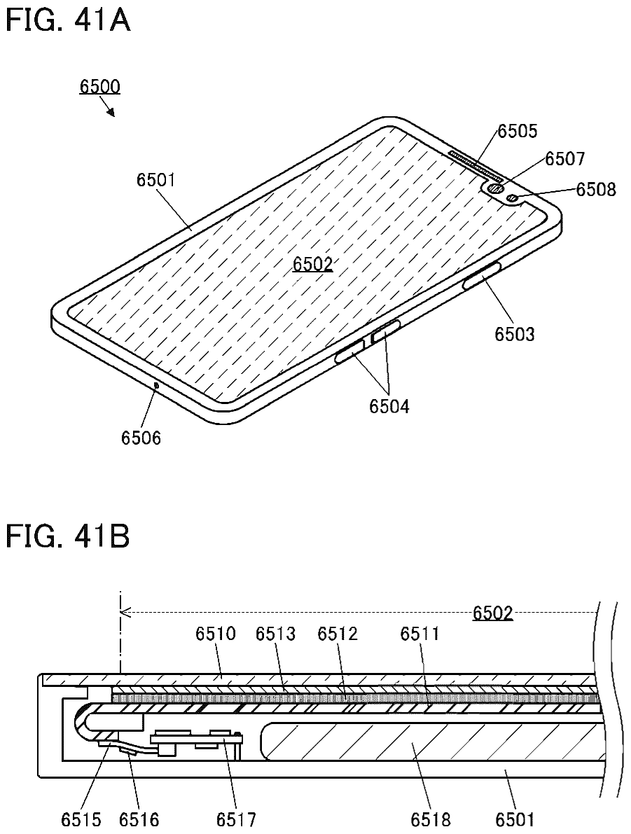

An electronic device 6500 illustrated in FIG. 41A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 41B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is provided on the back side of the pixel portion, whereby an electronic device with a narrow bezel can be obtained.

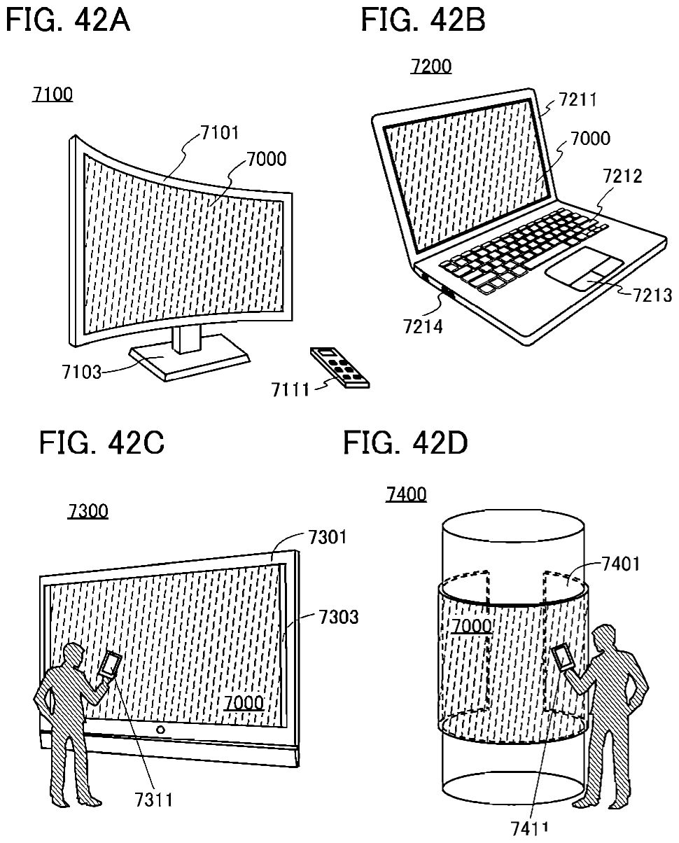

FIG. 42A illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 42A can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 42B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 42C and FIG. 42D illustrate examples of digital signage.

Digital signage 7300 illustrated in FIG. 42C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 42D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 42C and FIG. 42D.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 42C and FIG. 42D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

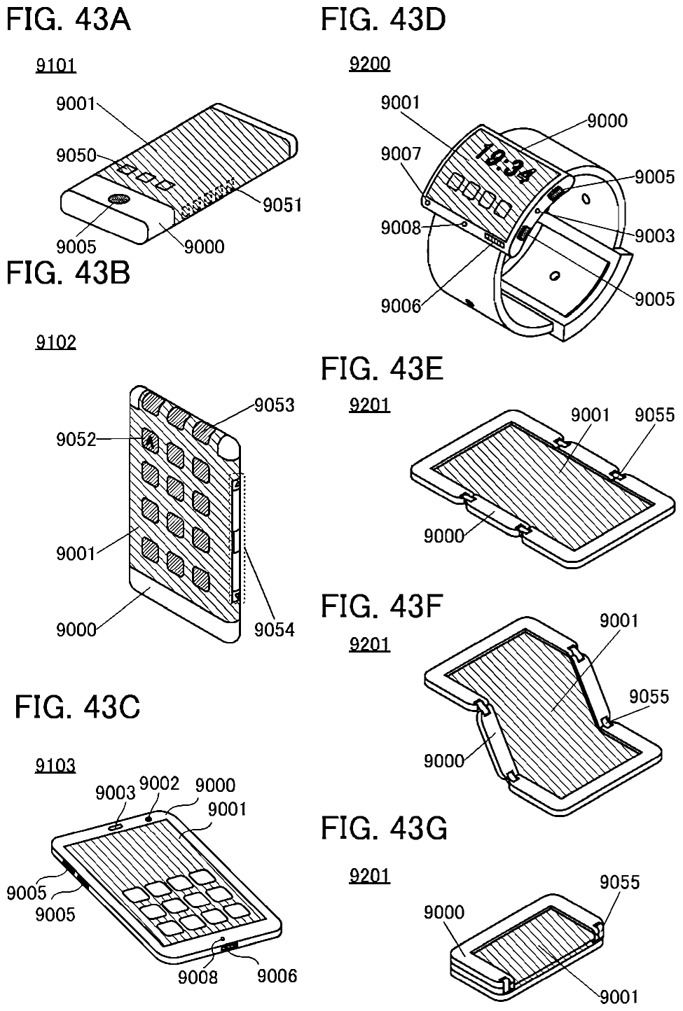

Electronic devices illustrated in FIG. 43A to FIG. 43G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 43A to FIG. 43G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 43A to FIG. 43G are described in detail below.

FIG. 43A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 43A illustrates an example where three icons 9050 are displayed. Furthermore, information 9051 indicated by dashed rectangles can be displayed on another surface of the display portion 9001. Examples of the information 9051 include notification of reception of an e-mail, an SNS (Social Networking Service) message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 43B is a perspective view illustrating a portable information terminal 9102. The portable information terminal 9102 has a function of displaying information on three or more surfaces of the display portion 9001. Shown here is an example where information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 43C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 43D is a perspective view illustrating a watch-type portable information terminal 9200. For example, the portable information terminal 9200 can be used for a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 43E to FIG. 43G are perspective views illustrating a foldable portable information terminal 9201. FIG. 43E is a perspective view of an opened state of the portable information terminal 9201, FIG. 43G is a perspective view of a folded state thereof, and FIG. 43F is a perspective view of a state in the middle of change from one of FIG. 43E and FIG. 43G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

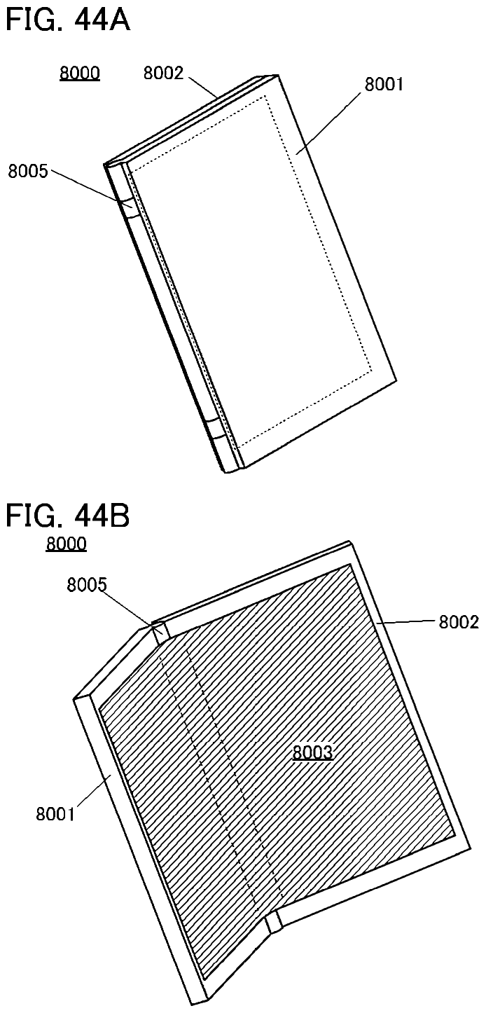

A foldable portable information terminal 8000 illustrated in FIG. 44A and FIG. 44B includes a housing 8001, a housing 8002, a display portion 8003, a hinge portion 8005, and the like. The portable information terminal 8000 can be folded with the hinge portion 8005.

The housing 8001 and the housing 8002 are joined together with the hinge portion 8005. The portable information terminal 8000 can be opened as illustrated in FIG. 44B from a folded state (FIG. 44A). Thus, the portable information terminal 8000 has high portability when carried and excellent visibility with its large display region when used.

In the portable information terminal 8000, the display portion 8003 that is flexible is provided across the housing 8001 and the housing 8002 which are joined together by the hinge portion 8005.

The display apparatus fabricated using one embodiment of the present invention can be used for the display portion 8003. Thus, the portable information terminal can be fabricated with a high yield.

The display portion 8003 can display at least one of text information, a still image, a moving image, and the like. When text information is displayed on the display portion, the portable information terminal 8000 can be used as an e-book reader.

When the portable information terminal 8000 is opened, the display portion 8003 is held with the radius of curvature being large. For example, the display portion 8003 is held while including a curved portion with a radius of curvature of 1 mm to 50 mm inclusive, preferably 5 mm to 30 mm inclusive. Part of the display portion 8003 can display an image while being curved since pixels are continuously arranged from the housing 8001 to the housing 8002.

The display portion 8003 functions as a touch panel and can be controlled with a finger, a stylus, or the like.

The display portion 8003 is preferably formed using one flexible display. Thus, a seamless continuous image can be displayed between the housing 8001 and the housing 8002. Note that each of the housing 8001 and the housing 8002 may be provided with a display.

The hinge portion 8005 preferably includes a locking mechanism so that an angle formed between the housing 8001 and the housing 8002 does not become larger than a predetermined angle when the portable information terminal 8000 is opened. For example, the angle at which they become locked (they are not opened any further) is preferably greater than or equal to 90° and less than 180° and can be typically 90°, 120°, 135°, 150°, 175°, or the like. In that case, the convenience, safety, and reliability of the portable information terminal 8000 can be improved.

When the hinge portion 8005 includes a locking mechanism, excessive force is not applied to the display portion 8003; thus, breakage of the display portion 8003 can be prevented. Therefore, a highly reliable portable information terminal can be achieved.

The housing 8001 and the housing 8002 may include a power button, an operation button, an external connection port, a speaker, a microphone, or the like.

Either the housing 8001 or the housing 8002 is provided with a wireless communication module, and data can be transmitted and received through a computer network such as the Internet, a LAN (Local Area Network), or Wi-Fi (registered trademark).

The electronic devices illustrated in FIG. 41 to FIG. 44 are suitable as the second display apparatus 1002 described in Embodiment 1.

This embodiment can be combined with the other embodiments as appropriate.

### REFERENCE NUMERALS

10A: display apparatus, 10B: display apparatus, 10C: display apparatus, 11: substrate, 12: substrate, 13: display portion, 14: terminal portion, 19: sub-display portion, 20: layer, 21: transistor, 22: channel formation region, 29A: section, 29B: section, 29C: section, 30: driver circuit, 30a: driver circuit, 30b: driver circuit, 30c: driver circuit, 30d: driver circuit, 31: source driver circuit, 32: digital-to-analog converter circuit, 33: gate driver circuit, 34: level shifter, 35: amplifier circuit, 39: section, 40: functional circuit, 41: storage device, 42: GPU, 42a: color irregularity correction, 42b: upconversion, 43: EL correction circuit, 44: timing controller, 45: CPU, 46: sensor controller, 47: power supply circuit, 50: layer, 51: pixel circuit, 51A: pixel circuit, 51B: pixel circuit, 51C: pixel circuit, 51D: pixel circuit, 51E: pixel circuit, 51F: pixel circuit, 51G: pixel circuit, 51H: pixel circuit, 51I: pixel circuit, 52: transistor, 52A: transistor, 52B: transistor, 52C: transistor, 52D: transistor, 52w: transistor, 53: capacitor, 53A: capacitor, 53s: capacitor, 53w: capacitor, 55: pixel circuit group, 59: section, 60: layer, 61: light-emitting element, 70: display module, 71: printed wiring board, 72: terminal portion, 73: wire, 74: FPC, 75: connection portion, 80: input/output circuit, 100: display apparatus, 101: substrate, 110: light-emitting element, 110a: light-emitting element, 110b: light-emitting element, 110B: light-emitting element, 110c: light-emitting element, 110G: light-emitting element, 110R: light-emitting element, 111: pixel electrode, 111B: pixel electrode, 111C: connection electrode, 111G: pixel electrode, 111R: pixel electrode, 112: organic layer, 112B: organic layer, 112G: organic layer, 112R: organic layer, 113: common electrode, 114: common layer, 121: protective layer, 124a: pixel, 124b: pixel, 125: insulating layer, 126: resin layer, 128: layer, 140: connection portion, 150: pixel, 151: pixel, 170: substrate, 171: adhesive layer, 200A: display apparatus, 200B: display apparatus, 200C: display apparatus, 200D: display apparatus, 200E: display apparatus, 200F: display apparatus, 200G: display apparatus, 230: pixel, 240: capacitor, 241: conductive layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274: plug, 274a: conductive layer, 274b: conductive layer, 280: display module, 281: display portion, 282: circuit portion, 283: pixel circuit portion, 283a: pixel circuit, 284: pixel portion, 284a: pixel, 285: terminal portion, 286: wiring portion, 290: FPC, 291: substrate, 292: substrate, 301: substrate, 301A: substrate, 301B: substrate, 310: transistor, 310A: transistor, 310B: transistor, 311: conductive layer, 312: low-resistance region, 313: insulating layer, 314: insulating layer, 315: element isolation layer, 320: transistor, 320A: transistor, 320B: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 441: timing controller, 442: input/output circuit, 443: frame memory, 461: image information input portion, 462: clock signal input portion, 463: image data temporary retention portion, 464: operation parameter setting portion, 465: internal clock signal generating portion, 466: image processing portion, 467: memory controller, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763: EL layer, 763a: light-emitting unit, 763b: light-emitting unit, 763c: light-emitting unit, 764: layer, 771: light-emitting layer, 771a: light-emitting layer, 771b: light-emitting layer, 771c: light-emitting layer, 772: light-emitting layer, 772a: light-emitting layer, 772b: light-emitting layer, 772c: light-emitting layer, 773: light-emitting layer, 780: layer, 780a: layer, 780b: layer, 780c: layer, 781: layer, 782: layer, 785: charge-generation layer, 790: layer, 790a: layer, 790b: layer, 790c: layer, 791: layer, 792: layer, 800A: electronic device, 800B: electronic device, 820: display portion, 821: housing, 822: communication unit, 823: wearing portion, 824: control unit, 825: imaging unit, 827: earphone portion, 832: lens, 1000: display apparatus, 1000A: display apparatus, 1000B: display apparatus, 1002: display apparatus, 1010: display portion, 1011: housing, 1012: sensor unit, 1013: communication unit, 1014: control unit, 1015: camera unit, 1016: wearing portion, 1017: display panel, 1018: power supply unit, 1019: optical member, 1020: display portion, 1021: housing, 1022: sensor unit, 1023: communication unit, 1024: control unit, 1025: camera unit, 1028: power supply unit, 1029: communication unit, 1040: display image, 1041: dimensional virtual object, 1042: display image, 1043: display image, 1044: display image, 1045: display image, 1060: display image, 1061: display image, 1110: headphone unit, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 8000: portable information terminal, 8001: housing, 8002: housing, 8003: display portion, 8005: hinge portion, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display system comprising:
a first display apparatus; and
a second display apparatus,
wherein the first display apparatus comprises a first display portion displaying a first image superimposed on a transmission image,
wherein the second display apparatus comprises a second display portion,
wherein the first display apparatus is configured to obtain positional information of the second display portion, and
wherein a display position of the first image is determined on the basis of the positional information of the second display portion.

2. The display system according to claim 1,
wherein the first display portion has a light-transmitting property, and
wherein the transmission image is an image passing through the first display portion.

3. The display system according to claim 1,
wherein the first display apparatus comprises an imaging means, and
wherein the transmission image is an image captured by the imaging means.

4. The display system according to claim 1,
wherein the first image is displayed in the case where at least part of the second display portion is positioned in a range of the transmission image.

5. The display system according to claim 1,
wherein the first image is generated in accordance with the positional information.

6. The display system according to claim 1,
wherein the first display apparatus is a glasses-type apparatus.

7. The display system according to claim 1,
wherein the first display apparatus is a goggle-type display apparatus.

8. The display system according to claim 1,
wherein the second display apparatus comprises a hinge portion, and
wherein the second display apparatus is configured to be folded at the hinge portion.

9. The display system according to claim 1,
wherein the first display apparatus comprises a first layer, a second layer, and a third layer,
wherein the first layer comprises a driver circuit and a CPU,
wherein the second layer comprises a pixel circuit,
wherein the third layer comprises a display device,
wherein the first layer comprises a first transistor comprising a semiconductor layer comprising silicon in a channel formation region,
wherein the second layer comprises a second transistor comprising a semiconductor layer comprising a metal oxide in a channel formation region, and
wherein the third layer comprises an organic EL device.

10. The display system according to claim 9,
wherein the metal oxide comprises indium, an element M, and zinc, and
wherein the element M is aluminum, gallium, yttrium, or tin.

11. The display system according to claim 9,
wherein the organic EL device is a light-emitting device processed by a photolithography method.

12. A display system comprising:
a first display apparatus;
a second display apparatus; and
a third display apparatus,
wherein the first display apparatus comprises a first display portion displaying a first image superimposed on a transmission image,
wherein the third display apparatus comprises a third display portion displaying a third image superimposed on a transmission image,
wherein the first display apparatus is configured to obtain positional information of the second display portion, and
wherein the third display apparatus is configured to obtain the positional information of the second display portion.

13. The display system according to claim 12,
wherein a display position of the first image for a user of the first display apparatus is determined on the basis of the positional information of the second display portion, and
wherein a display position of the third image for a user of the third display apparatus is determined on the basis of the positional information of the second display portion.

14. The display system according to claim 12,
wherein the first display portion has a light-transmitting property, and
wherein the transmission image is an image passing through the first display portion.

15. The display system according to claim 12,
wherein the first image is displayed in the case where at least part of the second display portion is positioned in a range of the transmission image.

16. The display system according to claim 12,
wherein the first display apparatus is a glasses-type apparatus, and
wherein the third display apparatus is a glasses-type apparatus.

17. The display system according to claim 12,
wherein the first display apparatus is a goggle-type display apparatus, and
wherein the third display apparatus is a goggle-type display apparatus.
